(19) United States
(12) Patent Application Publication
(10) Pub. No.: US 2015/0007872 A1
(43) Pub. Date: Jan. 8, 2015

(54) SOLAR GENERATOR PLATFORM

(71) Applicant: Powerak Pty Ltd, Maleeny, QLD (AU)

(72) Inventors: George Jaroslav Cap, Queensland (AU); Ross Woodfield, Queensland (AU)

(21) Appl. No.: 14/377,595

(22) PCT Filed: Feb. 7, 2013
(86) PCT No.: PCT/AU2013/000102

§ 371 Date: Aug. 8, 2014

(30) Foreign Application Priority Data
Feb. 8, 2012 (AU) 2012900455
Nov. 16, 2012 (AU) 2012904983

(51) Int. Cl. F24J 2/52; H01L 31/042

(52) U.S. Cl. CPC F24J 2/5267; H01L 31/0422; F24J 2/5239
USPC 136/251

(57) ABSTRACT

An assembly of, uniquely inter-connected modular parts form a high strength waterproof flexible membrane. The said membrane is restrained/positioned in the horizontal plane via a perimeter beam, with fixings on its exterior boundary to the storage parapet/berm, and through internal tendons to the PV panel super structure rows, whilst allowing unrestricted vertical movement in concert with the water level changes. This invention is intended to provide stability, reliability and durability under localised extreme weather conditions. The system may be mounted on a flotation pod or on a land based or building structure.

This invention relates to a solar generator array, plat-formed on an assembly of, uniquely inter-connected modular parts to form a high strength waterproof flexible membrane. This may be water based or land based on buildings. The said membrane is restrained in the horizontal plane via a perimeter beam, with fixings on its exterior boundary to the storage parapet/berm, and through internal tendons, whilst allowing unrestricted vertical movement in concert with the water level changes. This invention is intended to provide stability, reliability and durability under localised extreme weather conditions.

The invention ameliorates evaporation and/or water quality of water storages via partial or a full cover whilst providing a strong stable platform for the solar generation of power.

### BACKGROUND TO THE INVENTION

For some time there has been interest in the covering of water storages to reduce evaporation and to control air and water borne particulate contamination from those storages.

WO 98/12392 discloses a flat polygonal floating body where the faces of the floating body have partly submerged vertical walls with lateral edges. The Device has an arched cover with a hole in the top cover for air exchange.

Australian patent 199964460 discloses a modular floating cover to prevent loss of water from large water storages comprising modular units joined together by straps or ties, manufactured from impermeable polypropylene multi-filament, material welded together to form a sheet with sleeves. The sleeves are filled with polystyrene or polyurethane floatation devices to provide flotation and stiffness to the covers.

WO/02/086258 discloses a laminated cover for the reduction of the rate of evaporation of a body of water, the cover comprising of at least one layer of material that is relatively heat reflecting, and another layer of material that is relatively light absorbing and a method of forming the laminated cover.

Australian patent 198429445 discloses a water evaporation suppression blanket comprising of interconnected buoyant segments cut from tyres cut orthogonal to the axis of the tyre and assembled in parallel or staggered array.

Australian patent 200131305 discloses a floating cover with a floating grid anchored to the perimeter walls of the reservoir, and floating over the liquid level inside the reservoir. A flexible impermeable membrane is affixed to the perimeter walls and is loosely laid over the floating grid.

WO2006/010204 discloses a floating modular cover for a water storage consisting of a plurality of modules in which each module includes a chamber defined by an upper surface and a lower surface there being openings in said lower surface to allow ingress of water into said chamber and openings in the upper surface to allow air to flow into and out of said chamber depending on the water level within said chamber to provide ballast for each module and flotation means associated with each module to ensure that each module floats. The modules prevent water evaporation from the area covered and the shape and size is selected to ensure that the modules are stable in high wind conditions and don't form stacks.

Solar generation from arrays of solar collectors have been proposed.

U.S. Pat. No. 7,492,120 discloses a portable PV (photo voltaic) modular solar generator for providing electricity to a stationary electrically powered device. A plurality of wheels is attached to a rechargeable battery container. The solar PV panels generate power for the driving mechanism of the device so that the PV panels can be continually positioned in optimum sunlight. The device contains a rechargeable battery that can be charged via the PV panels. There is a pivotally connected photo-voltaic panel for generating electricity. The energy from this solar generator can be inverted from DC to AC mains power [via an inverter] and synchronized via computer to be connected to the utility grid if applicable.

WO2011/094803 discloses a fixed and/or variable inclination angle modular floating array with limited rotational [array axial alignment] capability. The disclosure describes a floating coupling type block connective system with arc type wedge frames supporting PV panels. The said wedge frames are hinged on the axis of the arc and have slots cut in the coupling-type block, to enable the rear submerging of the wedge as the wedge is tilted on the axis of its arc.

International patent WO 2010/064105 discloses an ecological friendly floating solar platform. Floating modular blocks are coupled together via their corners and a coupling mechanism. A PV device is embedded in each block.

US patent US 2008/0029148 A1 discloses a superstructure frame supporting PV panels fixed to an array of artificially ballasted pontoons. The pontoons give some maintenance access.

US patent US 2006/0260605 A1 discloses a complex floating solar concentrator system. The frame of said concentrator requires to be partially submerged to function.

USA patent 20070234945 discloses a flotation structure without any provision for extreme weather. It uses a photovoltaic laminate panel.

U.S. Pat. No. 7,642,450 B2 discloses an improvement to US 2006/0260605.

U.S. Pat. No. 6,220,241 B1 discloses a large conical floating solar concentrator.

US patent US 2008/0169203 discloses a floating solar array with the solar panels partially submerged.

WO2010/064271 discloses a floating array using tubular connection elements between modules to contain power cables etc. The structure is tethered via tethers to ballasts on the water body bottom.

International patent WO 2010/014310 discloses a solar power generator using a sealed evaporative cooling system built around a PV Cell array.

Patent WO2000012839 discloses a solar panel roof mounting system. This system appears complex and time consuming to assemble. This system relies on under tile fixing and the inherent system weight. There is no lower fixing mechanism to address fixing from the facia side of the roof, and further: The strapping mechanism has no inherent North-South & East-West, cross-fixing mechanism. The fixing system is a non non-tensioned system. The straps are illustrated fixed to the top tile battens, The system without the necessary cross tensioning, and strong, stable fixing points, will not endure medium-to-high wind speeds, and would predictably oscillate/vibrate/lift when affected by variable wind gusts.

Levels of maturity restrict these prior art devices specifically due to:
Limited adaptation capability to large/unlimited practical scale payload carrying capacity and therefore little possibility of commercial utility level power generation potential;
General wind stability issues;
Specific wind stability issues with commercial water level changes on deployments due to insufficient
   Inter product horizontal by-directional coupling deployment strength/stiffness;
   Deployed product perimeter strength, integrity and ineffective active tethering strategies;
Inability to provide a commercial product that can be adapted to satisfy the US EPA LT2 rule.

Land based arrays and systems designed for installations on roof tops or on buildings lack the ability to be easily and inexpensively installed.

It is an object of this invention to provide a commercial solar generator that is easy to install on land, buildings or on water where it offers evaporation control, compliance to the US EPA LT2 rule and ameliorates the disadvantages of the prior art.

### BRIEF DESCRIPTION OF THE INVENTION

To this end the present invention provides a platform for supporting solar panels which a solar panel support surface that seats on an existing building structure or on top of two or more flotation pods to form a module that is adapted to carry a solar panel. The support surface incorporates water drainage channels.

The said modules are preferably assembled from a top part moulding which forms the panel support surface which may be supported on a building or land based superstructure or a floating water based platform.

The flotation pods are purposely designed bottomless inverted cavities, hereafter referred to as: the ‘Invert’. Typically the flotation pod is an up turned polygon [in plan], shaped pod, with several isolated downward bottom-opened cavities. Minimums of two pods are aligned to nest at set angles [depending on the polygon side number and type], to form the minimum repeatable module.

A first embodiment of the Invert moulding may be likened to an up turned ‘T’ shaped bucket, with several isolated cavities. Each end of the cavities running up and down on the main vertical stem of the ‘T’, are triangularly protruded. If the two inverts are aligned so that the bottom triangular tips of the ‘T’ touch, a further invert part is mated either side of the opposed vertical ‘T’ stems. This shape forms the minimum repeatable size of the invert assembly. A preferred embodiment, is a square shaped moulding, again with several isolated cavities, with the difference that no cavity crosses over the diagonals of the square. This allows the cutting of the said square moulding along these diagonals. Arrays of modules are constructed by the concatenation of the said repeatable patterns in both directions in the horizontal plane. These arrays are specifically tessellated on the water body such that the perimeters of the arrays run purposely offset but closely matching the contours of the banks.

The perimeters of the deployments need to be supported by inverts to the edge of the perimeter. The first embodiment requires a further LHS and RHS half moulding of the invert part [i.e. cut down the vertical T centreline], with an extra moulded wall placed at the cut centreline, will assemble to the perimeter filling the gaps which necessitates the construction of an additional moulding tool.

The deck mates to the top of the invert part [via extruded bosses], in close alignment of the top part edges to the centreline of the vertical ‘T’ stems [or diagonals in the preferred embodiment]. The wings of the ‘T’s, overlap up to 50% into the deck placed either side of the vertical ‘T’ centreline greatly enhancing the connective vertical bending moment in the horizontal plane.

Whereas the deck in the preferred embodiment is assembled in the centre of an array of four square-shaped inverts, the deck diagonals span to the centre of the each invert. This embodiment provides the advantage that the edge of the deck will always run along the central axis of the square invert, allowing the load-bearing floatation of the entire square invert, to support active loads to the edge of the deck. These assemblies can be populated on the central areas (plates) of any shaped water reservoirs. The central plate of a reservoir is defined as the maximum area of reservoir cover, which does not cover any of the slope area of the storage containment shell.

When considering applications in the field, the banks of most water storages are not aligned exactly North or South, in fact the said storages may have many sides. For large deployments it is often fiscally preferable to cover the largest possible central plate area. In addition the storage cover may be required to comply with the US EPA LT#2 long-term storage rule, which will necessitate a complete rainwater run off and air particulate shedding capability. For working storages this requires flexible geo-membrane [i.e. synthetic rubber] connections, spanning from the shoreline to the central plate. Further, since the water level of the storage is continually changing, the differential chord length from the shoreline to central plate that will vary in proportion to the operational water level changes will have to be accounted for. Also to minimise expensive geo-membrane gusseting, it would be prudent to run the central plate perimeter edge as close as possible to the shoreline. Two major factors will influence this determination:
The lowest working water level and;
Whether the storage will be required to be drained and cleaned.

The latter of the two will necessitate the relocation and ‘parking’ of the floating membrane on a shelf adjacent to the storage.

The solar array to maximise its efficiency, is preferably aligned due South for northern hemisphere countries. Often this alignment conflicts with the membrane array and the water body, alignment.

In this invention, the solar array attachment design accomplishes this requirement with a unique design. The Solar panels are supported on a bottom hollowed out with the wedge angle identical to the latitude of the array, and the wedge length equal to the length of the PV panel. The top of the wedge is cut out leaving a rim for the connection of the solar panels. The moulding, which provides the PV panel support structure will be hereafter referred to as: the ‘Rack’. The triangular sides of the said rack, are lengthened from the base of the wedge for wind considerations. Normal horizontal extrusions away from the rack main body, form the base of each side and will be referred to as the feet.

The first embodiment of the rack is a generic embodiment where each foot is preferably not identical [in reflection], although each foot preferably has three equi-positioned holes. The LHS foot is designed with bottom protrusions to sit on top of the RHS foot with top protrusions. When the LHS and RHS feet are mated, the three holes in each foot become complete and axially inline. The purpose of the mating is for Omni-angle row alignment. The aim of the protrusions is so that each single rack can be fixed in the same way as those mated in a row, and still sit horizontally.

In the preferred embodiment of the rack the LHS foot is defined as the pivoting foot, and the RHS side foot is defined as the fixing foot. The advantage of this embodiment is that the fixing plate has moulded vertical rib extrusions and clipping points at the base of these extrusions, to facilitate a ‘piggy back’ type concatenation of row racking assemblies. The pivoting foot of the rack has slots positioned to accept the fixing plate ribs of the previous rack in the row. This ‘align-push and clip’ assembly process has obvious installation speed advantages.

Preferably the deck is square shaped, the top surface grading down from the four, corners to two shallow gutters, running normal to and through each other, bisecting the said square, horizontally in the ‘X’, and ‘Y’ directions. As the membrane is assembled, these gutters align to each other and run normal to each other across the membrane. They form the major rainwater run off paths on the membrane.

This first embodiment of the deck preferably incorporates a perimeter tongue extrusion—which takes on the profile of the top surface recessing when passing through each drain. The assembly of the invert part and the top part leaves a small [diurnal/seasonal], thermal expansion gap, in which is placed a compressible seal. Each seal intersection point [i.e. at every top part corner], has a waterproof seal junction, essentially of similar profile, with inserts for jointing seals from four directions. All seals are re-insert-able. This process waterproofs the entire top membrane.

The deck has also incorporated an array of extruded cylindrical vertical bosses [CVB]; the horizontal separation of the bosses is such that it is equivalent in both directions over the entire membrane [inclusive of top part junctions]. Preferably there is a small square vertical protrusion and a small fixing-hole starter on top of each said boss.

Note: That the top of the said cylindrical bosses are all aligned horizontally. All said bosses are braced underneath.

The deck has also its major fixing holes, which extend through sub top surface bosses to another horizontal alignment. These mate with the invert part.

A rail connector is designed to fix to three inline CVB's, in horizontal, vertical and diagonally. The part can be defined as an extruded ‘U’ section of sufficient length, with two opposing further extrusions from the top of the ‘U’ stems in opposing directions to form the rails. The CVB connections are extruded from the bottom of the ‘U’ section.

Note: This part is moulded with countersunk pilot fixing holes for fixing the top part.

The slider is a moulding constructed to slide on the rail connector. It is a block type moulding with cuts for adaptation to the rail connector. Preferably on top of this, and centrally placed, is a further mould forming a ‘T’ with a cylindrical stem. And a bar type section top, with rounded vertical edges.

The slot washer is basically a slotted washer with a top perimeter extrusion.

The above three parts are all preferred components in the rack row fixing strategy. After assembly, aligning, basic tethering [of the top and invert assembly-membrane], and sealing of the membrane has been completed. The rack rows are now ready to be assembled.

In this process:
The row angle is determined [due south for Northern latitudes];
The rail connectors are laid out and fixed across the membrane;
One slider is fitted to each rail connector;
Starting from the left, the racks are placed on the sliders, with the ‘T’s placed through the foot holes [at least two];
The slot washer, is then inserted into the foot holes over the ‘T’, and then twisted until the slot is approximately parallel to the rails;
Final adjustments and checks of the row are made;
A hole is drilled from the top of pilot placed either side of the top of the T, in the slider T through:
   Slider T;
   Slot Washer;
   Rail connector;
   Through to bottom of the slider main body;
A Standard set of bolts can now fix the parts together.

Each row can be fixed to the modules in the platform in a straightforward process. The second preferred embodiment of the deck complies to the US EPA LT2 rule specifically in relation to the prohibition of compressional seal designs. The seal in this embodiment is fixed to both of the decks allowing for thermal movement via a concertina type loop and a vertical curve at each end allowing the placement of a water proof cap over the seal intersection.

This design variation requires the elongation of the rack support bosses and the inclusion of extra support bosses to address the geo-membrane attachment.

The preferred embodiment of the rack connects directly to the deck.

Another factor is the effect of possible maximum storm [PMS]. The rows must be able to with stand the impact of such a storm, from any possible orientation around the storage with a good factor of safety.

To this end this invention provides the above assembled floating platform and solar panel racking, with a plurality of structural tendons forming a horizontal grid where each tendon is attached to a plurality of modules along its length spanning between a perimeter transfer beam positioned about the periphery of the modular membrane deployment, where each end of the said tendons is secured to the said transfer beam.

In the first rack embodiment the tendons running parallel to the rows are fixed in three positions on the front of the rack, a second set of tendons running normal to the first are fixed at the front and rear at the centre of each rack. The said positioning of the tendons, will distribute the elemental forces acting on each row, preventing the stacking and or crushing of the rack rows and damage to the membrane.

In the preferred embodiment the tendons are run parallel to the rows and fixed to the front feet [ie: in two places], the second set of tendons are run along the feet fixed at the front and back of the feet.

As discussed before the racked PV panel rows are not necessarily aligned to the banks of the storage. This necessitates the restraint of the central plate, and to avoid a number of cost and design constraints it is preferable to run these restraint cables normal to the banks.

A perimeter transfer beam will be needed, with storage specific horizontal and vertical deflection strength, to distribute the internal forces of the tendons to the external tethers running normal to the banks.

Commercial water level variances bring to fore two more necessary design functions need to be incorporated into the said transfer beam. These become apparent when considering a PMS coincident with a different water level or an [unlikely], actual water level change. If say the water level was reduced to half, then there is introduced an eccentricity to the beam due to the increased vertical component of the tether cables and the separation between the tendon connections and the tether cable fixing points.
1. The transfer beam will require some torsional [twisting], strength design, to redistribute torsional forces on the beam due to water level changes.

When considering a PMS at this level, then the whole membrane could move in the direction of the PMS with a damaging consequence of membrane edge lifting.
2. The Transfer beam will require vertical edge restraint cables, which in turn will cause some vertical deflection, and will need vertical deflection strengthening design.

The vertical restraint cable system, is fixed to function on the outer edge of the transfer beam.

Note: The design of the transfer beam will depend on the separation of the tether cables and the vertical restraints and the actual maximum vertical movement of the beam.

The vertical restraint cables [VRC], are preferably fixed to ground anchors or to high-mass weights, specifically placed around the bottom or fixed and floated below the transfer beam, of the storage. The said cables will need to run off to the shoreline to winches. To balance the forces placed on the transfer beam by the VRC cables, half of the cables are run to the right of the [side], of the transfer beam, and the other half in the opposite direction. The anchorage point at the cable takeoff point [either side of the beam side], will need to be able to restrain the sum of all loads on the cables routed to the point. Note that the VRC cables can also be run direct to the shore [if applicable and/or possible], normal to the transfer beam.

Note: In normal conditions, there will no load on the VRC cables, the load appears only when load appears on the transfer beam due the onset of a storm or in a lesser extent, a medium wind.

The transfer beam is assembled in sections and placed on top of a ‘bed’ of rail connectors, once assembled the transfer beam's cable is tensioned, and the beam will rise of its bed.

The maximum water shedding of the membrane is defined by its ability to drain the collected rainfall on its surface in a specified time. The maximum water shedding therefore also defines the maximum area of the membrane. If storages are larger than this area gutters will need to be placed in between membrane deployments. The said gutters would be spaced via the tendons and lined with a flexible membrane such as geo-membrane type synthetic rubber. The said synthetic rubber is fixed to the sides of the top part, in standard fixing procedure, and lapped up to be fixed, on the seal tongue effecting a waterproof fixing. The gutters feed into the central plate perimeter drain, which is an essential part of the synthetic rubber cover span from the central plate to the shoreline.

In small water reuse storages where the area of the central plate of the reservoir approximates to half of the surface area of the full reservoir it may be necessary to populate the slope areas with a slope tracking type membrane.

The bottom [underside], of the top part provides symmetrical ribbing in both x and y directions, to provide strength in the vertical [z] direction, these also provide connection points for substructure parts.

A square substructure pipe adaptor part, which can be oriented in any of four directions [i.e.: the four sides of the top part], and plugged into the underside ribbing of the top part at the corners. A total of four pipe adaptor parts can be plugged into a single top part. The purpose of the pipe adaptor part is to provide a parallel fixing structure for more than one large diameter [circular], pipe of defined length with specific end caps. On both the adaptor substructure sides normal to the pipe direction, are moulded lockable pipe receptacles, designed to fix the end caps of piping. The adaptor part provides dual curved arms designed to support pipes, with inserted rollers [a further minor part] that allow the inserted pipe to rotate freely within the curved arms.

If the pipe adaptor is oriented [and fixed in the top part], so that in a row of top parts all the parallel pipes are collinear, then concatenations of this assembly may be used for populating the slopes of storages, as the rotating/rolling capability of the pipes provides the least friction to the storage slope liner. Concatenation of the said row assemblies is provided via a further minor hinging part. This hinge part incorporates two cylinders separated by a ‘U’ extrusion, where the cylinders fit over the end caps of the pipes. The external diameter of the said cylinders is such that in their operation they will not impede the rotation and travel of the pipe on the slope [or any other surface]. The hinge part preferably has provision for the insertion of two [locking] pin parts, that when inserted, lock the pipe caps in place via a circular groove in the cap. A secondary purpose of the hinge part, is to lock two end caps [and therefore two pipe ends], together, and also in place via separation guards, to arrest endplay. If there is an LT2 requirement, adjacent row member top parts will via assembly be ready to accept the insertion of a flexible seal, the adjacent rows will have synthetic rubber geo-membranes [such as Hypalon or CSPE], fixed to the tongue along both sides of the length of said rows. The runoff can collect in this membrane and run normal to the slope to the storage corner gussets where it is collected in sumps and pumped off the cover.

The above system with a minor adaption can be used to form an alternative storage central plate [CP] substructure.

This type of cover would be applicable to reuse storages that the invert part would not be suitable, such as storages that have large volumes of gas emissions either from the water body or from the storage bed.

If the pipe adaptor is oriented [and fixed in the top part], so that in a single top part all the parallel pipe fixings are normal to each other, we can then assemble a substructure building block, that through the horizontally interlocked pipe array will impart the CP membrane vertical [z], and planar [x-y horizontal] strength. The pipe adaptor part has a number of locking [note: this mechanism is identical to the hinge part], cylinders on the faces normal to the pipe fixing direction. This is to secure the transverse pipe ends across the top parts. The complex pattern produced via the connection scheme, provides the interconnection and strength for each module to become integrated into the larger membrane. The rollers in the pipe adaptor part provide yet another degree of freedom, and that is the possibility of differential movement along the axis of the pipes. As the Pipes will be fully/partially immersed in the water and the top part exposed to the elements, there will be a temperature differential between the water-cooled parts and the fully exposed parts. The rollers will allow for the necessary adjustments of differential movement due to the cyclic thermal differential expansion and contraction of the said parts.

The restraining of the slope tracking membrane can be adapted quite easily to the CP with the transfer beam installed.

One end of the tracking membrane will be fixed to the parapet/berm of the storage. As the water level drops, there will be a shortening of the effective membrane length, due to the beaching of the modules. This can be modelled mathematically into a simple linear relationship (call this relationship: t). At the other end of the slope tracking membrane, near the transfer beam, the end of the tether will be fixed to a small beam. This beam will be tethered to the transfer beam with a ‘shoelace’ type configuration, with either end of the shoelace cable fixed to two ground anchors in the storage. As the water level falls, cable is released into the shoelace from the height differential and the width of the shoelace expands [—vice versa for the water level rising], this is also a linear relationship that can be made equal to (t). No extra winches will be needed to implement this tracking membrane. The transfer beam will need to be strengthened [up from the CP requirement], to account for the extra forces incurred by the tracking membrane.

Advantages of this invention include:
a) A modular set of parts, assembled to form a large continuous membrane;
b) The said modular membrane has a large payload capacity;
c) The first embodiment of the rack, has a unique Omni angle rack row fixing and aligning system connecting the rack to the deck;
d) A preferred embodiment of the rack has a specific number of alignment angles, however it connects directly to the deck;
e) A preferred embodiment of the rack has a self aligning capacity allowing a: quick: align-push-click-&-fix assembly procedure;
f) The rows of racking are able to redistribute wind generated forces through tendons;
g) The tendons also set the required expansion separation distance between the deck and racks, allowing for seasonal and diurnal thermal expansion cycling;
h) A flexible seal fixed to either deck, with upturned ends, provides the [US EPA LT2 rule] approved waterproofing/expansion room necessary between parts in the membrane;
i) A perimeter transfer beam around the central plate redistributes the tendon forces to the tether cables running normal to the bank and the vertical restraint forces through cables running vertically to the base of the storages whilst simultaneously tensioning the [inner] array tendon cables;
j) In a further adaptation with the same deck and racking parts, rolling pipes may be attached to the deck base [effectively replacing the invert], having the advantage of extending the central plate coverage to covering major parts of the slope area of storages. This cover provides an articulated, tracking membrane that rolls on the liner surface reducing liner wear or storage surface erosion, in concert with the normal diurnal working water levels;
k) The same adaptation of parts can be reoriented to assemble a pipe interlocked CP membrane, suitable for reuse storages with a high gas output;
l) The deck racking system can be adapted to provide a competent, roof top racking system, with the advantages of low basic part numbers and a self aligning rapid assembly procedure;
m) The deck racking with further adaptation can be used as a competent, land base racking system, with the advantages of low basic part numbers and a self aligning rapid assembly procedure.

### DETAILED DESCRIPTION OF THE INVENTION

Preferred embodiments of the invention will be described with reference to the drawings in which:

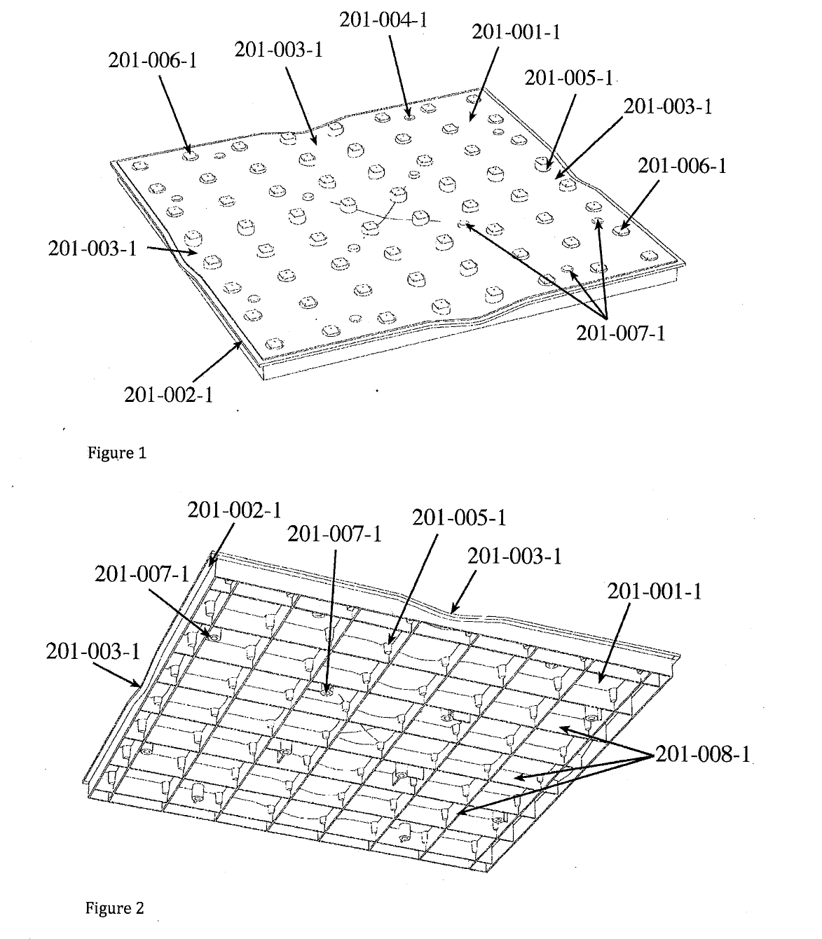

FIGS. 1 & 2 illustrate: the first embodiment deck with top and bottom views respectively;

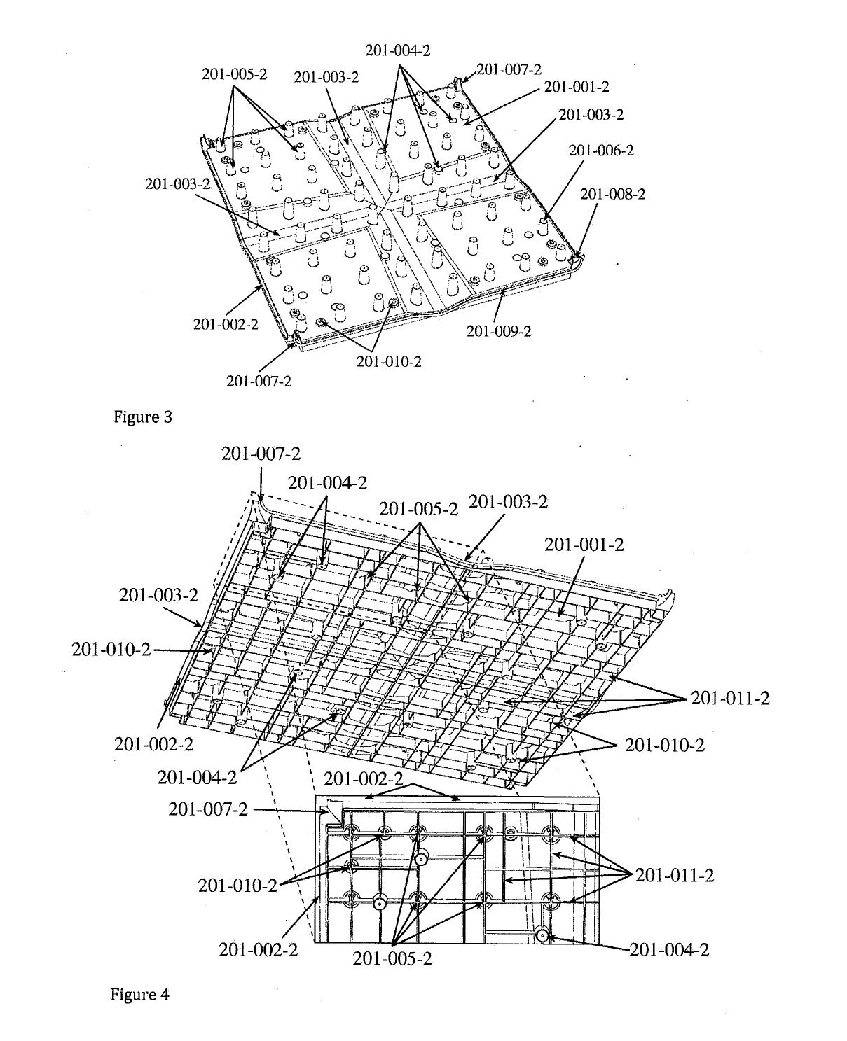

FIGS. 3 & 4 illustrate: the preferred deck embodiment with top and bottom views respectively;

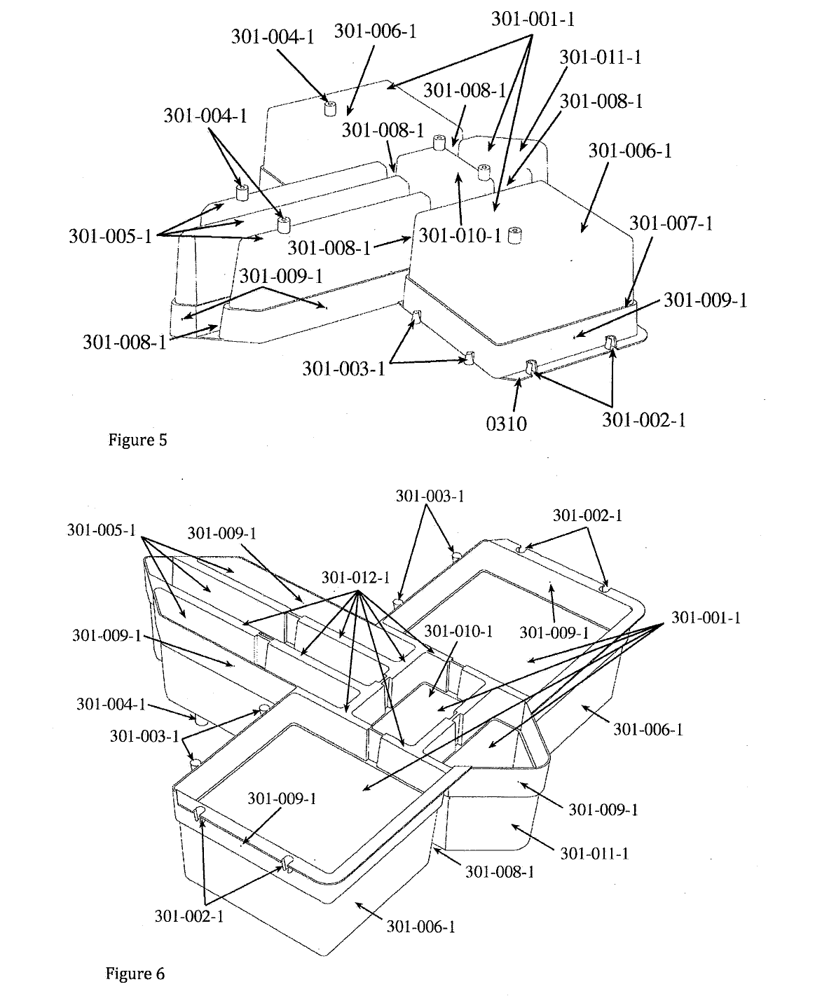

FIGS. 5 & 6 illustrate: the first embodiment of the invert with top and bottom views respectively;

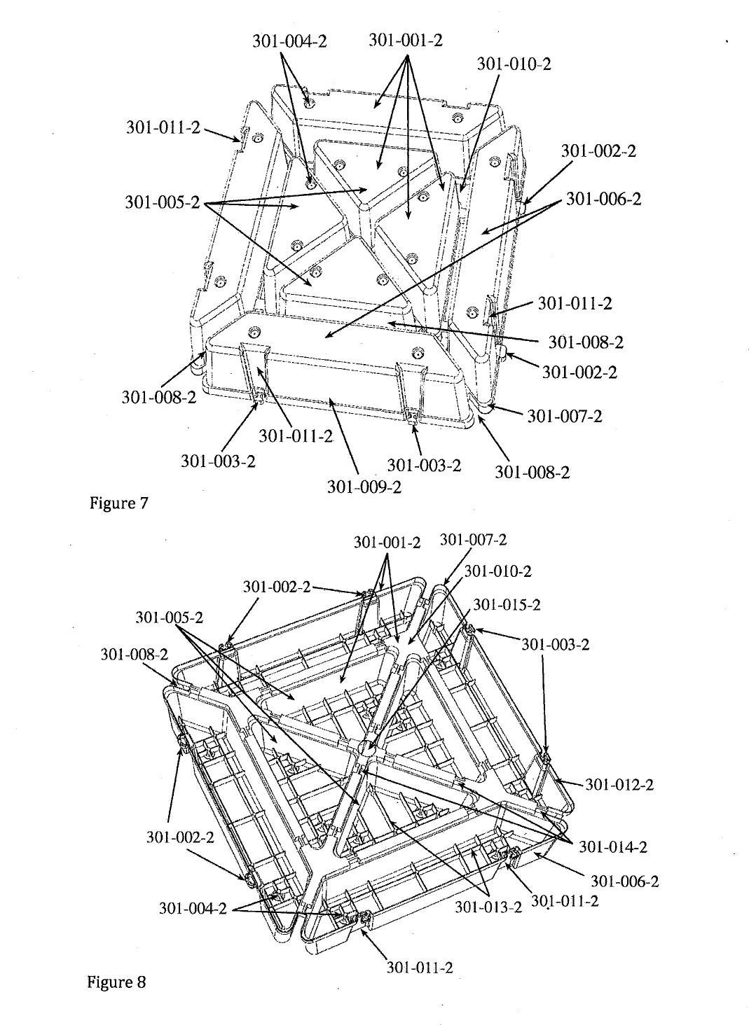

FIGS. 7 & 8 illustrate: the preferred embodiment of the invert with top and bottom views respectively;

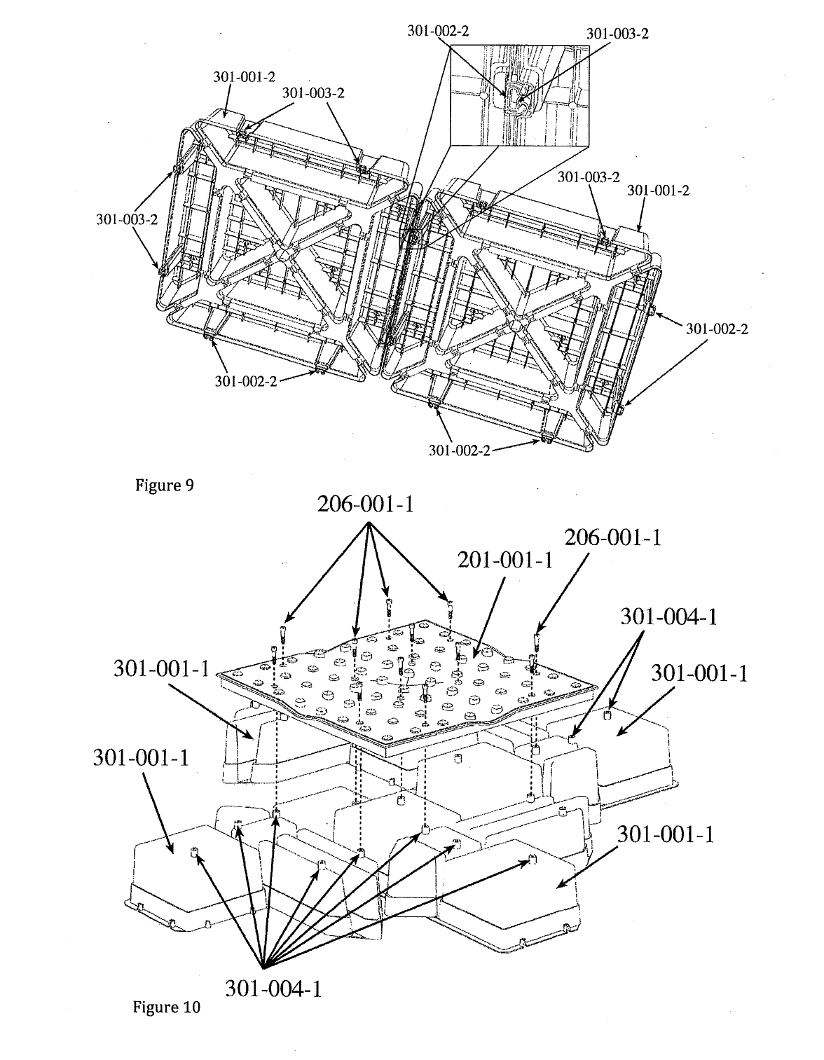

FIG. 9 illustrates: the jointing detail of two preferred embodiment inverts;

FIG. 10 illustrates: an explosion view of the first embodiment deck and invert assembly;

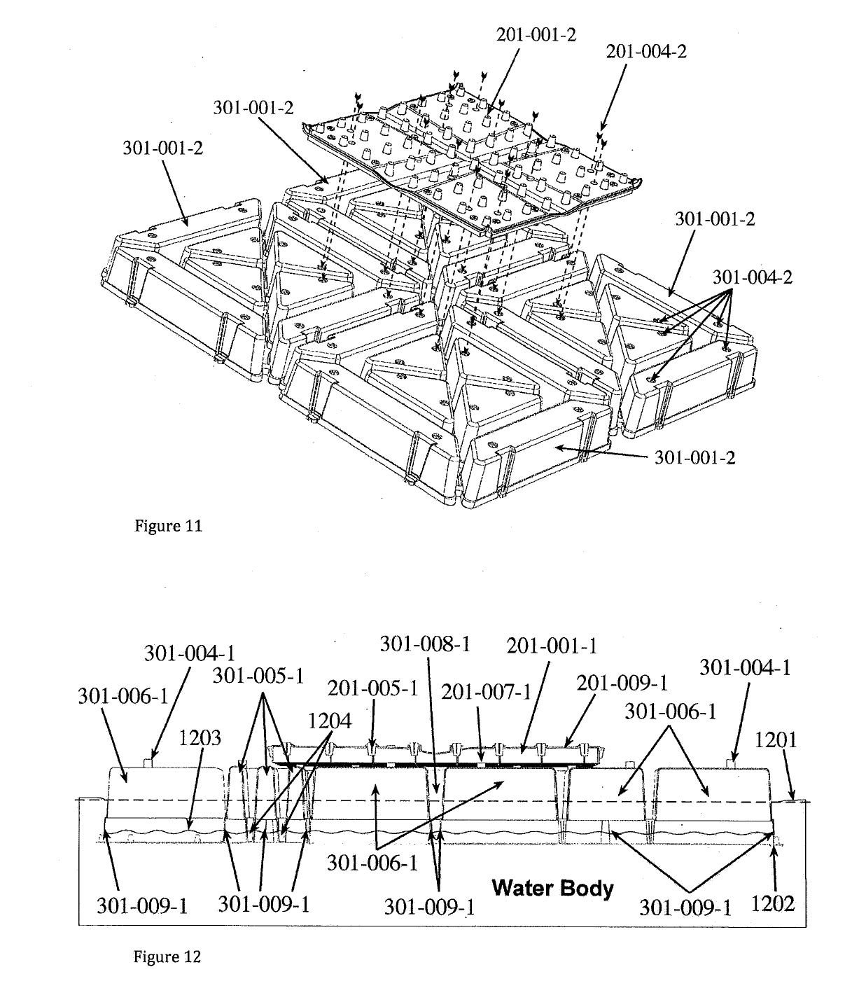

FIG. 11 illustrates: an explosion view of the preferred embodiment deck and invert assembly;

FIG. 12 illustrates: a sectional view of the first embodiment of the deck and invert part assembly with floatation considerations;

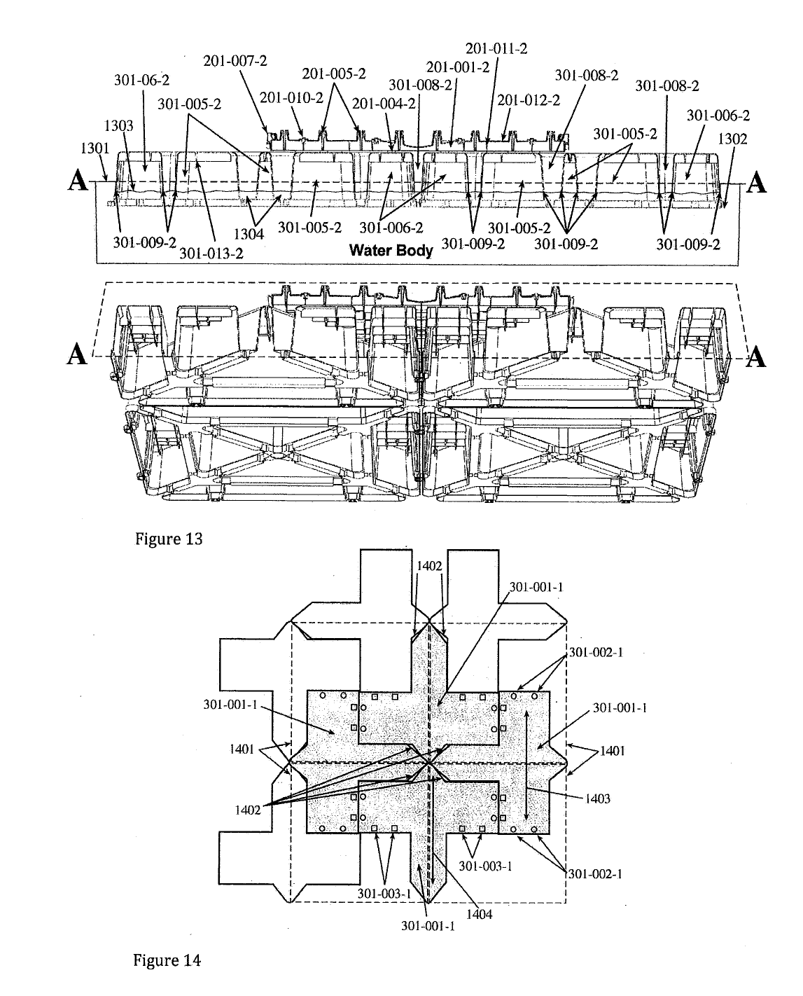

FIG. 13 illustrates: a sectional view of the preferred embodiment of the deck and invert part assembly with floatation considerations;

FIG. 14 illustrates: the assembly layout of the first embodiment deck and invert in a minimum array size;

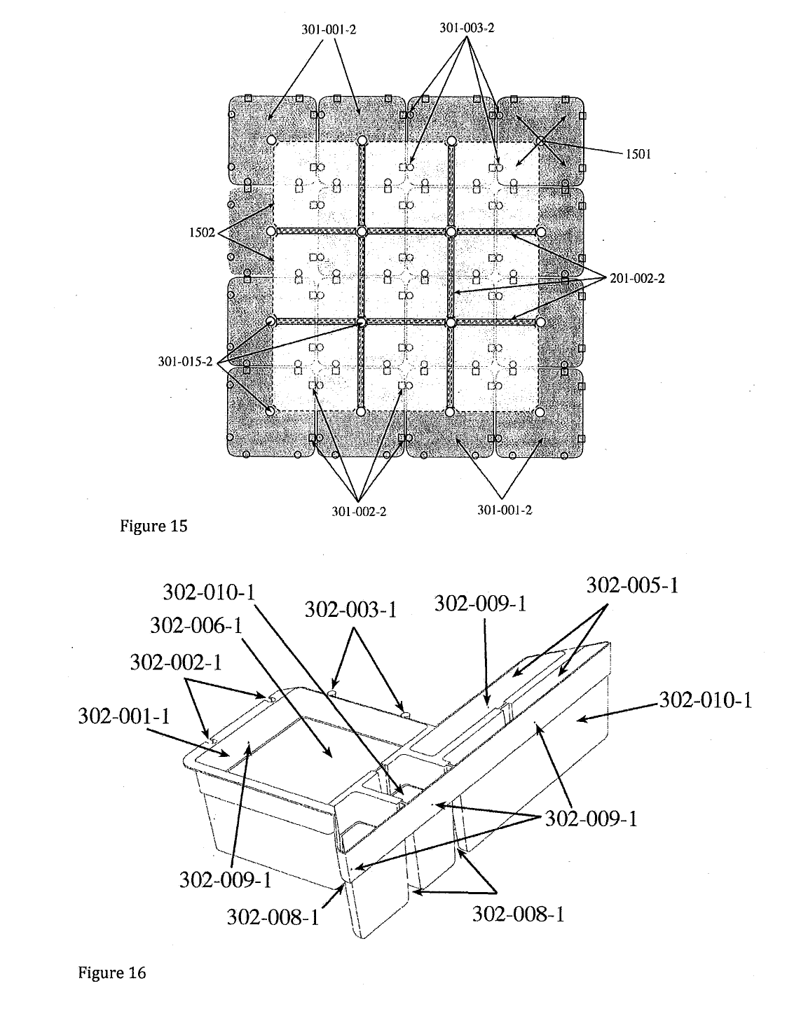

FIG. 15 illustrates: a 4×4 sq invert with a 3×3 deck [second embodiment] assembly top view layout showing the connection of, and assembly scheme;

FIG. 16 illustrates: a bottom view of the first embodiment LHS invert moulding;

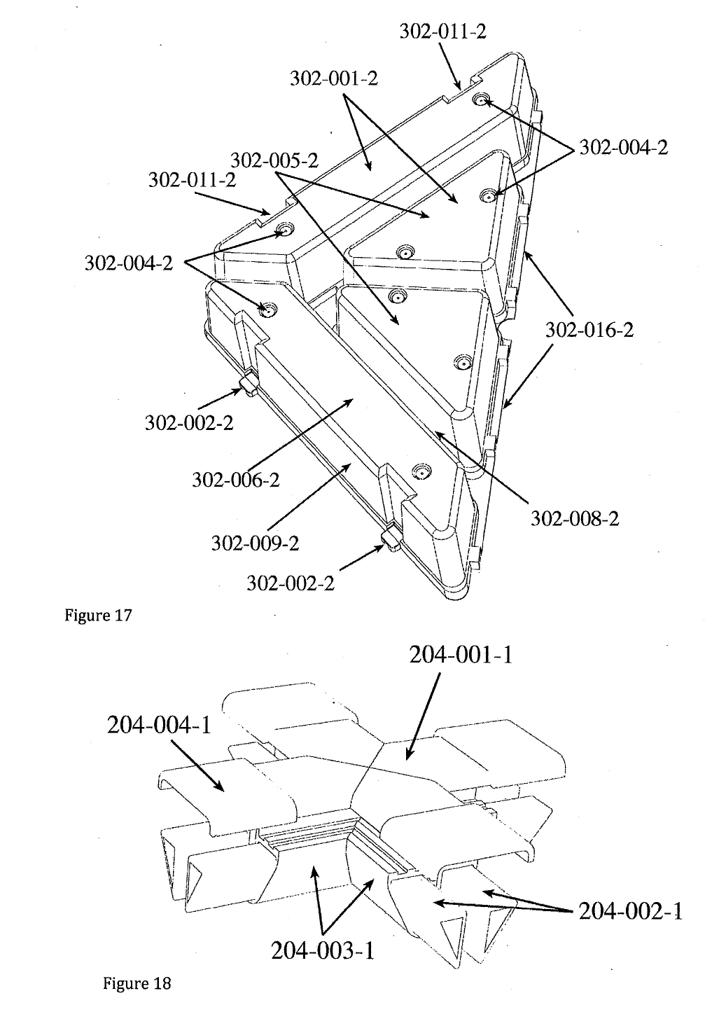

FIG. 17 illustrates: a top view of the preferred embodiment LHS square invert moulding;

FIG. 18 illustrates: the first embodiment seal ‘cross’ junction part;

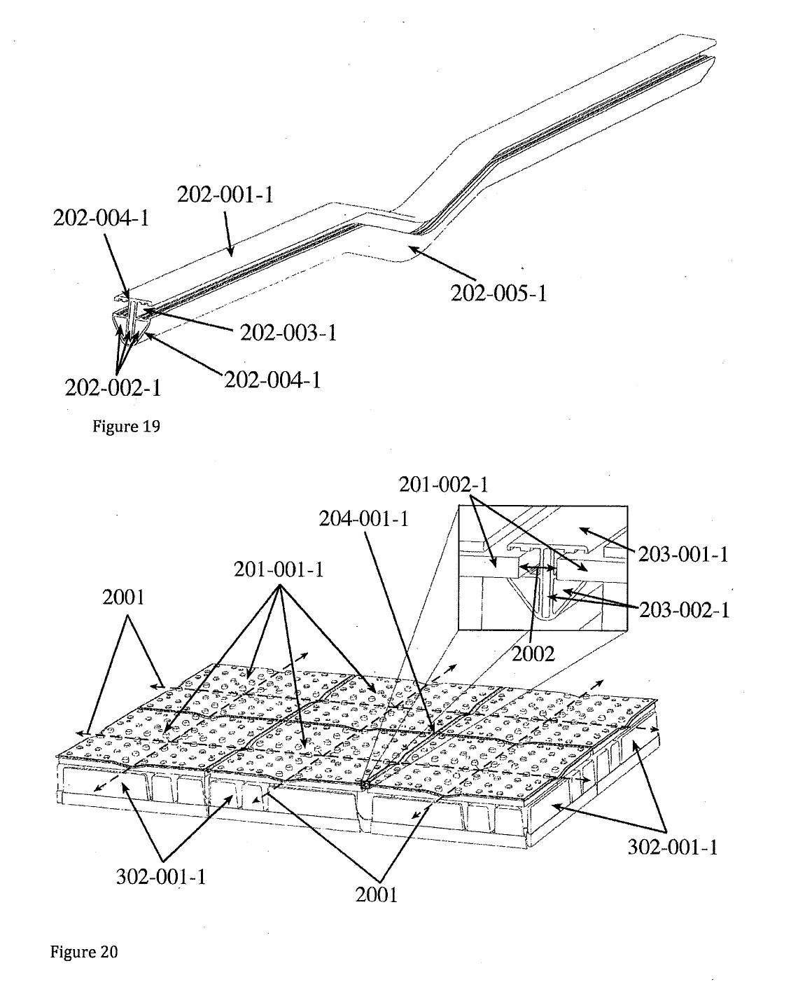

FIG. 19 illustrates: the first embodiment synthetic rubber [typically: EPDM], flexible seal extrusion with an end sectional drawing;

FIG. 20 illustrates: a 3×2 array of the first embodiment deck and invert with the inclusion of seals, seal junctions and left and right hand half invert parts. Including a magnified view of the installed seal;

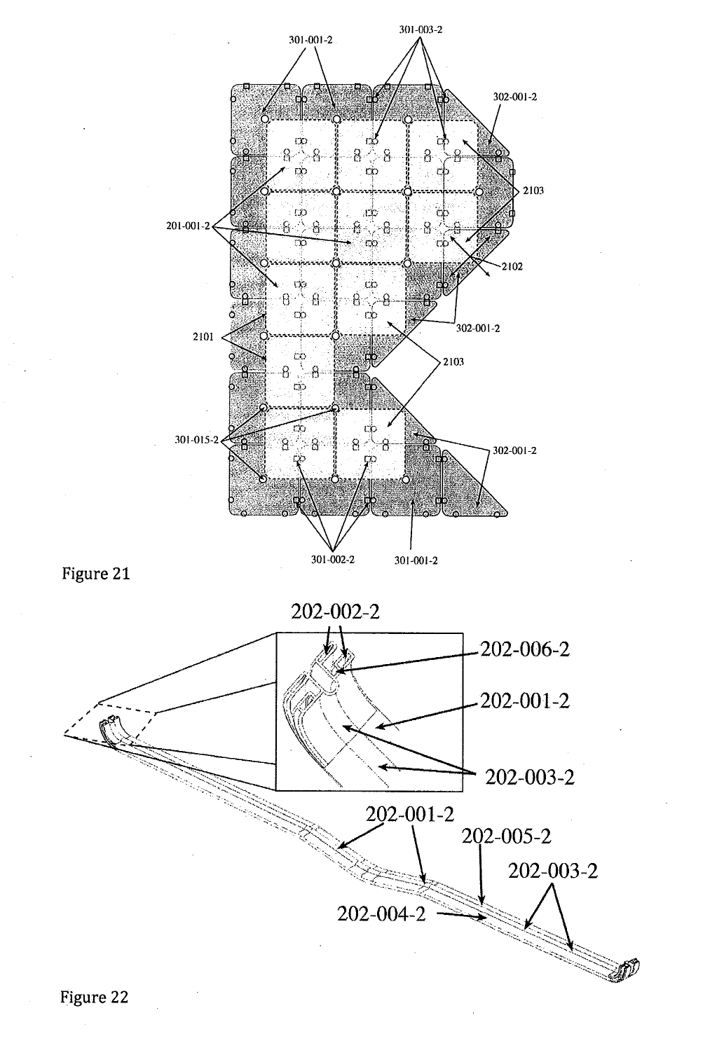

FIG. 21 illustrates: the assembly layout of the preferred embodiment deck, invert and half invert treatment of ‘ragged edges’ in the deployment;

FIG. 22 illustrates: the preferred embodiment synthetic rubber flexible seal extrusion with a magnified end sectional drawing;

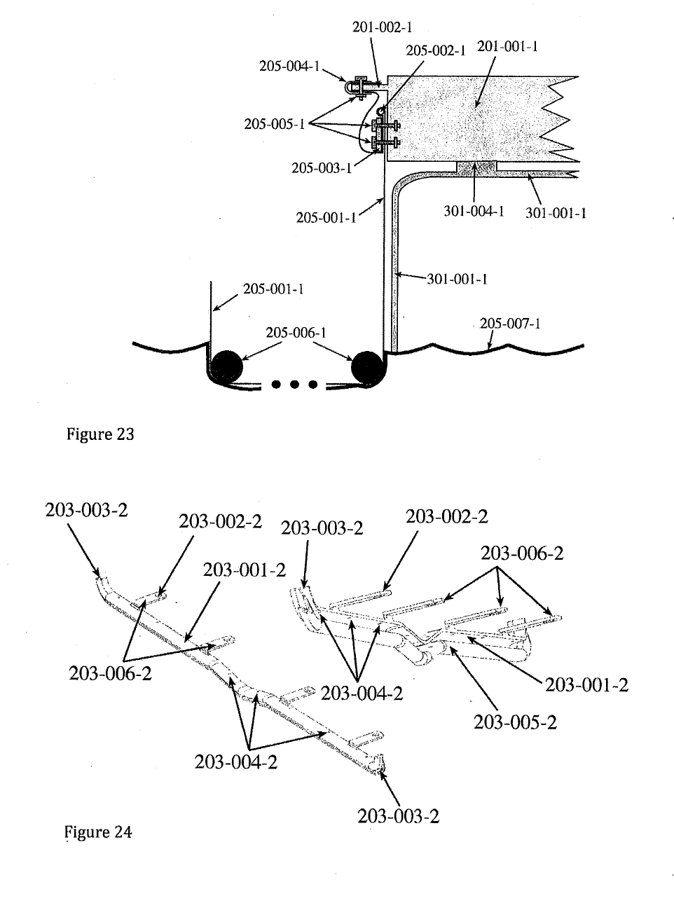

FIG. 23 illustrates: the first embodiment synthetic rubber deck attachment scheme;

FIG. 24 illustrates: the preferred embodiment geo-membrane deck-attaching bracket.

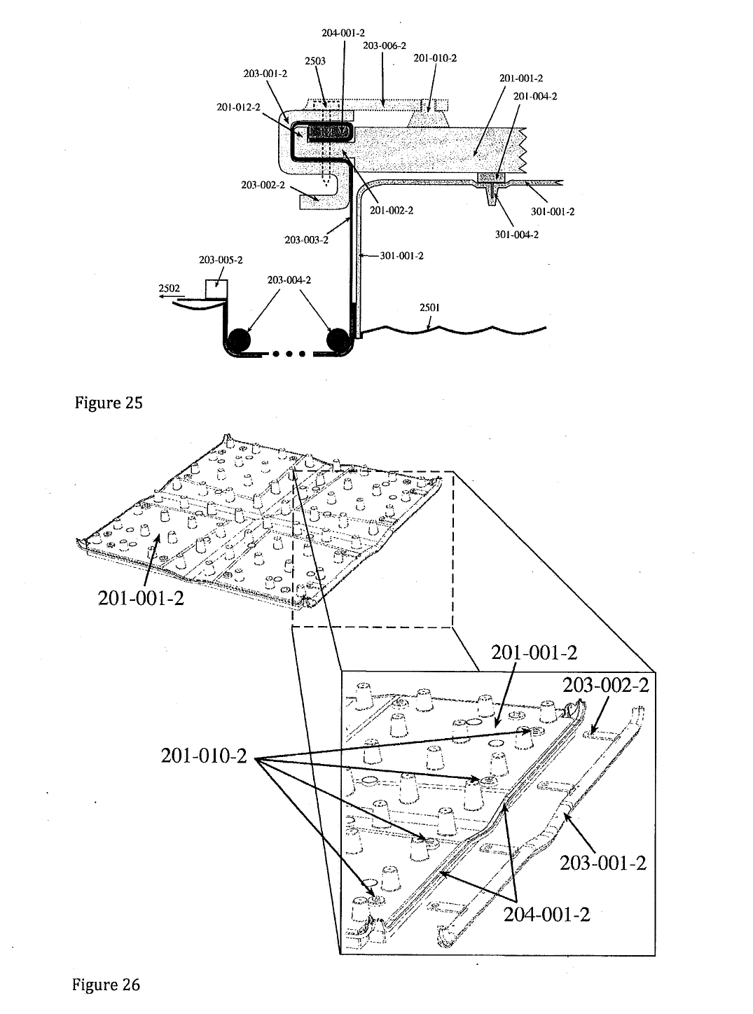

FIG. 25 illustrates: the preferred embodiment synthetic rubber deck attachment scheme, with geo-membrane, geo-membrane attachment bracket and deck;

FIG. 26 illustrates: an exploded view of the preferred embodiment of the geo-membrane attachment deck-fixing device with deck;

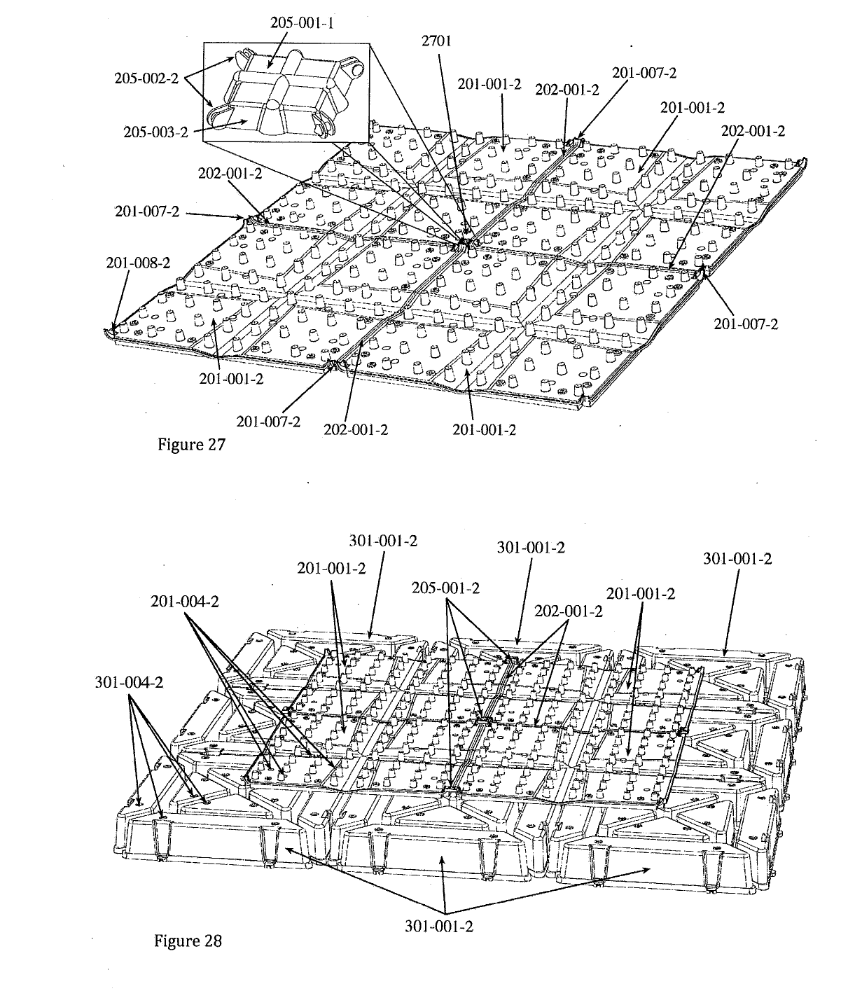

FIG. 27 illustrates: a 2×2 array of the preferred embodiment deck with the inclusion of preferred seals and seal caps;

FIG. 28 illustrates a 2×2 array [from FIG. 27], of the preferred embodiment deck fixed onto a 3×3 array of square inverts;

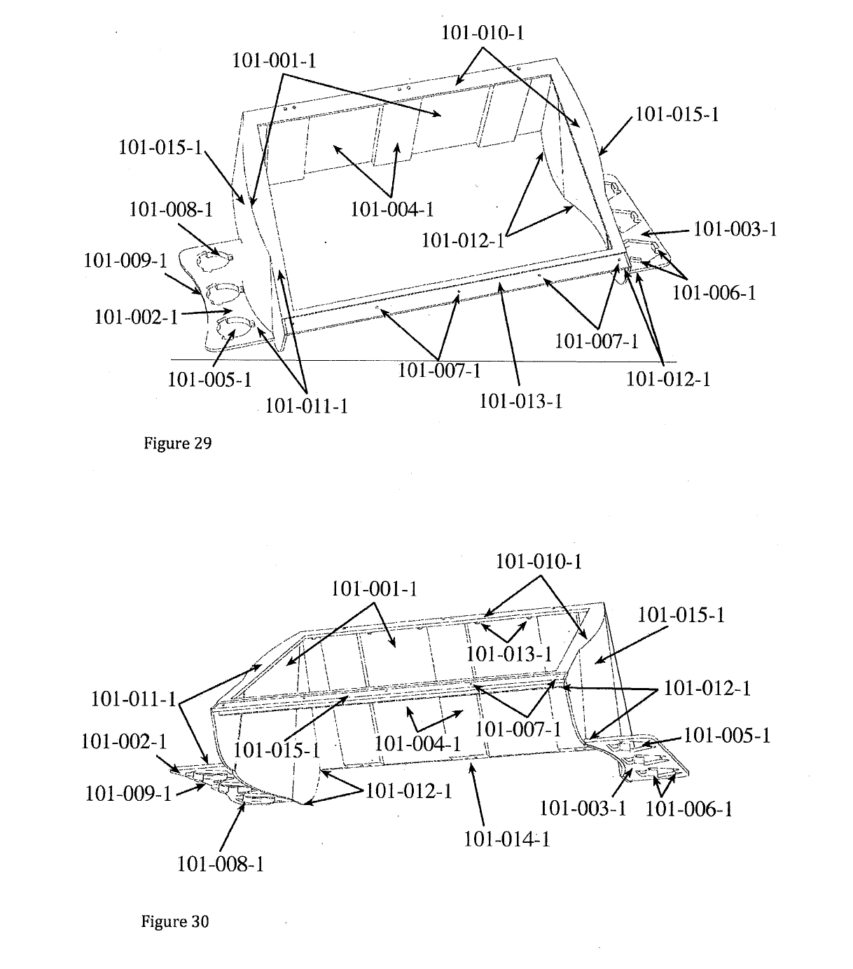

FIGS. 29 & 30 illustrate: the first embodiment of the rack with top and bottom views respectively;

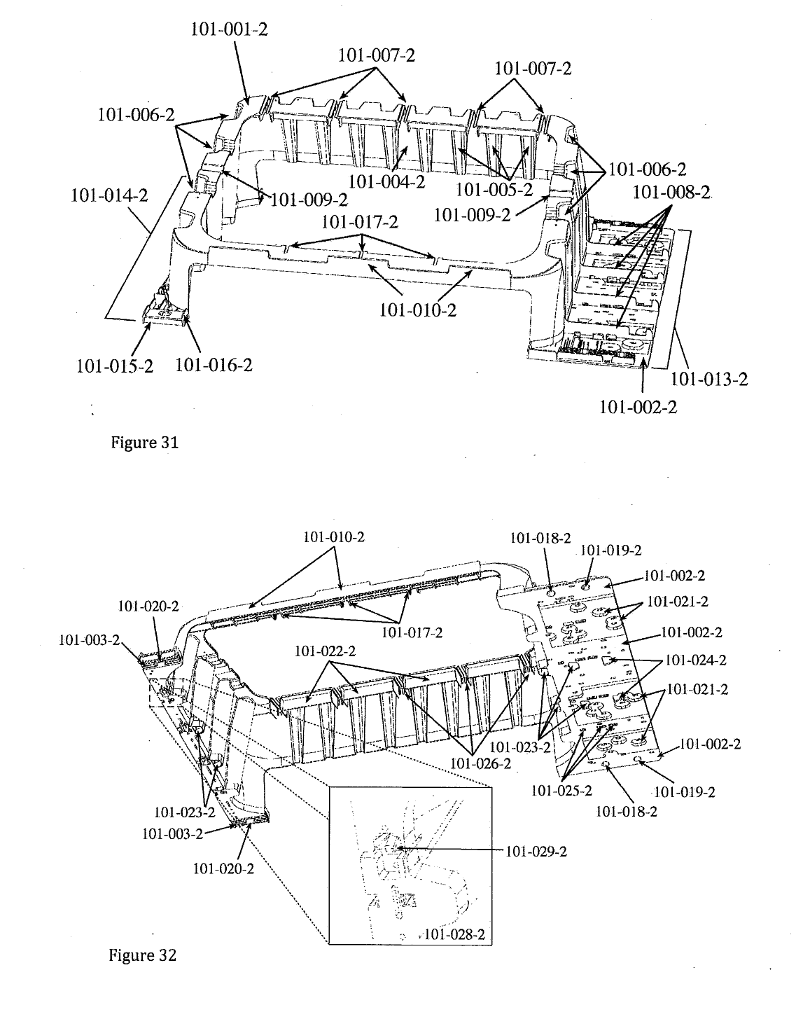

FIGS. 31, 32, 33, 34, 35 & 36 illustrate: the preferred embodiment of the rack with top, bottom, side and specific inset views;

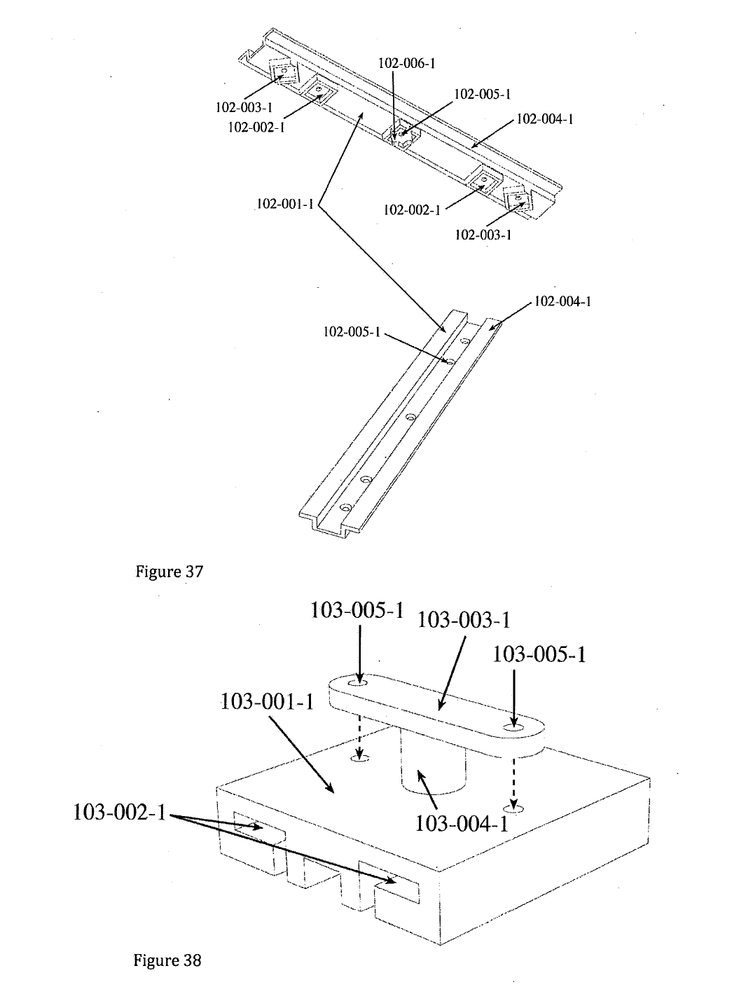

FIG. 37 illustrates: the first embodiment rail connector part;

FIG. 38 illustrates: the first embodiment sliding connector part;

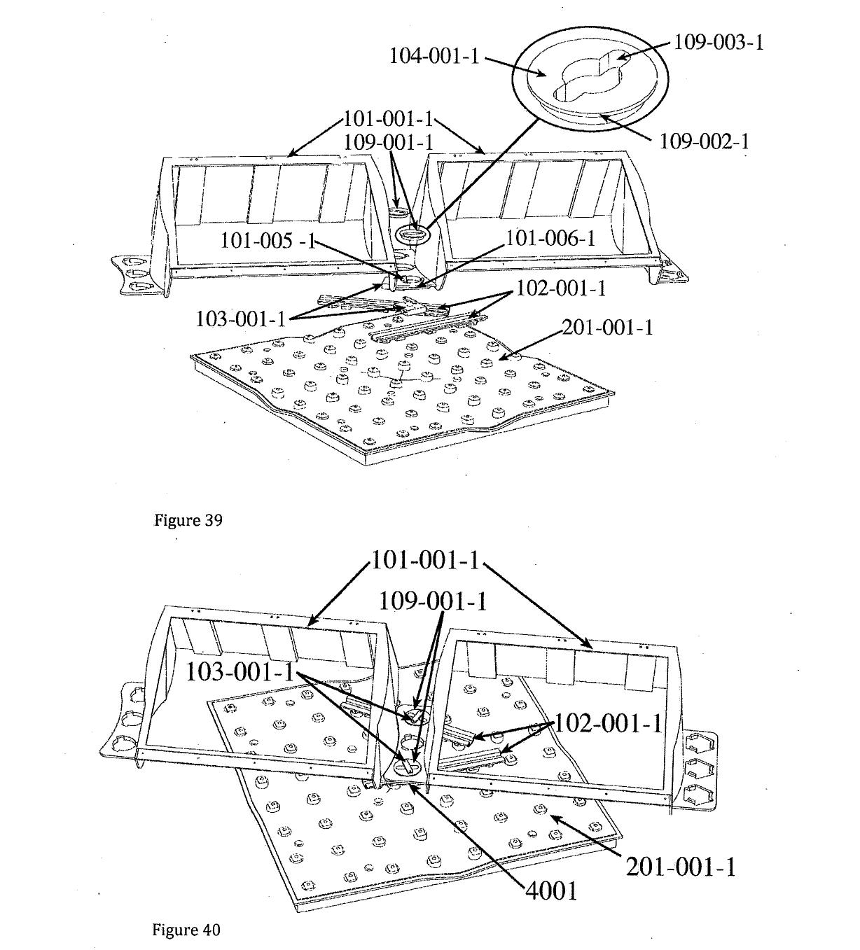

FIG. 39 illustrates: an explosion view of the first embodiment of two racks on a deck with the slotted washer, sliding and rail connector parts;

FIG. 40 illustrates: an assembly view of the first embodiment of two racks on a deck with the slotted washer, sliding and rail connector parts;

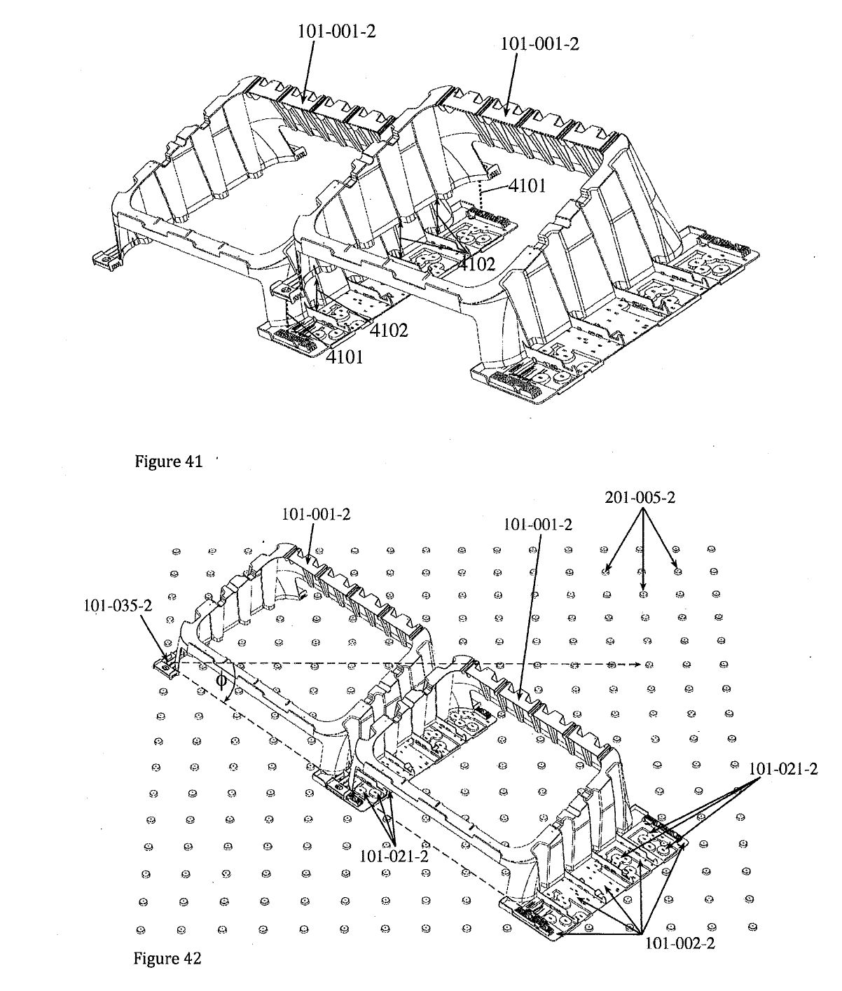

FIG. 41 illustrates: an explosion view of the preferred embodiment of a second rack ‘piggy-backed’ on the first;

FIG. 42 illustrates: an assembly of the preferred embodiment of two racks ‘piggy-backed’ and fixed to a 2×2 deck array with only the top protrusions visible;

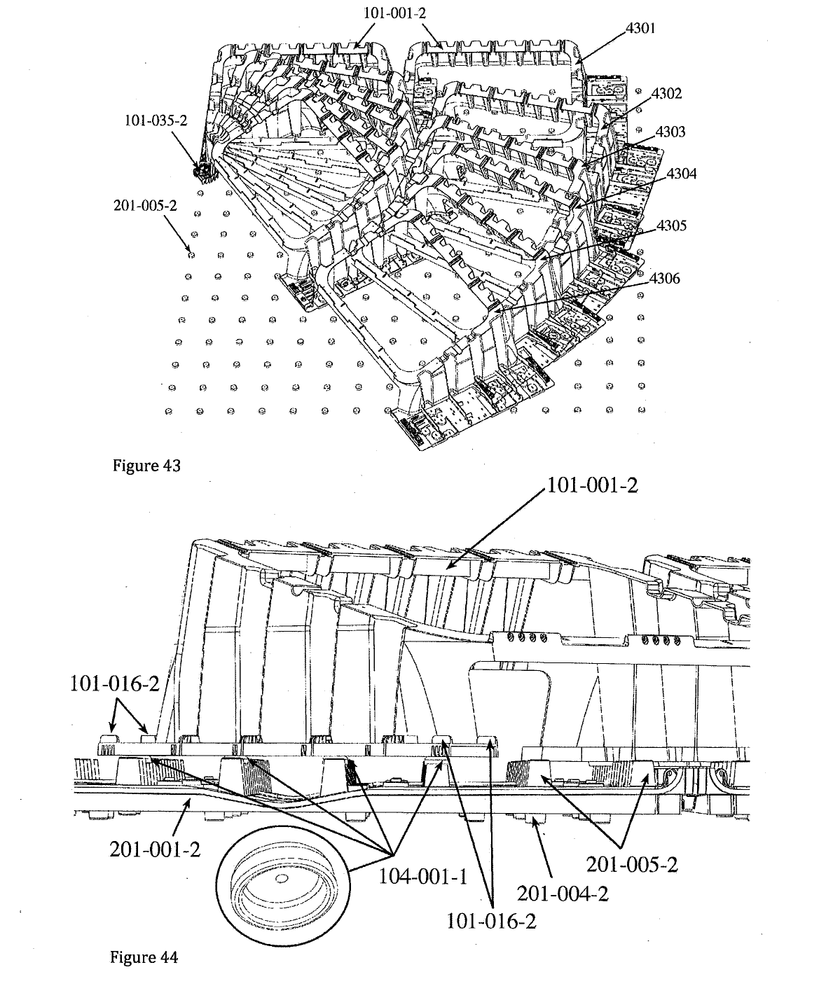

FIG. 43 illustrates: A 2×2 deck array with a double rack row at six different angles;

FIG. 44 illustrates: the preferred deck rack support extrusion first column-levelling cap;

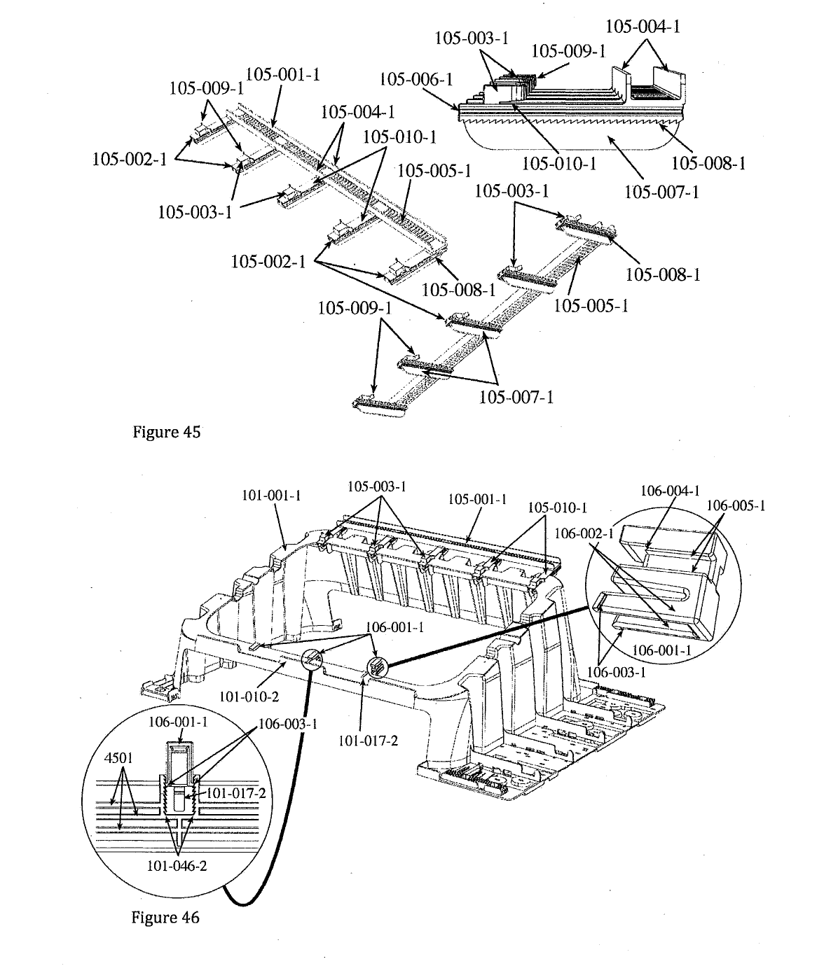

FIG. 45 illustrates: two views of the preferred embodiment of the rack PV panel adjustable fixing slide and integrated cable management part;

FIG. 46 illustrates: the preferred embodiment of the rack rear PV panel adjustable fixing slide with integrated cable management and the front zip clip—both identified and fitted to a rack;

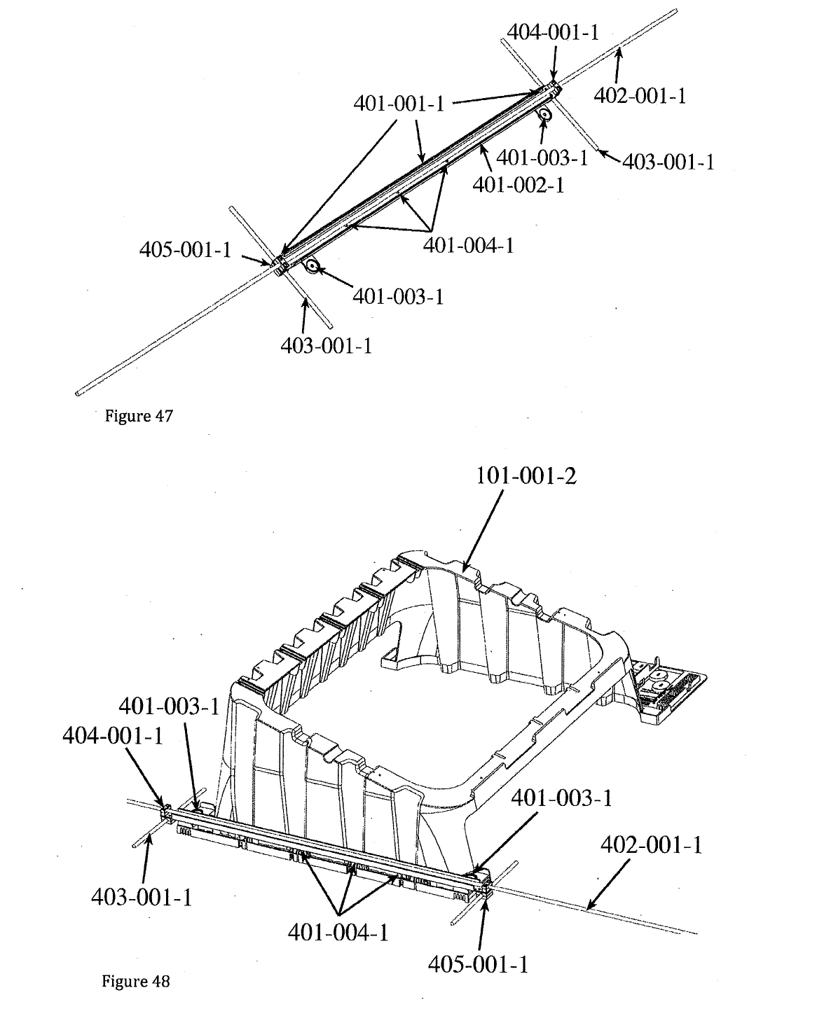

FIG. 47 illustrates: the preferred embodiment of the rack tendon support bracket with cable [tendon] clamps;

FIG. 48 illustrates: the preferred embodiment of the rack tendon support bracket with cable [tendon] clamps assembled in position on a rack;

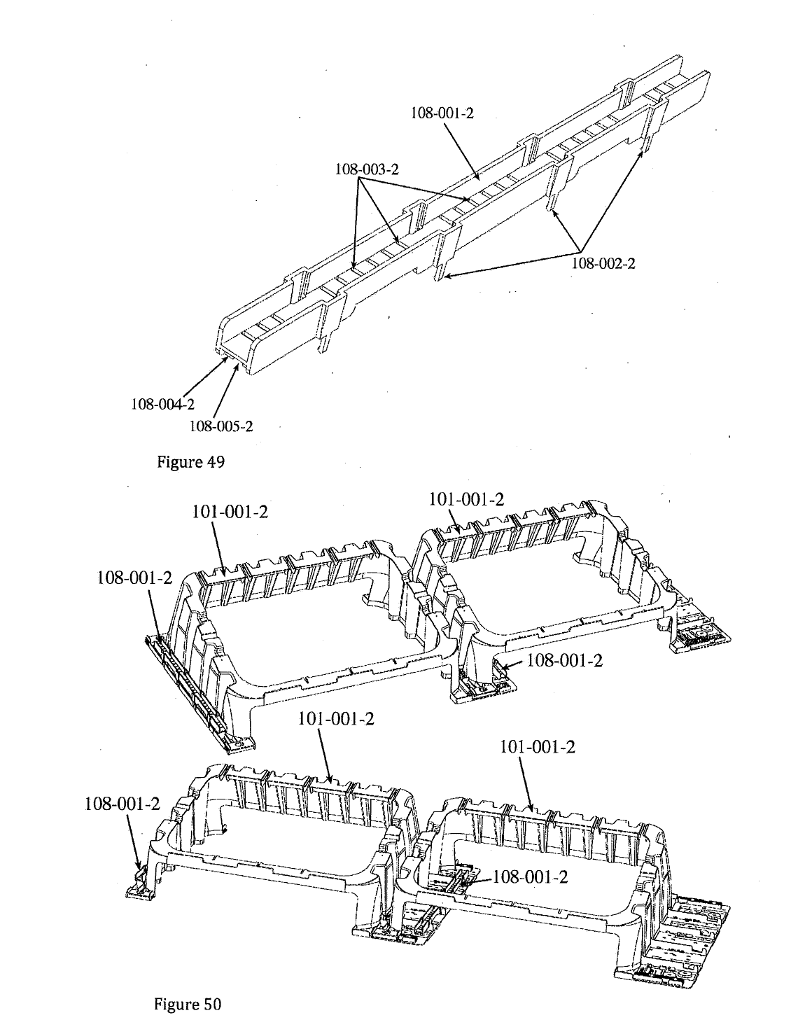

FIG. 49 illustrates: the preferred embodiment of the rack cable management tray;

FIG. 50 illustrates: two views of the preferred embodiment of the rack cable management tray assembled in two positions on two piggybacked racks;

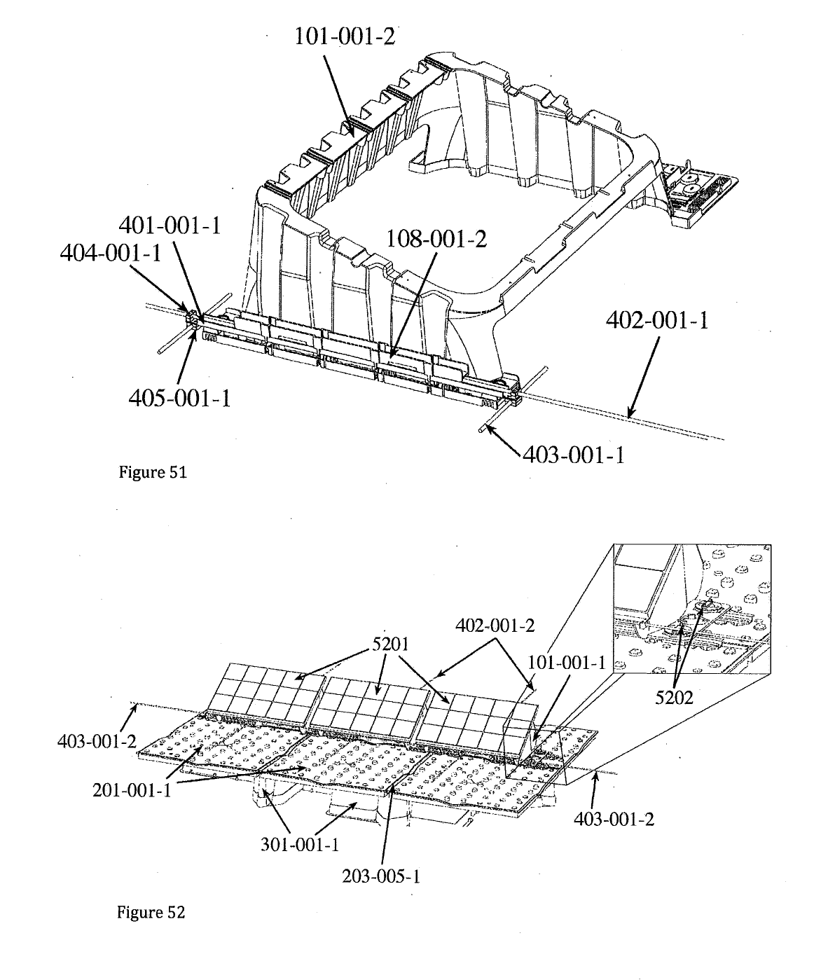

FIG. 51 illustrates: the preferred embodiment of the rack cable management tray assembled on top of the rack tendon support system attached to a rack;

FIG. 52 illustrates: the first embodiment of an assembly of a row of three PV panel & rack assemblies on top of a 3×2 deck array;

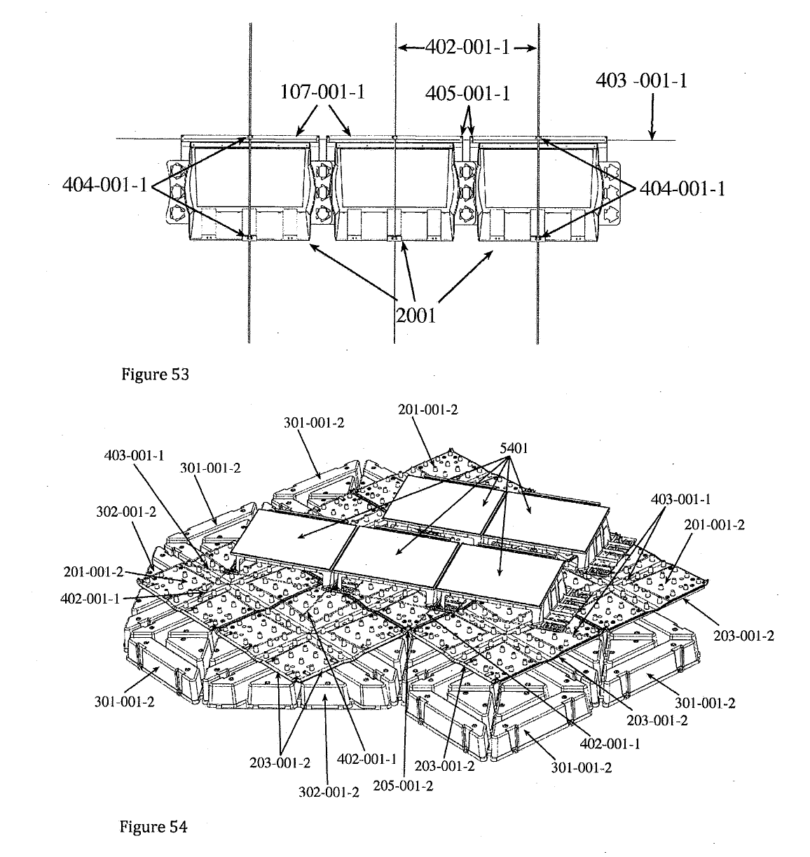

FIG. 53 illustrates: the first embodiment of the underside view of a row of three racks & PV panel assemblies clearly illustrating the positions of the tendons and fixings;

FIG. 54 illustrates: the preferred embodiment of an assembly of five PV panel, rack & tendon assemblies on top of a 3×3 [with one deck removed], deck array with invert substructure;

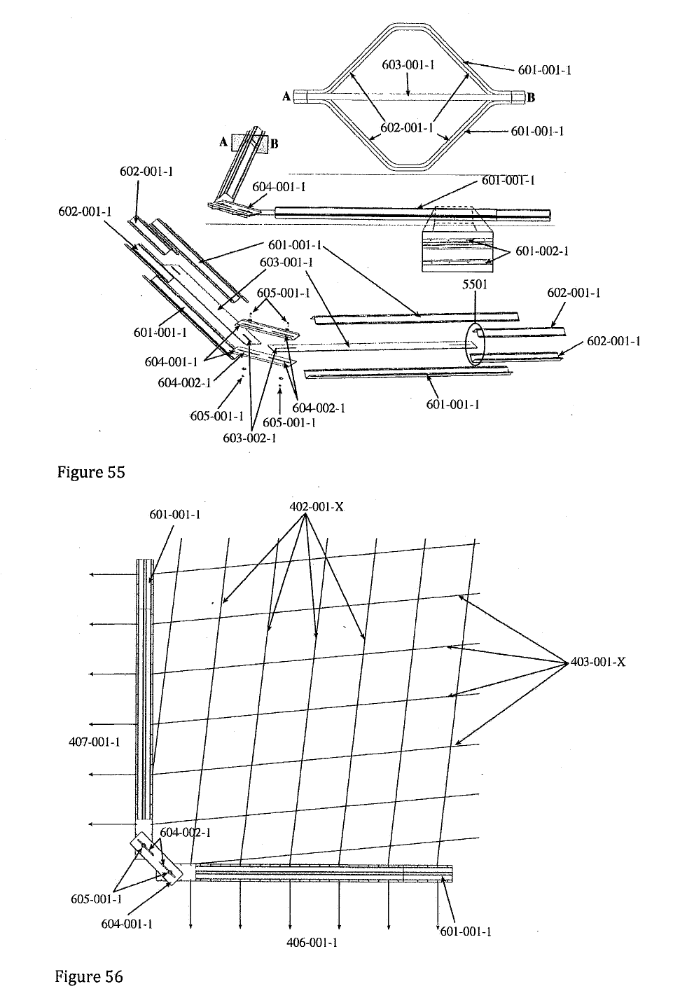

FIG. 55 illustrates: an explosion and sectional diagram of the preferred metal embodiment of the transfer beam planar expansion slide, extension coupling and associated parts;

FIG. 56 illustrates: a diagram of the preferred embodiment of the transfer beam elucidated with tendons (inner array fixing & positioning cables) and tethers (storage position maintaining and system tensioning cables);

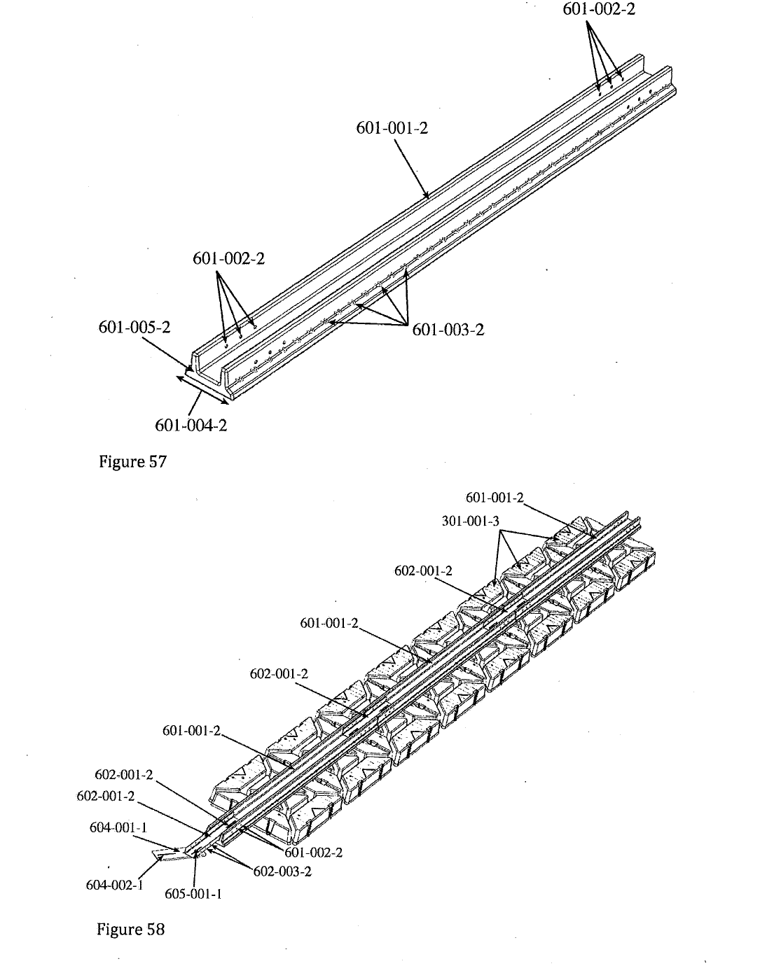

FIG. 57 illustrates the reinforced variable density concrete transfer beam part (length not to scale);

FIG. 58 illustrates a series of three concatenated variable density concrete (transfer) beam parts, placed on a row of supporting (floating) inverts and the planar expansion slide;

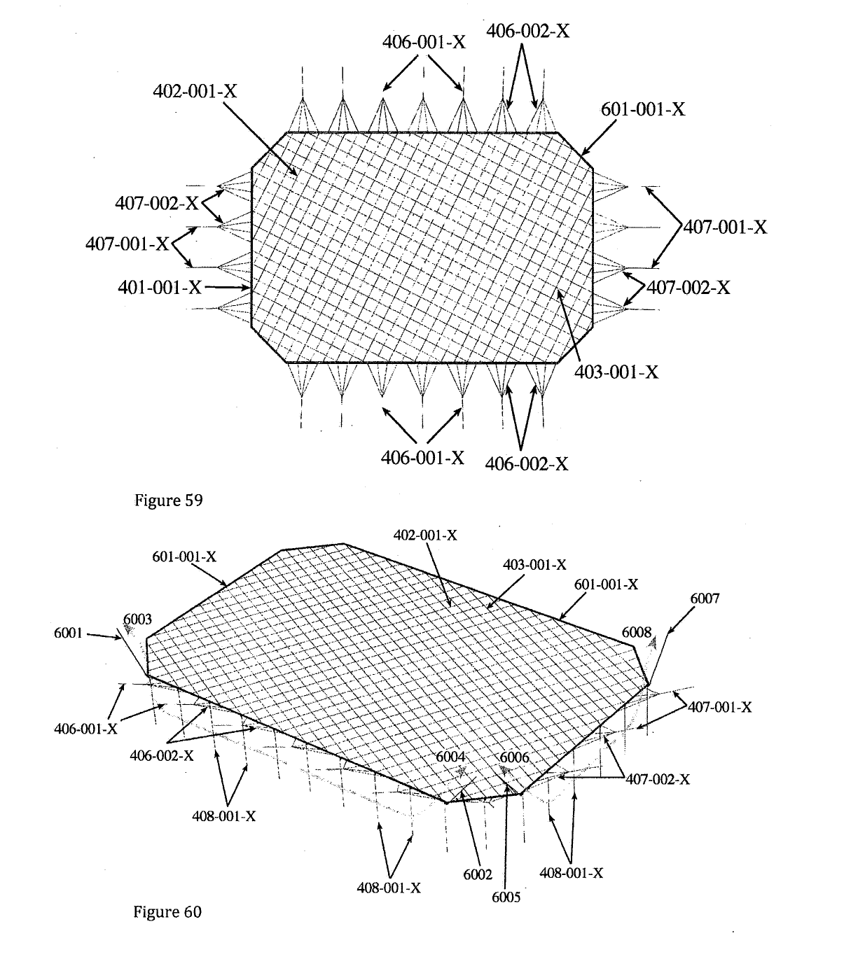

FIG. 59 illustrates: the preferred embodiment of a top view of the skewed tendons of a typical storage with surrounding transfer beam with the external tethering normal to the transfer beam [which runs parallel to the storage shoreline];

FIG. 60 is an isometric [3D], drawing of FIG. 59, illustrating the vertical restraints and the inclination of the tethering;

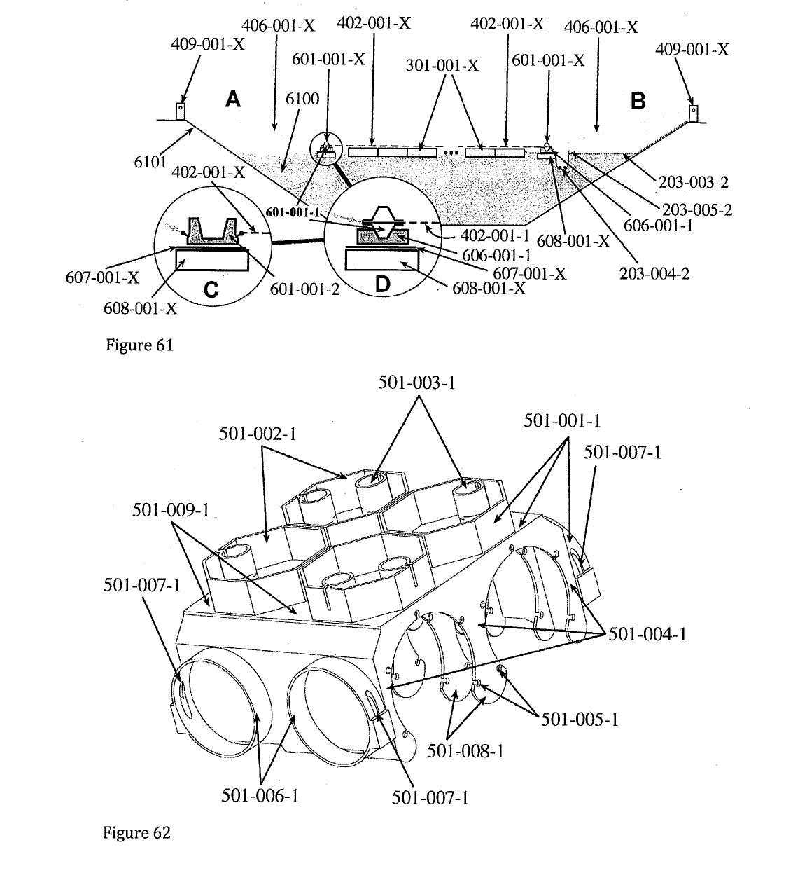

FIG. 61 illustrates a typical storage section elucidating the two possibilities (for low wind areas not requiring ground restraints):
1. Water reuse—no/or limited cover [A];
2. Potable/partially treated water—full cover [B].

FIG. 62 illustrates: a third floatation embodiment of a pipe adaptor part, of which one plugs into each of the four corners of the top part. This part can be oriented in any of four positions. The adaptor incorporates dual ribbing designed to support piping, and lockable receptacles, designed to fix the end caps of piping;

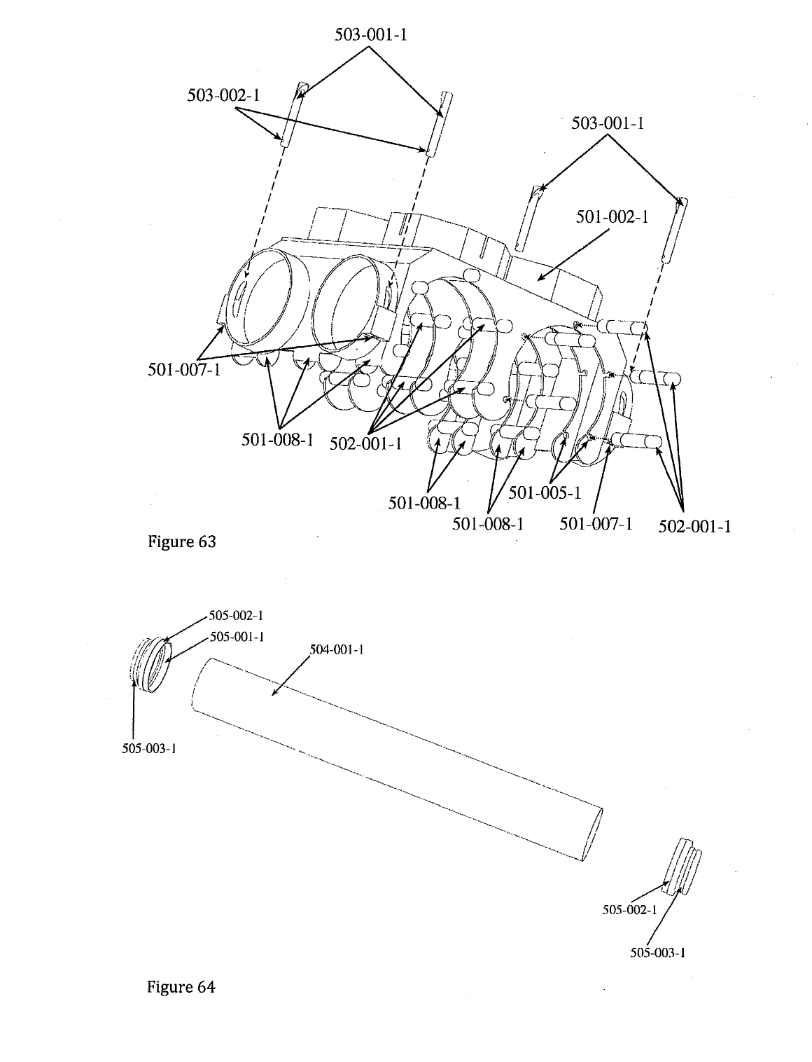

FIG. 63 illustrates: a third floatation embodiment of the position of locking pins of the pipe adaptor; with the insertion of rollers to allow the pipe inserts movement around and in the direction of, the central axis of the said pipe;

FIG. 64 illustrates: a third floatation embodiment of the pipe and end caps;

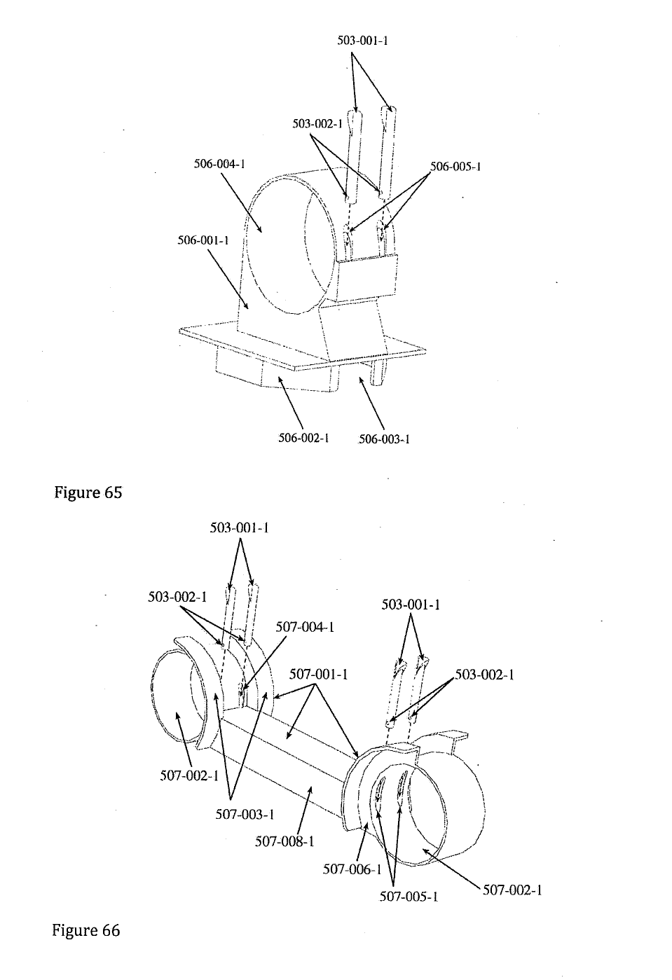

FIG. 65 illustrates: the third floatation embodiment of a plug in [to the top part], pipe end cap docking & locking device. The purpose of this device is to arrest end travel [axis inline] movement;

FIG. 66 illustrates: a third floatation embodiment of an inter row articulation part. The part locks two end caps via the locking pins without restricting pipe movement around the pipe axes of the pipe and the said articulation part;

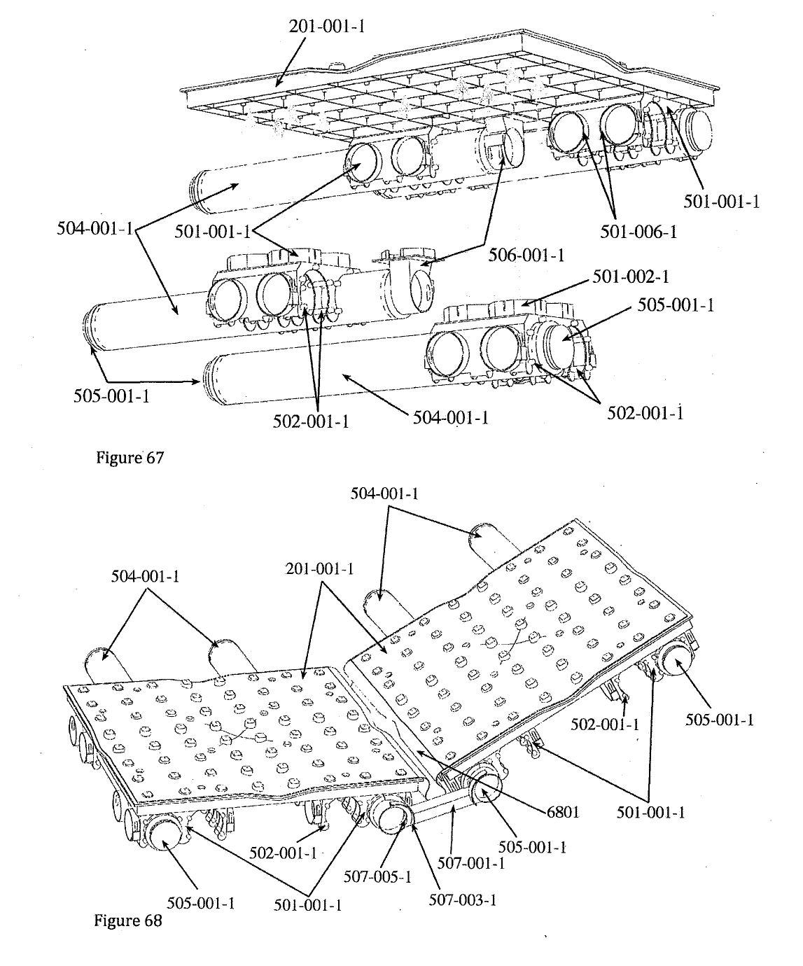

FIG. 67 illustrates: a third floatation embodiment of a partly exploded view of the complete assembly of the top part with four pipe adaptors, four pipes with end caps and two docking devices;

FIG. 68 illustrates: a third floatation embodiment of two complete assemblies [described above], articulated via the row articulation part, with the placement of a Hypalon [or similar] geo-membrane sheet at the joint;

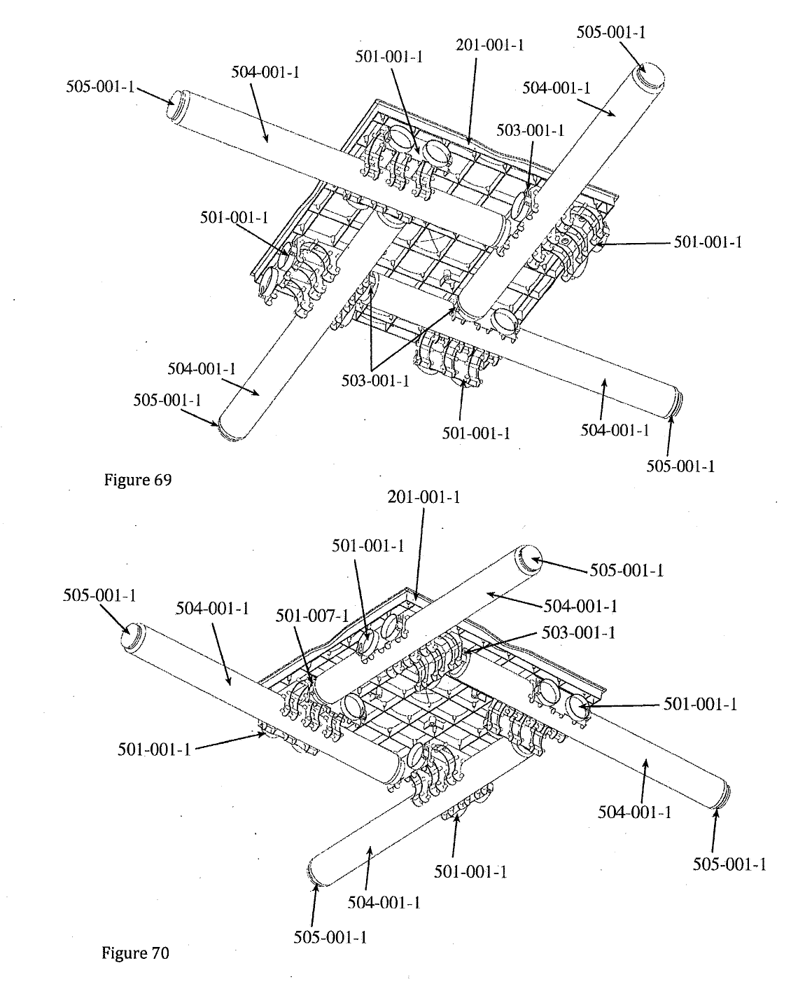

FIG. 69 illustrates: a third floatation embodiment of another configuration of the pipe adaptor part. This time each part is oriented so that only one ribbing axis is allowed per top part side. The part also illustrates four pipes [with end caps], fixed in the centre most positions;

FIG. 70 is identical to FIG. 69 except that the four pipes [with end caps], are fixed in the outer most positions;

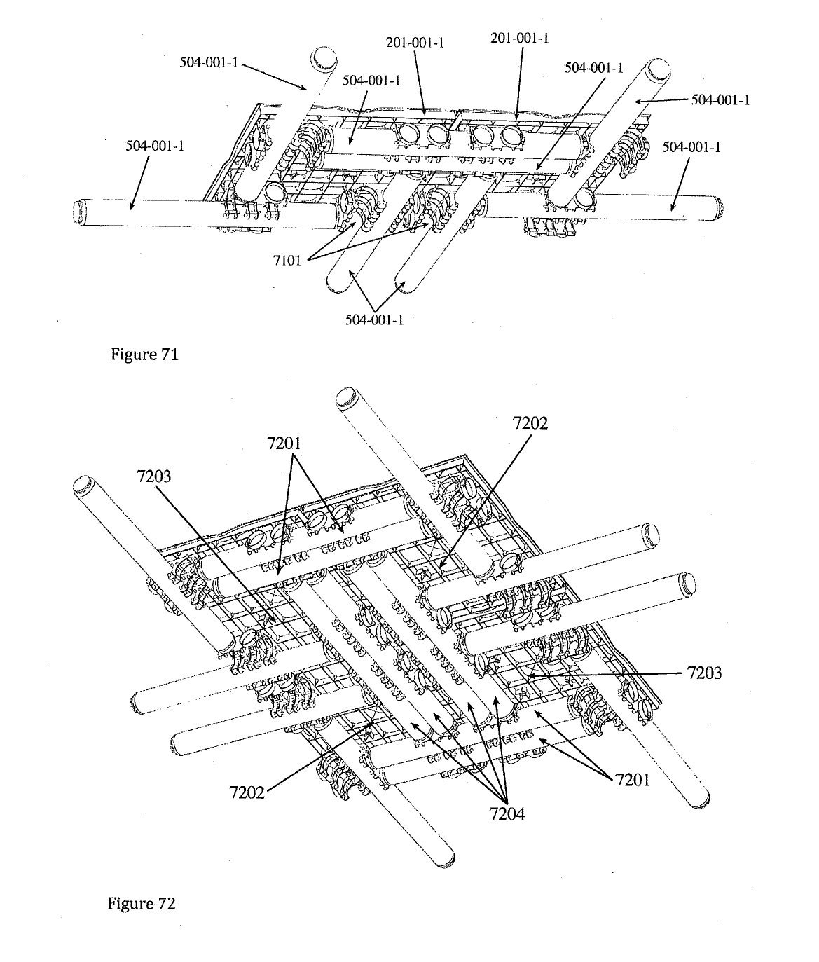

FIG. 71 illustrates: the assemblies of FIGS. 69 & 70;

FIG. 72 illustrates: the assembly of two assemblies as illustrated in FIG. 71, to form a basic CP building block. Note the central piping in the assembly imparting structural strength to the assembly;

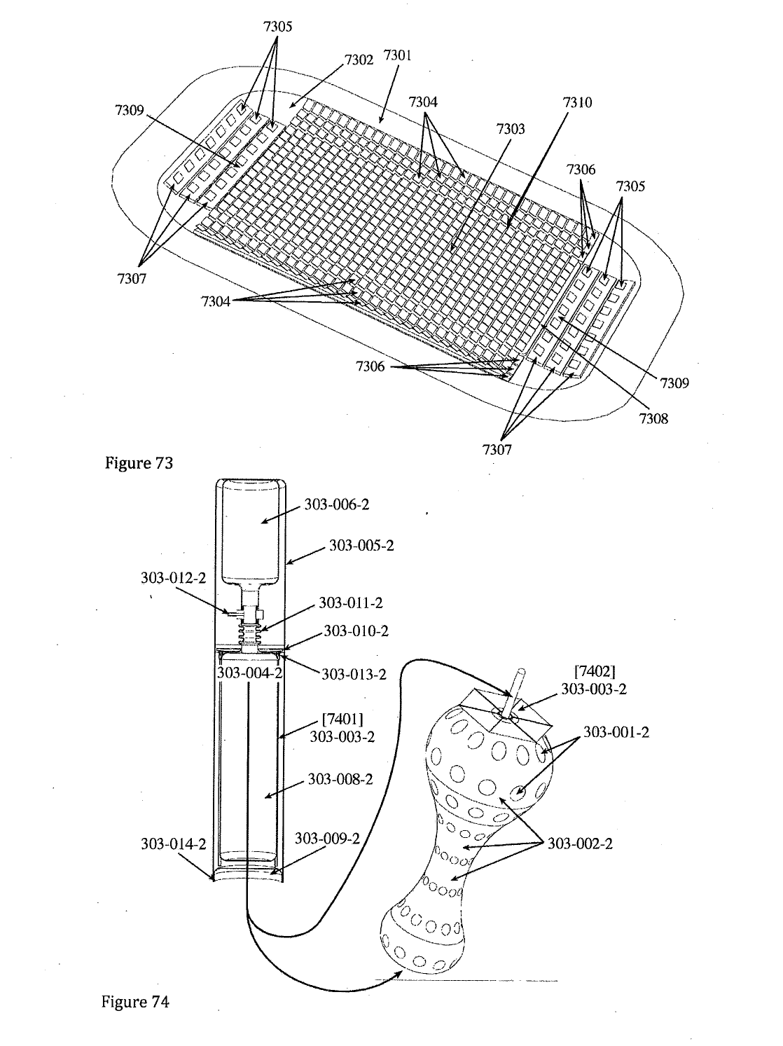

FIG. 73 illustrates: an implementation of the third floatation embodiment in a small North orientated storage with a slope wings population.

FIG. 74 illustrates: The canister section denoting the main part positions of the inflatable balloon prop—with balloon prop bundled in the canister and deployed;

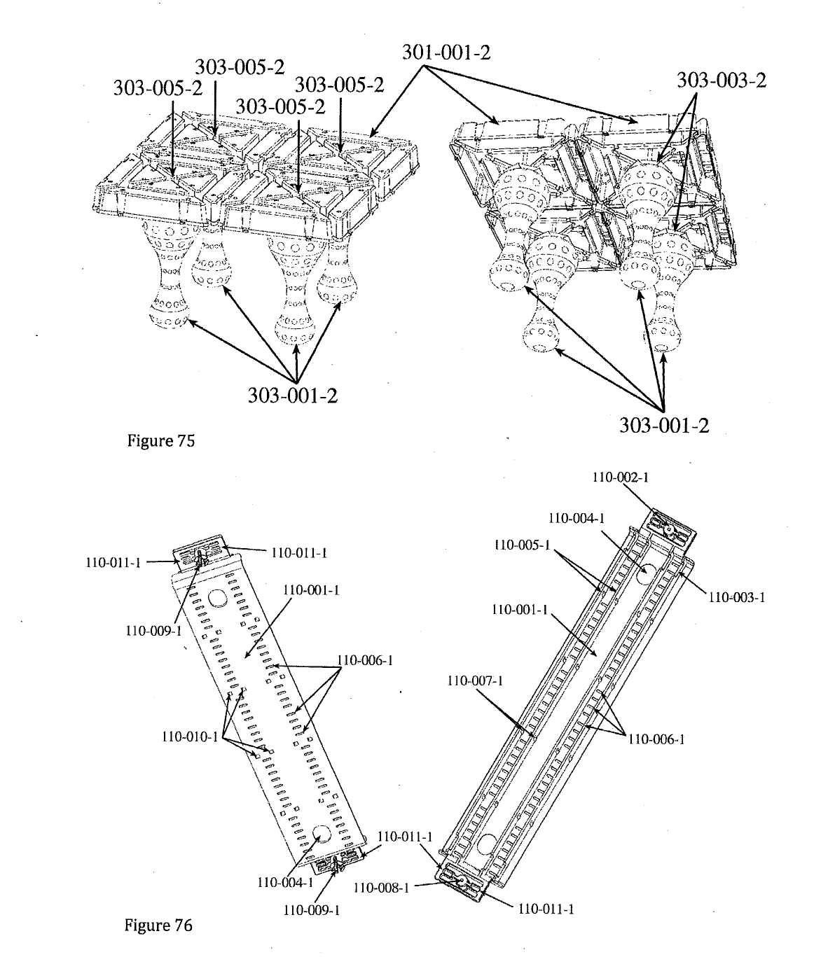

FIG. 75 illustrates: Top and bottom views of the preferred embodiment 2×2 invert array with four props deployed;

FIG. 76 illustrates: a diagram of the preferred embodiment of two views of the separator;

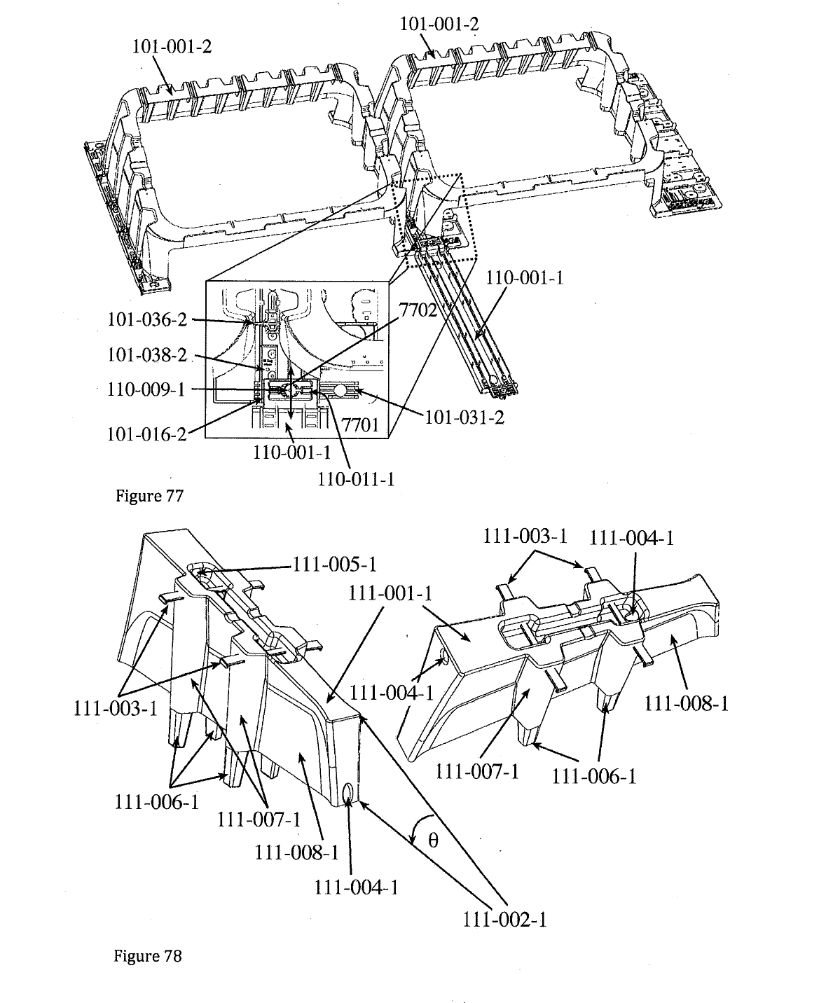

FIG. 77 illustrates: a diagram of the preferred embodiment of the separator connected to two racks;

FIG. 78 illustrates: a diagram of the preferred embodiment of two views of the ballast wedge;

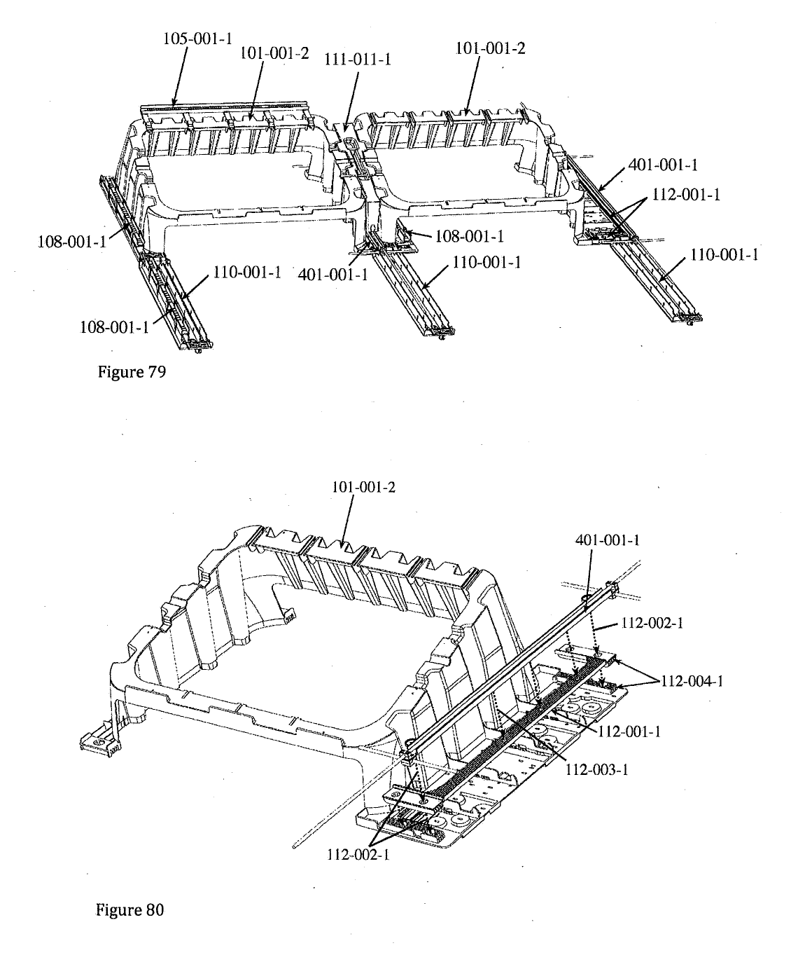

FIG. 79 illustrates: a diagram of the preferred embodiment of the roof racking assembly without the PV panels;

FIG. 80 illustrates: an exploded view of the preferred rack embodiment with fixing buffer and tendon bracket;

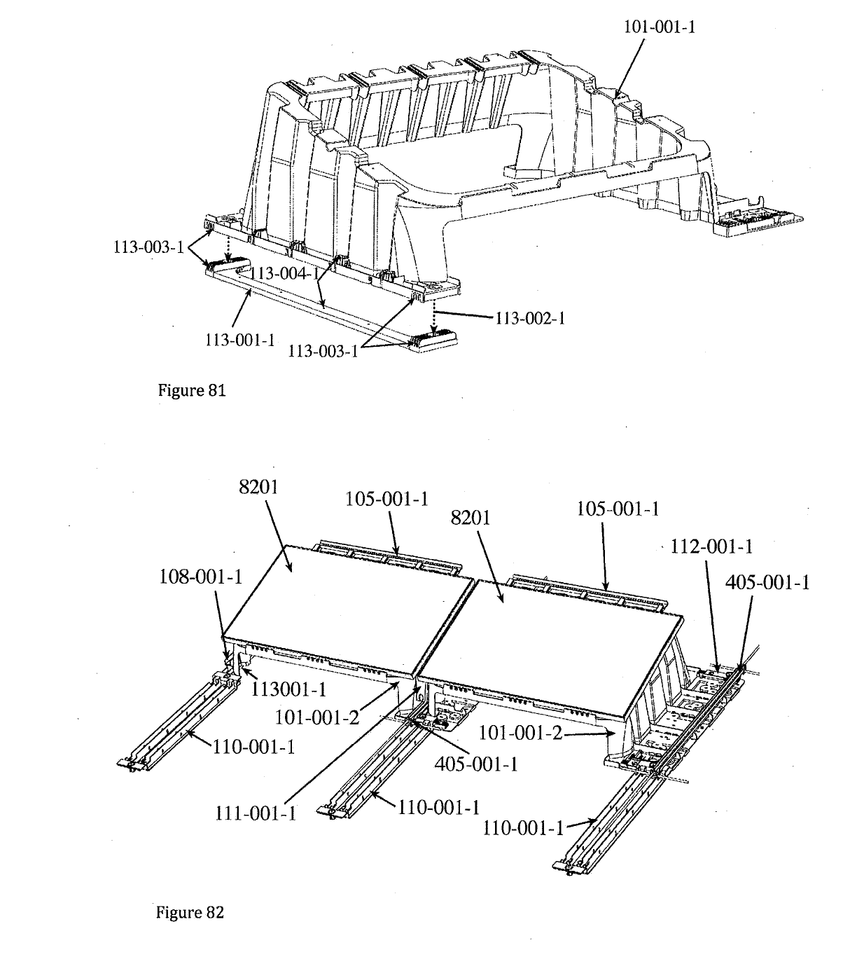

FIG. 81 illustrates: an explosion diagram of the preferred embodiment of the rack with pivot buffer part;

FIG. 82 illustrates: a diagram of the preferred embodiment of the complete roof racking assembly;

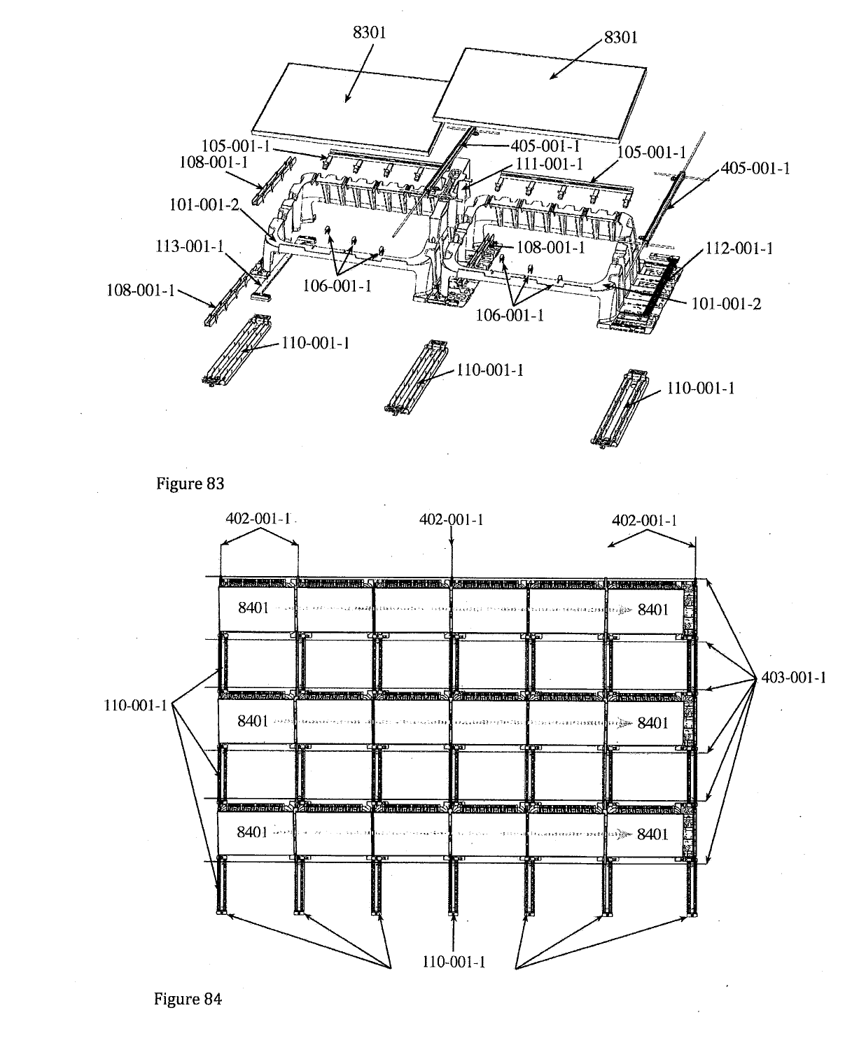

FIG. 83 illustrates: an explosion diagram of the preferred embodiment of FIG. 82 [above];

FIG. 84 illustrates: the preferred embodiment of the top view of an array of 6×3 PV panel, rack, separator & tendon assemblies;

FIG. 85 illustrates an isometric drawing of the preferred ‘production model’ rack specifically modified to reduce part numbers [eliminating the ‘buffer parts’] adding the capacity for a two position concatenation system, whilst retaining thermal expansion capability;

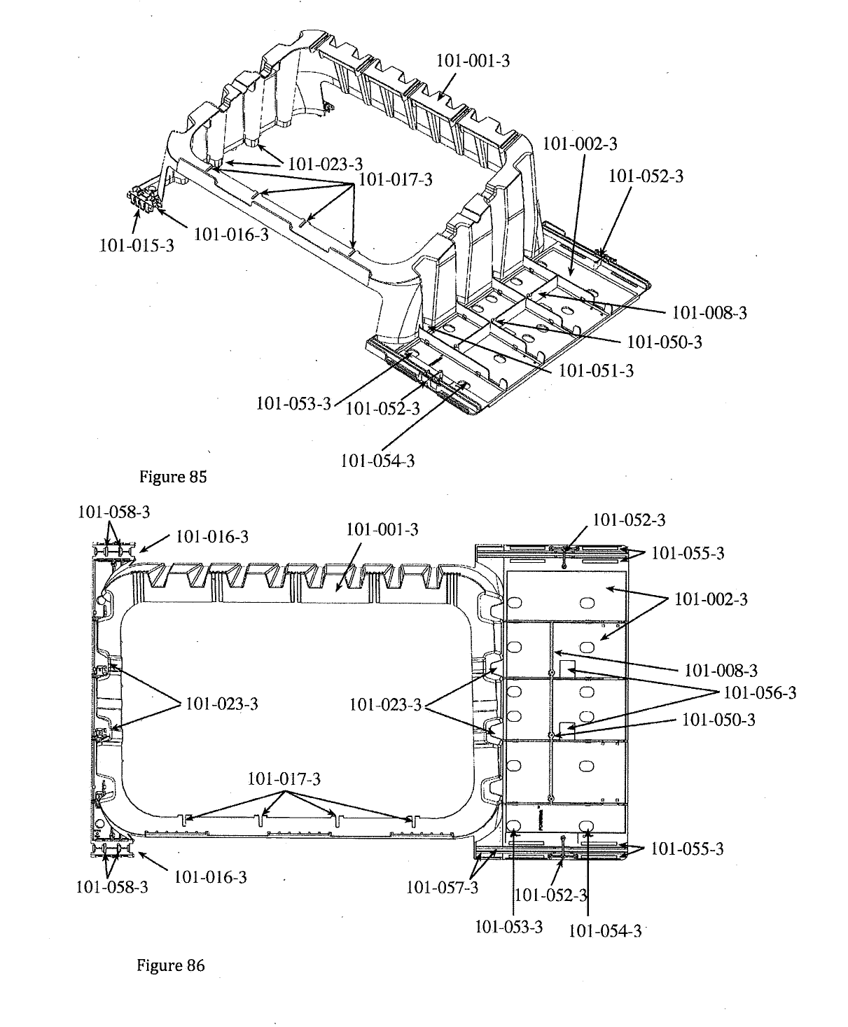

FIG. 86 illustrates the top view of the production model of the rack;

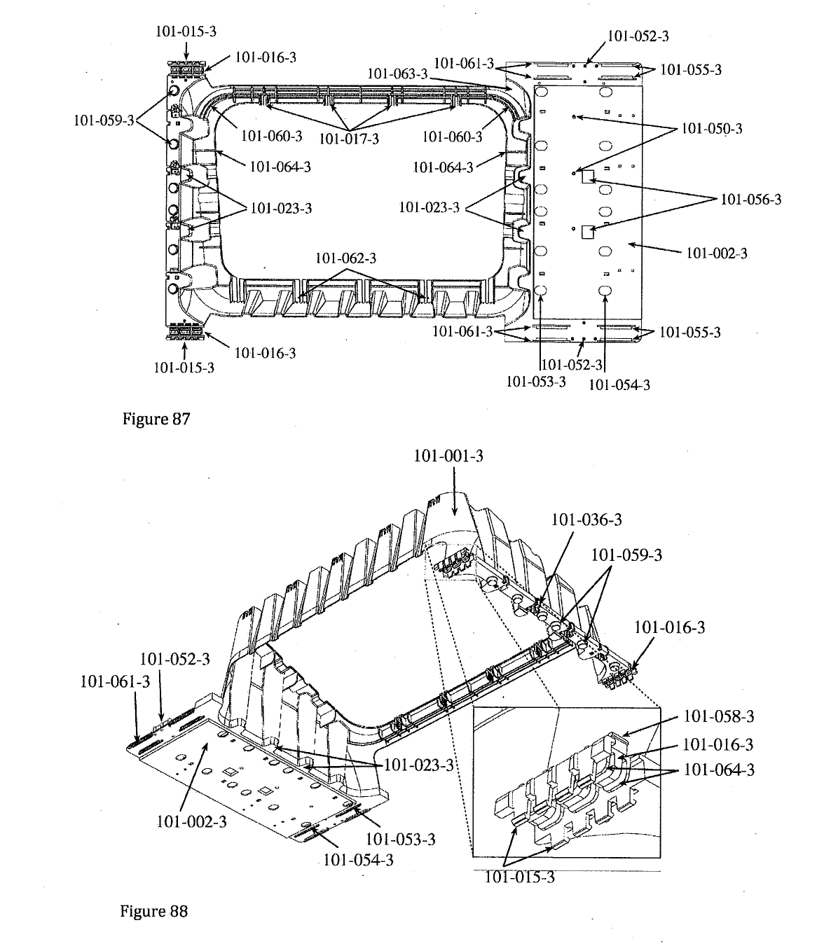

FIG. 87 illustrates the bottom view of the production model of the rack;

FIG. 88 illustrates a bottom isometric view of the production model rack;

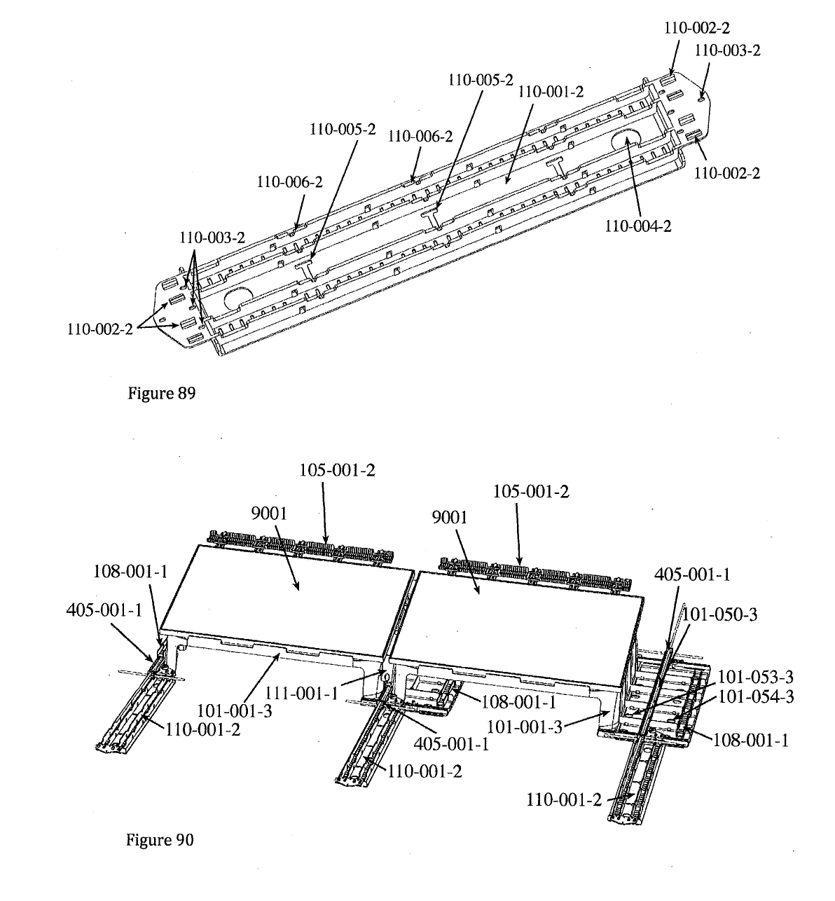

FIG. 89 illustrates modified separator to accommodate the linking design changes of the rack;

FIG. 90 illustrates the rack production model complete assembly accommodating the shorter 1662 mm [65.43″], PV panels;

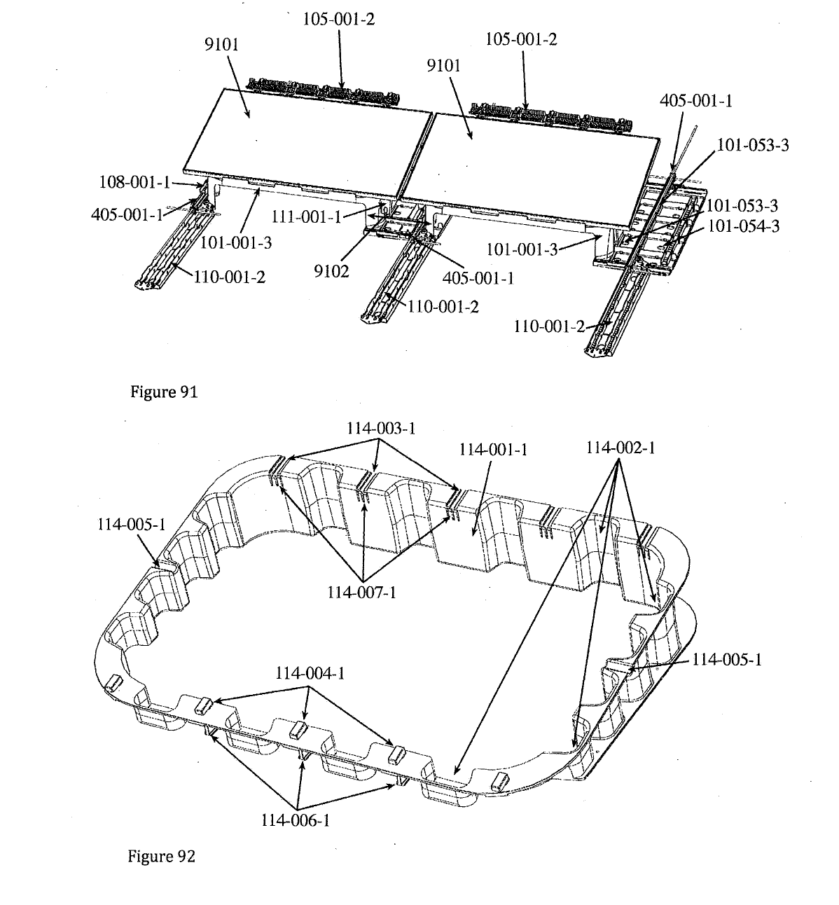

FIG. 91 illustrates the rack production model complete assembly accommodating the longer 1962 mm [77.24″], PV panels;

FIG. 92 illustrates: a diagram of the top view of the preferred embodiment of a reversible 10-degree angle adaptor;

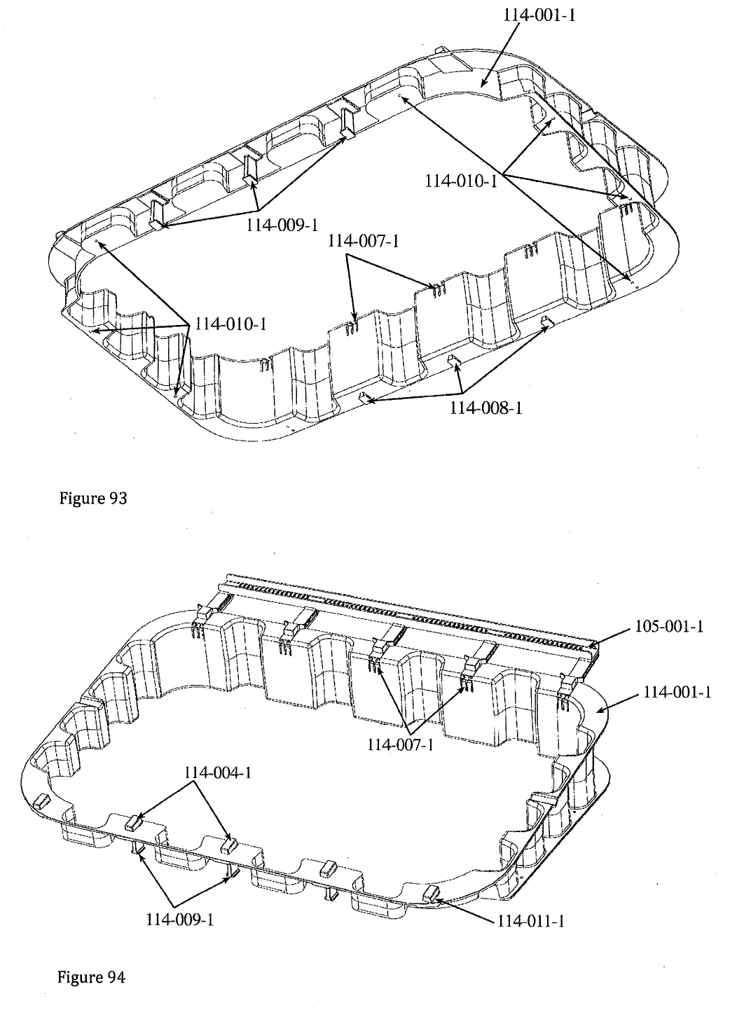

FIG. 93 illustrates: a diagram of the bottom view of the preferred embodiment of a reversible 10-degree angle adaptor;

FIG. 94 illustrates: a diagram of the preferred embodiment of a reversible 10-degree angle adaptor with attached adjustable sliding PVP fixing part;

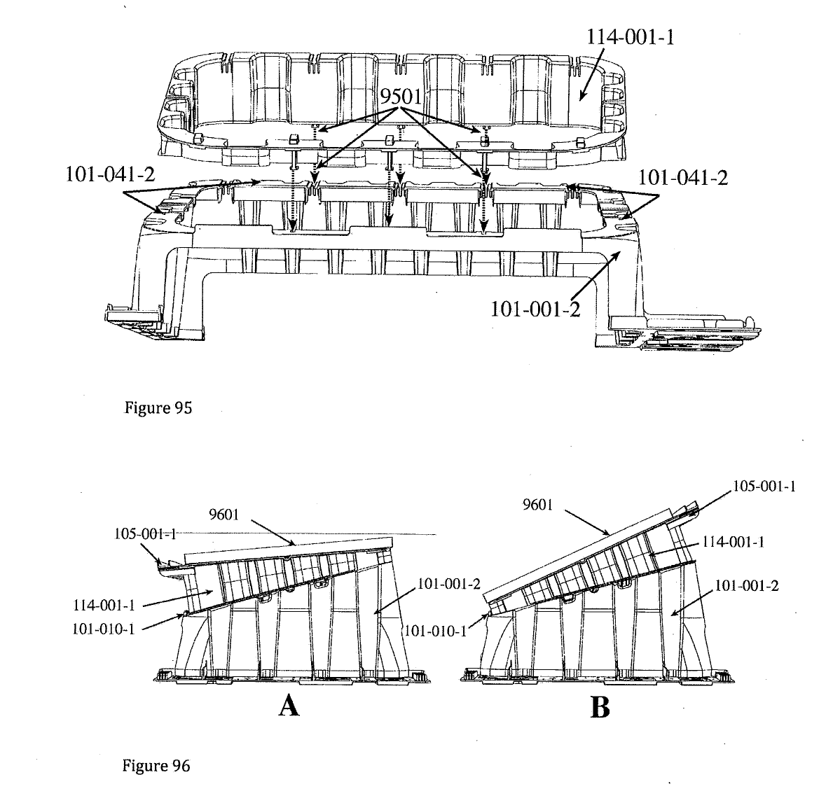

FIG. 95 illustrates: an explosion diagram of the preferred embodiment of a reversible 10-degree angle adaptor fixed to the rack;

FIG. 96 illustrates: two side views of the rack with the angle adaptor and PV panel assembled in the standard and reversed positions;

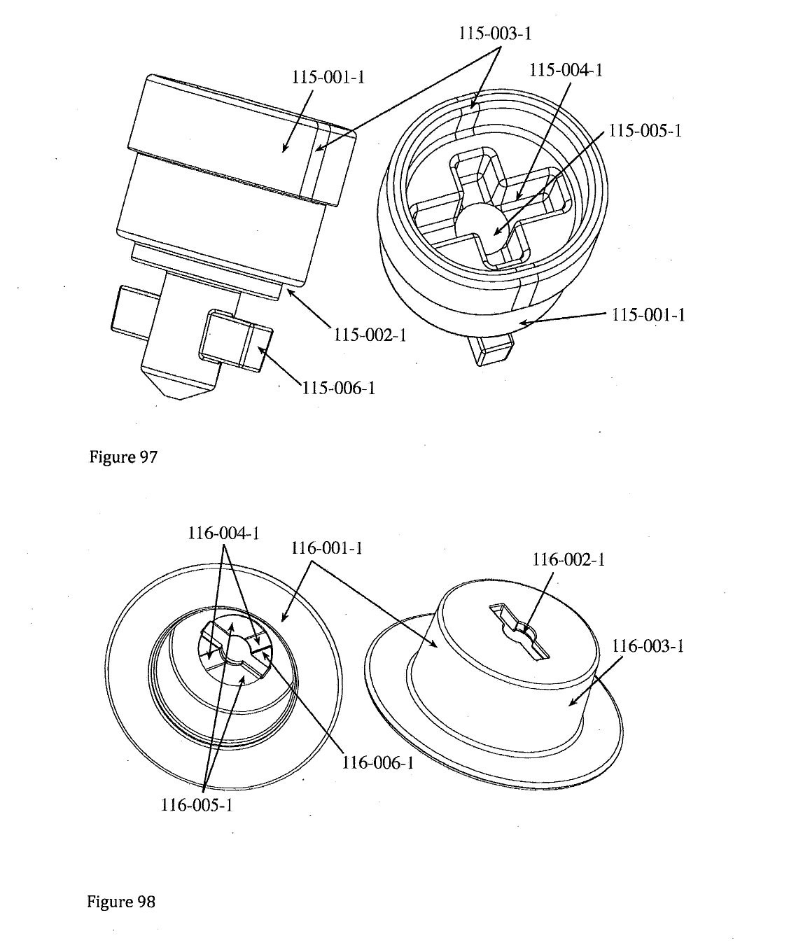

FIG. 97 illustrates: two views of the land based system key fastening device;

FIG. 98 illustrates: Two views of the land based system lock fastening device;

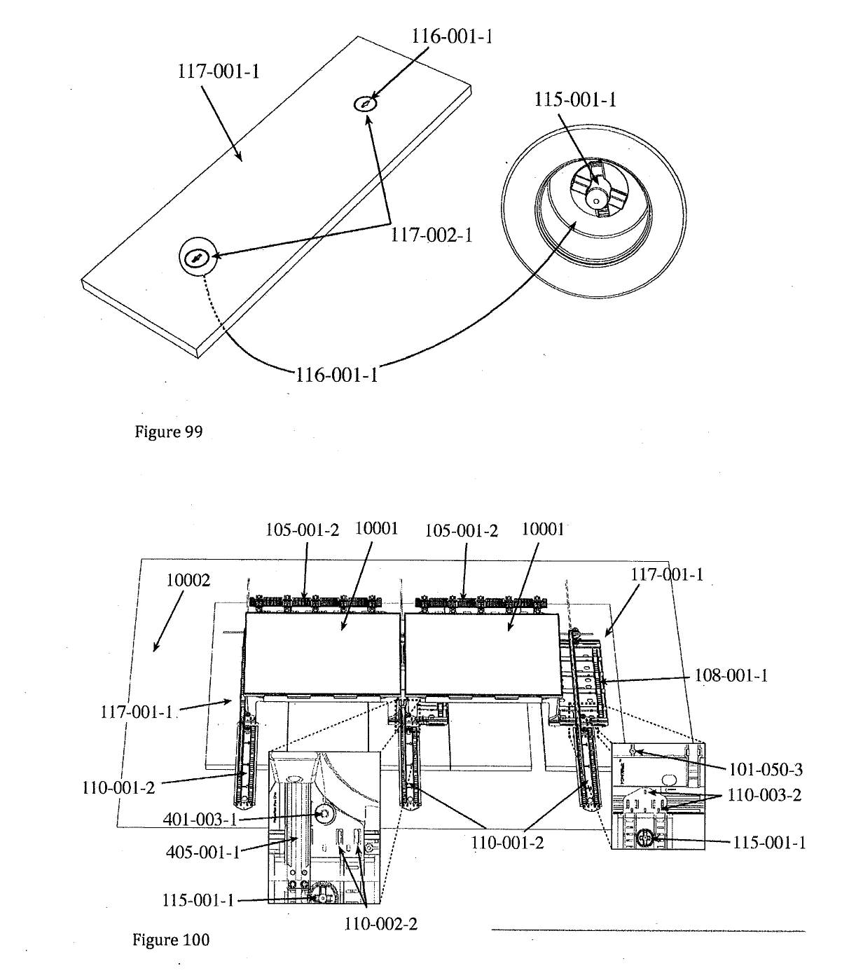

FIG. 99 illustrates: a light cement block with two lock fastening devices embedded;

FIG. 100 illustrates the total assembly of the production model rack adapted for a ground-based system;

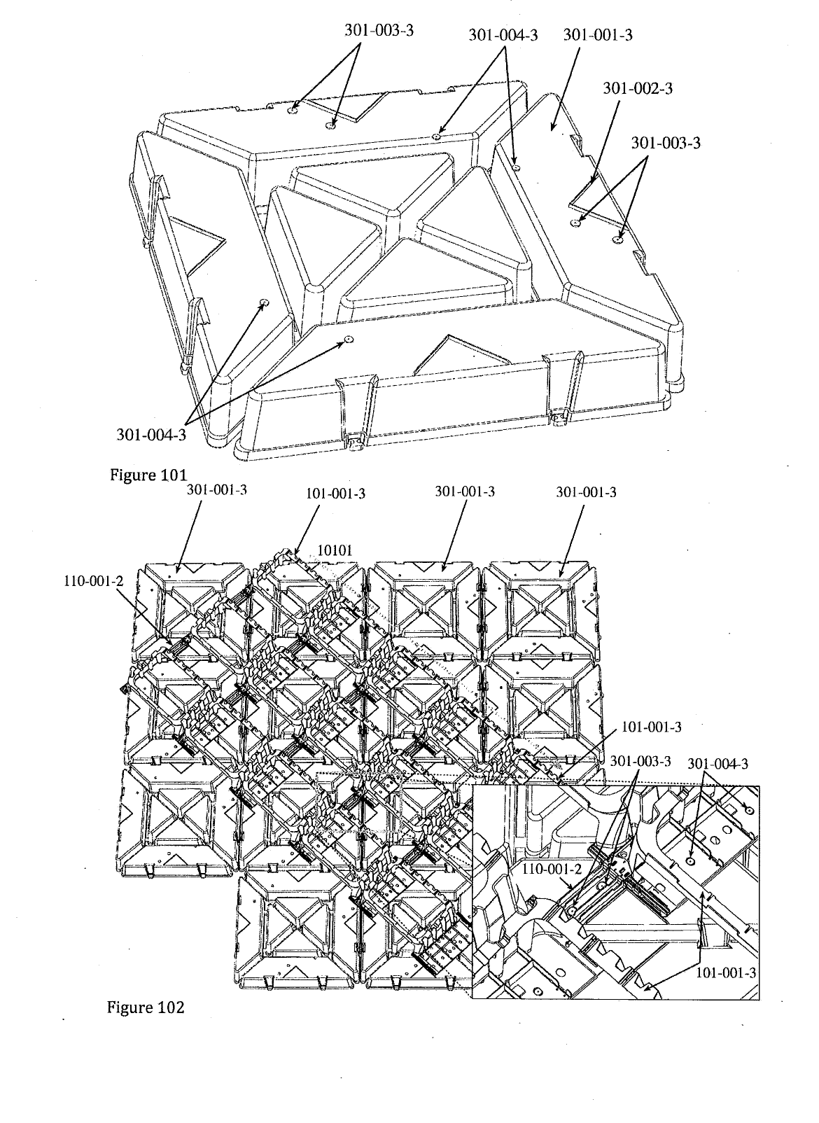

FIG. 101 illustrates a redesigned invert adapted for reuse water systems;

FIG. 102 illustrates the cost effective; reuse invert design assembled with the production ‘roof’ rack and shortened separators, eliminating the need for the deck part;

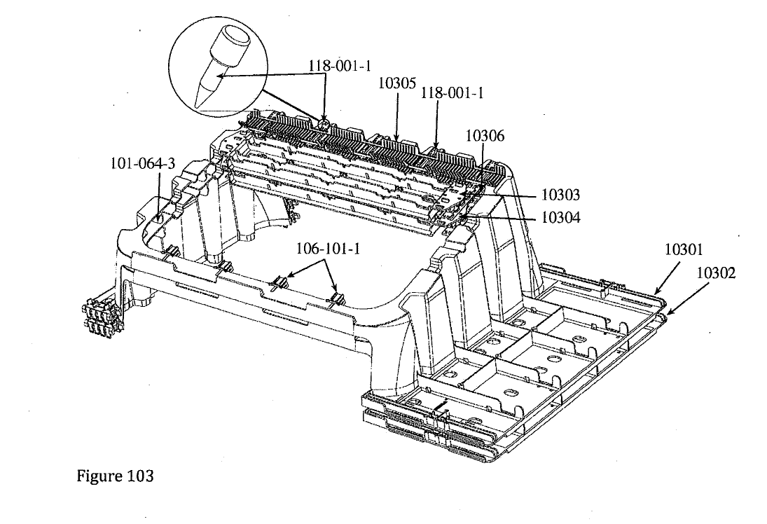

FIG. 103 illustrates a stack of two racks assembled with front and rear zip connectors, separators and locating pins. All parts come in one package geared for rapid onsite positioning and deployment;

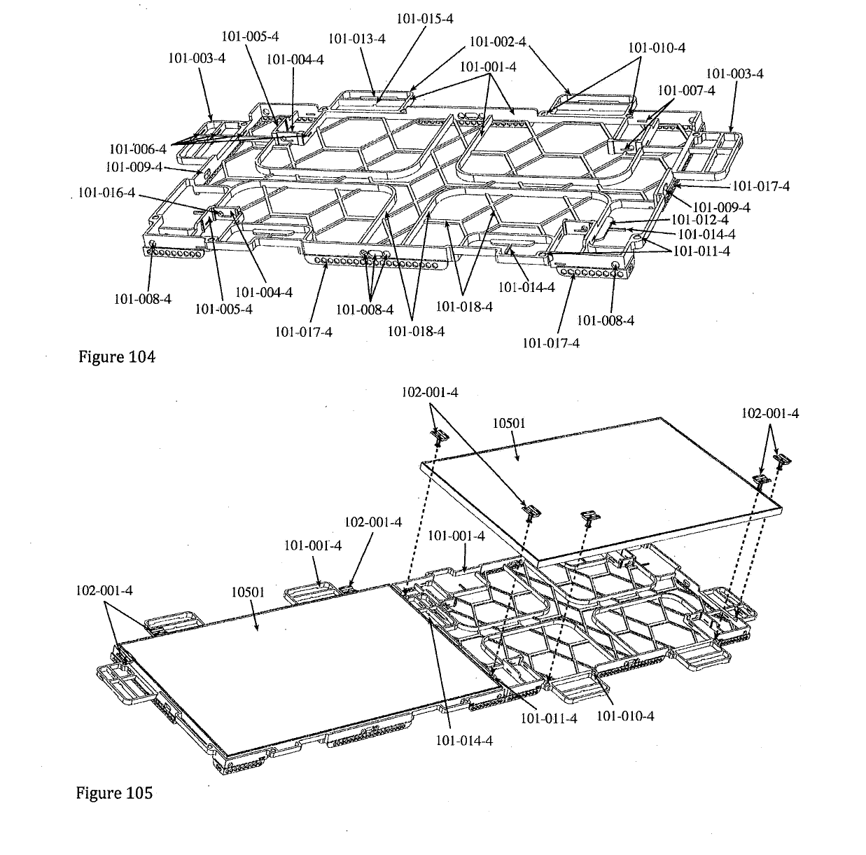

FIG. 104 illustrates the basic roof rack for a domestic roof array;

FIG. 105 illustrates the assembly of roof racks of FIG. 104;

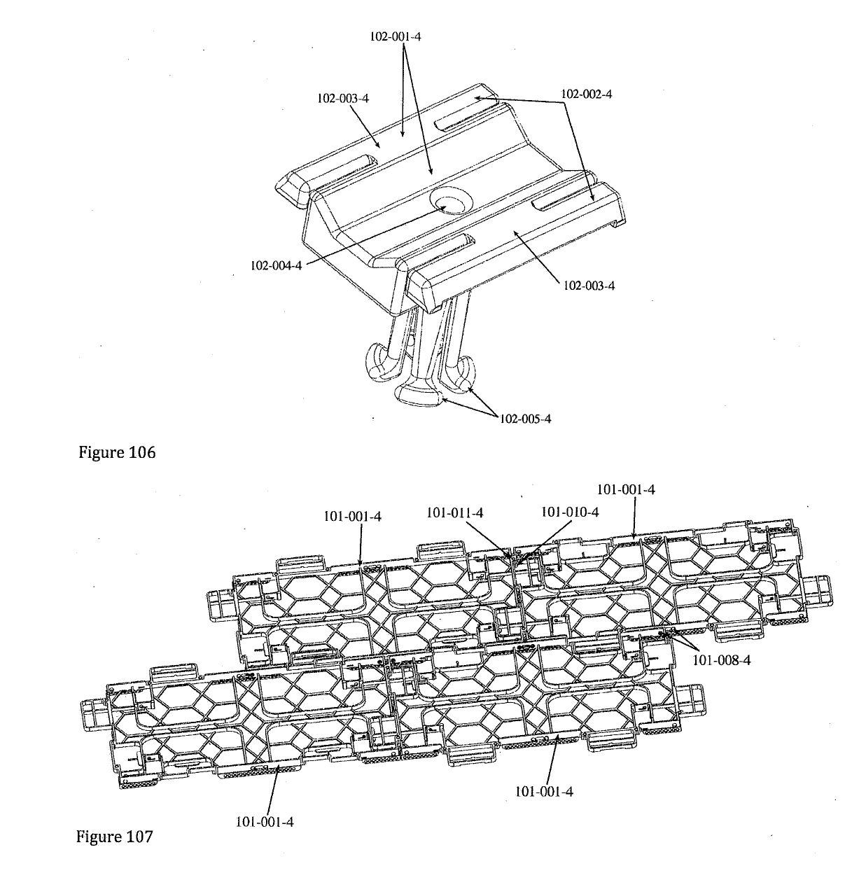

FIG. 106 illustrates the clip for joining pairs of racks;

FIG. 107 illustrates a joined pair of racks as shown in FIG. 104;

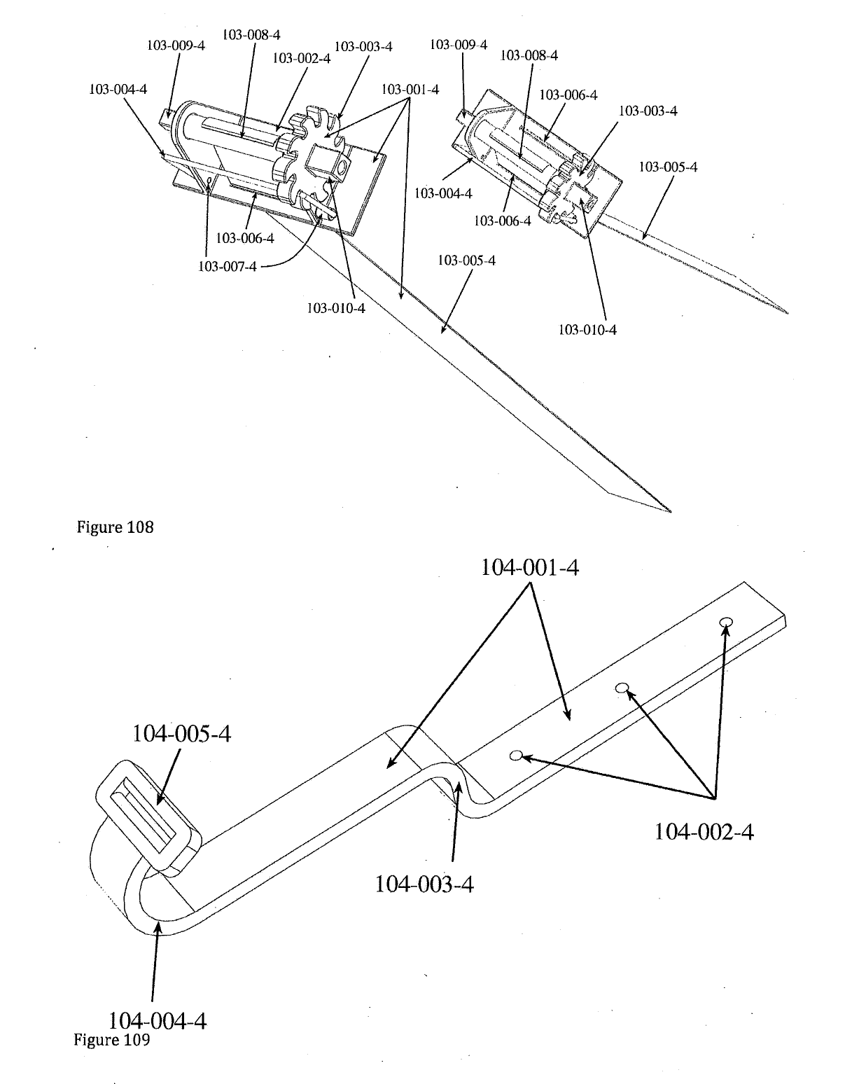

FIG. 108 isslustates the ratchet mechanism for the straps used with the base of FIG. 104;

FIG. 109 illustrates a bracket used with the ratchet of FIG. 108;

FIG. 110 illustrates details of the assembled bases.

The numeral system used in the drawings consists of: part-subpart-feature-embodiment.

The Part number identifies a specific part class; the subpart identifies extra support for the said specific part.

If all the part/subpart/feature/embodiments are applicable and interchangeable in a specific assembly, the said part/subpart will be indicated/designated via embodiment.

All parts [unless otherwise stated], are either low or high pressure injection moulded from High Density Poly Ethylene Structural Foam [HDPE-SF]. Each of the said assemblies that are the building blocks of the invention will be described in the sections below:

### Section 1: The Floating Membrane Base

FIGS. 1 & 2 illustrate the major components/features of the first embodiment of the deck [201-001-1]. FIGS. 3 & 4 illustrate the major components/features of the preferred embodiment of the deck [201-001-2]. The top surface of both embodiments of the deck incorporates a slight slope [201-009-1, FIG. 12 and in the second embodiment: 201-012-2, FIG. 13], designed for rainwater run off to drain to a gutter [201-003-1, FIGS. 1&2, and in the second embodiment: 201-003-2, FIGS. 3&4]. There are several circular, conical extruded bosses [201-005-1, FIGS. 1, 2 & 12 and in the second embodiment: 201-005-2, FIGS. 3, 4 & 13 respectively], on the top surface on the deck, which also protrude from the bottom surface of the deck, merging with the bottom ribbing, and in the first embodiment, a further rectangular top extrusion from the top of these said bosses [201-008-1, FIG. 1] with a blind fixing pilot hole [201-006-1, FIG. 1], in the centre. The said extrusions form a vertically and horizontally equally spaced planar array, such that when two or more contiguous decks are attached in any number, vertically and/or horizontally, the said extrusions remain equally spaced expanding forming a continuous planar symmetric array [see: 201-001-1, FIG. 20, and in the second embodiment: 201-001-2, FIG. 27].

In the preferred [second], embodiment, the conical extrusions [201-005-2, FIG. 3], are taller than in the first, there is a small inverse protrusion [201-005-2, FIG. 4], again merging with the bottom ribbing [201-011-2, FIG. 2], to strengthen the screw blind fixing hole on top of the cones [201-006-2, FIG. 1]. The preferred embodiment, there are no rectangular extrusions as in FIG. 1: [201-008-1], the small protrusions below the top of the cones provide strength to the fixing points [201-006-2, FIG. 3], in the top centres.

The tops of all said conical circular bosses [201-005-1 & 201-005-2], of both embodiments are all uniplanar. In the first embodiment, the purpose of the combined extrusion, [201-005-1 & 201-008-1, FIG. 1], is to provide super structure positioning and fixing points. To provide further strength to these fixing points both embodiments incorporate a substantial ribbing structure [201-008-1 & 201-011-2, FIGS. 2, 4 respectively], spanning the bottom of the deck intersecting the underside of each of the top conical extrusions, [201-009-1, FIG. 1 & 201-011-2, FIG. 2, embodiment respective].

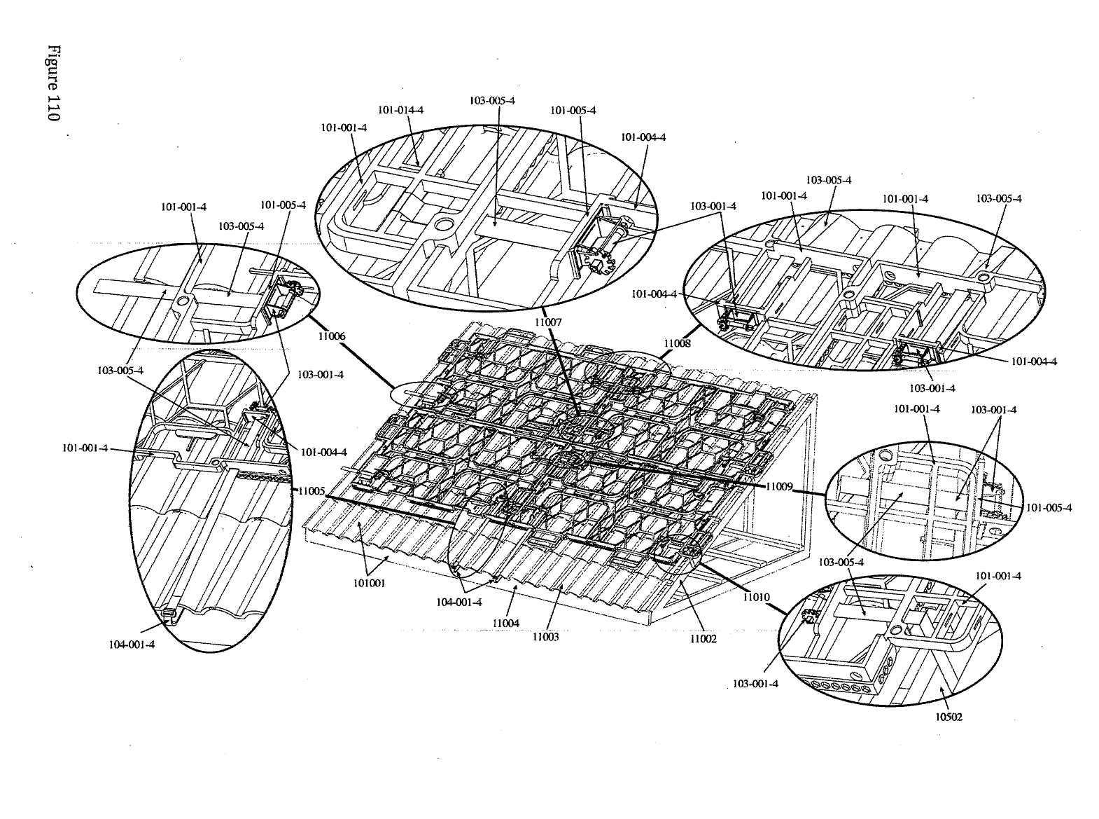

The first embodiment includes another tapered cylindrical extrusion [201-007-1, FIGS. 1&2], provides a mounting fixing point for the invert [301-001-1, FIGS. 5, 6 & 10], where bolts are inserted, fixing through the deck into the invert [301-004-1, FIGS. 5, 6 & 10]. In the preferred embodiment, an inverted cone extrusion through to the base of the deck [201-004-2 FIG. 4], provides the fixing point to the invert [see FIG. 11]. The bottoms of all of the said extrusions are horizontally uniplanar. The said extrusions incorporate a hole, to allow the insertion of bolts/screws [206-001-1, FIG. 10 & the second embodiment: 201-004-2, FIG. 11], fixing the decks [201-001-1, FIGS. 10 & 201-001-2, FIG. 11 respectively], with the invert [301-001-1, FIGS. 10, 12, 14 & 20 and in the second embodiment: 301-001-2 FIGS. 11, 13, 15 & 28]. Note: All fixing points on both embodiments have joint reinforcing underside rib mould intersections [201-008-1, FIGS. 2 and 201-011-2, FIG. 4 respectively].

In the first embodiment, the deck incorporates a perimeter extrusion [201-002-1, FIGS. 1, 2, 20], which when an array of decks is assembled, each deck perimeter extrusion is inserted into one side of a seal [202-001-1, FIGS. 19 & 20], which runs parallel to and between each said deck perimeter extrusion [2002]. The perimeter extrusion is moulded following the contour of the deck surface [201-002-1, FIGS. 1&2], thus connecting and continuing an in plane X & Y directional drainage system, extending to the perimeter of the array. The said seal provides a compressional waterproof connection between adjacent first embodiment decks. Where four decks meet, a specific four armed compressional seal [204-001-1, FIG. 18], where waterproof inserts [204-002-1, FIG. 18] slip into the seal cavities [202-002-1, FIG. 19], with a waterproofing extrusion [204-004-1, FIG. 18]. There may also be a perimeter extrusion [201-002-2, FIGS. 3,4 & 25], with the addition of a perimeter upturned edge [201-012-2, FIG. 25], and upturned corners [201-007-2, FIGS. 3,4 & 27]. This design complies to the US EPA LT2 rule specifically re the prohibition of compressional seal designs. The seal [202-001-2, FIGS. 22 & 27], in this embodiment is fixed to both of the adjoining decks [201-001-2, FIG. 27], via parallel extrusions [202-004-2 & 202-005-2, FIG. 22] that are hollow [202-002-2, FIG. 22], providing an extruded ‘L’ shaped nook [202-006-2, FIG. 22], that slips over the ‘L’ shaped permitter extrusion of the deck [201-012-2, FIG. 25]. The seal allows for thermal movement of the deck, via a flexible concertina type link [202-003-2, FIG. 22], between the said parallel extrusions [202-004-2 & 202-005-2, FIG. 22]. The seal terminates at each end of the deck's ‘upturned edges’ [201-007-2, FIGS. 3, 4, 13 & 27], allowing the placement of a waterproof cap [205-001-1, FIG. 27], over the deck's sealed intersection/junctions [2701, FIG. 27]. The cap is made of ethylene propylene diene monomer [EPDM] a synthetic flexible rubber which includes four, flexible ‘arrow & hole’ fixings [205-002-2, FIG. 27], which fix through holes in the reinforcing rib of the upturned edges of the deck [201-008-2, FIGS. 3 & 27].

The second deck embodiment also includes a further set of smaller perimeter extrusions [201-010-2, FIGS. 3, 4, 13, 25 & 26], for the purpose of the connection of a geo-membrane [Hypalon, CSPE or similar] skirt adaptor [203-001-2, FIG. 24], on the shoreline facing side of each deck, around the entire perimeter of the deployment. The skirt adaptor during assembly is pushed over the deck perimeter extrusion [201-002-2, FIG. 25], and the perimeter extrusion lip 201-012-2, FIG. 25], straps [203-006-2, FIGS. 24 & 25], catch over the deck extrusion [201-010-2, FIG. 25], via hole in the strap [203-002-2, FIG. 24]. The strap is fixed into position via a plastite screw and washer into the boss [201-101-2, FIG. 25]. The purpose of this part is to provide a quick, practical and cost effective geo-membrane fastening system. FIG. 25 illustrates the connection strategy of the said geo-membrane [203-003-2, FIG. 25], note the rectangular fixing spiral of the membrane, in particular the wrapping around gasket [204-001-2, FIG. 25], its position on the deck perimeter extrusion and the position of the fixing screw [FIG. 25, aspect#2503]. [Note that the features in FIG. 25, with a dashed outline have been projected from another parallel section.]

The first embodiment of the Invert [301-001-1, FIGS. 5 & 6] may be generally described as a ‘T’ shaped upturned bucket with multiple cavities. The upturned bucket principle has been used before in providing floatation on a body of water. There are however, additional features to the invert that are unique. The invert is moulded incorporating several separate cavities including [301-005-1, 301-006-1, 301-010-1, 301-011-1, FIGS. 5 & 6]. These cavities when upturned on to the water body provide floatation for the top part and its payload, more specifically, the placement of the cavities provides a certain amount of structural flexibility in the body of the invert to allow for differential movement between the deck connection points [301-004-1, FIG. 5] due to the thermal cycling of the deck. As the invert is partially submerged in [and in close proximity of], the water body [see aspect#1201 & 1202, FIG. 12], the said invert will not be subject to the same degree of thermal cycling as the deck, and the bridged cavities, as flexure areas [301-012-1, FIG. 6], accommodate movement at the fixing points.

The preferred embodiment [301-001-2, FIGS. 7 & 8], is square in plan again with several isolated cavities [0305a & 0306a], as in the first embodiment, with the difference that no cavity crosses over the diagonals of the square [301-005-2, FIG. 7]. In both embodiments, each cavity has a small air bleed hole [301-009-1, 301-009-2 FIGS. 5, 6, 12 & 7, 8, 13 respectively], which allows the escape of entrapped air, so that the water level [aspect#1303, FIGS. 13 and 1203, FIG. 12, in the first embodiment], is allowed to rise to the level of the said hole. All holes are moulded in a horizontal plane, allowing for a constant level of water egress into the cavities, and their location [height from invert bottom aspect#1202 & 1302, FIGS. 12 & 13 respectively], is determined by the MET [meteorological] specifications of the storage. The payload/active [live] load/wind load combination placed/fixed on/to the deck will:
(1) Produce a displacement of water equal to the equivalent weight of the said combined payload;
(2) Compress the entrapped air in accordance to the cavity air temperature and the weight of the combined load. Although the said compression of air will provide some vertical movement—if the deck is subject to lift forces—relieving the pressure, the entrapped air will come to a balance pressure point, beyond which, the water egressed into the cavity will act like a dampener to the lift force. In effect dampening the impact of a sudden lift force, note that for large deployments this can be a substantial figure.

Extruded bosses [301-004-1, FIGS. 5 & 10], on the top of the first embodiment of the invert are placed to accept the fixings from the deck via bolts [202-001-1, FIG. 10], provide the fixing between the invert and deck. Perimeter male connectors [301-003-1, FIGS. 5 & 6], at the base of the invert, provide a snap lock fitting with the receptacle [301-002-1 FIGS. 5 & 6], enhancing the ‘dry’ assembly rate of the surrounding invert parts [see FIG. 10]. The membrane [entire cover], will be assembled in clusters on a crane able platform, where on completion the cluster is lifted into place, floated into position and attached to a major working cluster.

The preferred embodiment incorporates shallow depressions [301-004-2, FIGS. 7, 8 & 11], with underside bosses, and ribbing [301-013-2, FIG. 8], strengthening the fixing hole. Perimeter male [301-003-2 FIGS. 7, 8 & 9], and female [301-002-2, FIGS. 7, 8 & 9], taper lock connectors provide base assembly positioning [see insert FIG. 9].

FIG. 14 illustrates the interconnection strategy of the ‘T’ shaped outline of the first embodiment of the invert. The deck top connection pattern [aspect#1401, FIG. 14], with respect to the invert placement pattern as illustrated in FIG. 7: 3001-003-1, illustrates the connection strategy. FIG. 7, also highlights, the minimum connective unit group, and their positioning under the deck array. A total of four inverts connect across the deck, to provide a strong interconnection strategy. The invert part provides across joint strengthening [aspect#1403 FIG. 14], as well as inline strengthening. This scheme provides a rigid connection scenario to the final membrane, as constructed from modular parts. It is essential for the constructed membrane to be rigid as possible, and therefore to act as a single surface, for the distribution and management of imposed forces and the elimination of low frequency membrane resonance. The three parallel cavities [301-005-1, FIGS. 5, 6 & 12], whilst providing allowance for differential compression distortions when diurnal thermal expansion differentially expands the deck interconnections vs. the invert inter connections also provide backbone rigidity below the deck interconnection interface [aspect#1404, FIG. 14]. There are also moulded gaps between the cavities [301-008-1, FIGS. 5, 6 & 12]. These are flooded to the water level on the application of the array to the water body and combined applied payload. The said flooded cavities [attribute #1204, FIG. 12 and in the second embodiment #1304, FIG. 13], effectively capture or temporally trap water, which is released/circulated through specific gapping [aspect#1402, FIG. 14], and the perimeter channels [301-008-1, FIG. 12], through the variation of the combined payloads. The captured water provides additional pre-dampening to the wind/elemental and active forces/loads applied to the membrane as a whole. The interconnection strategy of the preferred embodiment [see FIG. 15], illustrates a half deck width offset in the in plane X and Y directions, as the deck and the square invert have similar dimensions in plan. This embodiment includes four fixing points [301-004-2, FIGS. 7 & 11], compared to three [301-004-1—FIGS. 5, and the bolt cluster 202-001-1, FIG. 10], in the first embodiment attach each invert to the deck. The minimum connective unit comprises of: one deck and four inverts [see FIGS. 11 & 15]. All the features in the first embodiment are duplicated in this embodiment, with the additional feature of the water ingress/egress hole in the centre of the invert [301-015-2, FIGS. 8, 15 & 21], corresponds to the location of the upturned seal cap junction of four decks [205-001-1, FIGS. 15, 21 & 27]. Instrumentation, water grounding and lifting devices [see FIG. 75], can be inserted through this alignment to the water-body. Also there is the advantage that the edge of the deck [aspect#1502, FIG. 15], will always run along the central axis of the square invert, allowing the load-bearing floatation of the entire square invert, to support active loads to the edge of the deck. FIG. 20 illustrates a first embodiment assembly of a 3×2 array, complete with deck [201-001-1, FIG. 20], half invert parts [302-001-1, FIGS. 20 & 16], with whole invert parts [301-001-1, FIGS. 5, 6, 10 & 20], in the centre of the array. The placement of seals [203-001-1, FIG. 19], with the gapping allowance [between decks], of diurnal as well as seasonal thermal cycling [aspect#2002, FIG. 20], allows a free run off of water off the array [aspect#2001, FIG. 20], in planar X and Y directions. The seals are extruded mouldings of preferably EPDM, [203-001-1, FIG. 19], which are flexible and crushable via their material type, sectional moulding [203-002-1, FIGS. 19 & 20], and wall thickness [203-004-1, FIG. 19]. The material flexibility of the seals [203-005-1, FIG. 19], provides the ability for removal and insertion post membrane deployment should it be necessary to do so. The seal junction [204-001-1, FIGS. 18 & 20], provides a reinsert-able crushable water proof junction for the seals. The said junction profile is identical to the seals with insertion points [204-003-1, FIG. 18], and covers [204-004-1, FIG. 18], to provide waterproofing.

The half invert parts [302-001-1, FIGS. 16 & 20] provide a smoother array edge connection, rather than the ragged edges illustrated in FIG. 14. There are two types a right hand half [RHH] invert part [302-001-1, FIG. 16], and a left hand half [LHH] invert part which is a mirror reflection of part [302-001-1, FIG. 16], and because of the mirror the LHH invert part will not be discussed in detail. The numbering/feature identification system of the RHH invert part is identical to the full size part except for the sub-part delineation <02>, and the moulded side wall [302-010-1, FIG. 16]. These parts will have to be made in separate injection mould processes and will require separate tooling.

FIG. 21 illustrates a 6×4-‘R’ shaped array of the preferred embodiment, where use of the half square invert [302-001-2, FIGS. 17 & 21] is made to smooth the ragged edges of the deployments. No extra moulds will be needed for these sub parts as the parts are acquired by cutting the square mould along both diagonals forming the edge [302-016-2, FIG. 17]. As with the first embodiment the numbering/feature identification system of the RHH square invert part is identical to the full size part except for the sub-part delineation <02>, and the moulded side wall [302-016-2, FIG. 17]. Note that if the deployment necessitates the placement of decks in positions illustrated by [aspect#2103, FIG. 21], restrictions will need to be made re the active load traffic beyond the diagonals of the decks closest to and parallel to the edge of the array. Point [aspect#2102 FIG. 21], illustrates the active load force distribution in the said restricted area. Note the positioning of the circular [301-003-2—male] and rectangular [301-002-2—female] connectors on the connecting edges of the half square inverts—requiring sectioning of the square invert through both diagonals. If the cover has a US EPA LT2 requirement, the deck sealing will not be affected by the addition of the geo-membrane adaptor [202-001-2, FIG. 22].

The maximum [length×breadth] dimensions of an array is determined by the rainfall and the water runoff capability of said array. For potable deployments greater than this capacity, where covers need to comply with the US EPA LT2 storage rules flexible gutters are run through the array. The flexible geo-membrane material [a synthetic rubber or equivalent], connection scheme in principal is illustrated in a sectional drawing [see FIG. 23 for the first embodiment, & FIG. 25 for the preferred embodiment].

In the first embodiment, the synthetic rubber [205-001-1, FIG. 25], is connected to the deck [201-001-1, FIG. 25], via strip [205-003-1, FIG. 23], and bolts [205-005-1, FIG. 23]. A length of cordage is inserted in a loop of the synthetic rubber [205-002-1, FIG. 23], preventing the synthetic rubber from being pulled through the joint. The synthetic rubber is then wrapped around the module perimeter extrusion [201-002-1, FIG. 23], and fixed to the, extrusion via a clip [205-005-1, FIG. 23]. Bolts [205-005-1, FIG. 23], fix the clip in place. Sand bags [205-006-1, FIG. 23], with variable weight-length distribution form the run off needed so that the rainwater can be collected and pumped of the surface of the membrane.

In the preferred embodiment, to enhance installation speed, functionality and geo-membrane jointing integrity, a geo-membrane attachment adaptor has been designed [203-001-2, FIG. 23]. The adaptor attaches to the deck via straps [203-006-2, FIG. 25], and fixed to perimeter bossed extruded on the deck via washer and plastite screw. FIG. 25 illustrates the connection principle as discussed. An EPDM [ethylene propylene diene monomer] synthetic rubber extrusion [204-001-2, FIG. 25], provides a compressible yet robust packing material for the geo-membrane [203-003-2, FIG. 25], to wrap around. The general ‘S’ shape of the moulding [203-001-2, FIG. 25], is to clamp over the geo-membrane, EPDM and perimeter extrusion so that fixing screws [aspect#2503 FIG. 25], can be placed through all items and to protect the geo-membrane form the screw piercing points via the bottom part of the ‘S’ [203-002-2, FIG. 25]. The edges of the adaptor [203-003-2, FIG. 24], are curved in two aspects:
1. So that the geo-membrane can be wrapped around and capped to form a water proof joint;
2. So that the edges do not interfere with others when forming inner [see 203-001-2, FIG. 54], and outer angles.

The other end of the geo-membrane sheet [aspect#2502, FIG. 25], spans to the fixings on the shoreline, where a specific design length between the sand bags [230-004-2, FIG. 25], is increased to accommodate for the necessary storage working [and maintenance], levels.

Another major function of the gapping between the sand bags [205-006-1, FIG. 23 and in the second embodiment 203-004-2, FIG. 25 respectively], and a float [203-005-2, FIG. 25], is to form perimeter gutter. This perimeter gutter will collect all the water surface runoff from the deck array, which is removed through standard sump pumping technologies and pumped to and away from the shoreline.

### Section 2: The Membrane Superstructure Supporting the PV Panels

FIGS. 29 &30 illustrate the first embodiment of the rack [101-001-1, FIGS. 29 & 30]. The rack is injected moulded from High Density Poly Ethylene [HDPE]. The rack face is moulded to the PV panel latitude or preferred power angle [101-011-1, FIG. 30], to which the PV panel is fixed [101-010-1, FIGS. 29 & 30]. The rack has two three holed feet/flanges [101-002-1 & 101-003-1, FIGS. 29 & 30] of which, the left [foot/flange], of each [rack], are designed to assemble on top of the right [see 101-001-1, FIGS. 39 & 40], as denoted by aspect#4001, FIG. 40. Further, each left foot has downward protrusions [101-008-1, FIGS. 29 & 30] and each right foot has upward protrusions [101-006-1, FIGS. 29 & 30], a curve in the left foot [101-009-1, FIGS. 29 & 30], allows for closer contact to the right side of the previous row member. The purpose of the single foot mating design and protrusions is to allow a simpler row assembly, without any part needing shims to adjust relative heights. Wind studies have determined an optimal but practical distance between the said feet and the bottom of the upper moulding [ie: the main body] of the rack [the distance between arrow heads: 101-012-1, FIGS. 29 & 30]. The rack has curved left and right side walls [101-015-1, FIGS. 29 & 30], as well as a ribbed back [101-104-1, FIGS. 29 & 30]. The top of the ribbed back has small air pressure bleed holes [101-013-1, FIG. 30], to equalize rear external and internal pressures created by wind action. A recess in the front [101-015-1, FIGS. 29 & 30], with holes [101-007-1, FIGS. 29 & 30], forms the mounting point of a structural reinforcing member [110-001-1, FIG. 53], which in turn has tendon [described later], horizontal [or X direction in plane], attachment points [109-001-1, FIG. 53], and vertical [or Y direction in plane], attachment points [108-001-1, FIG. 53]. Horizontal tendons restrain the rack via attachments across the front recess [101-015-1, FIGS. 29 & 30], and vertical tendons restrain the rack through the centre of the rack, attaching in the middle of the front recess [see FIG. 53], through to a rear tendon attachment point [101-014-1 FIGS. 30 & 108-001-1, FIG. 53].

FIG. 37 illustrates the rail connector [102-001-1]. The connector has three types of protrusions, two diamond [102-003-1, FIG. 37], two square [102-002-1, FIG. 37], and one a combination of both in the centre [102-006-1, FIG. 37]. The purpose of these protrusions is for the rail to be able to be fixed onto the deck [201-001-1], in horizontal, vertical and diagonal orientations [102-001-1, FIG. 40] on the deck. Countersunk holes [102-005-1, FIG. 37] are the fixing screw insertion points.

FIG. 38 illustrates the sliding part that fits onto the rail connector via the rails [102-004-1, FIG. 37], into the moulding cut outs [103-002-1, FIG. 38]. The said sliding part has a vertical ‘T’ shaped protrusion [103-003-1, FIG. 38], which provides a further assembly adjustment point when passed through [during assembly], a slotted washer [109-001-1, FIG. 39]. The purpose of the slotted washer is to fix the feet of the mated racks [101-001-1, FIG. 39], to the deck via the rail connector [see FIGS. 39 & 40]. The slotted washer fits snugly into the mated racks, whilst allowing for thermal expansion along the slot [109-003-1, FIG. 39]. The washer has a perimeter rim extrusion around the top surface [109-002-1, FIG. 39], which when fully inserted through the sandwiched piggyback rack holes [101-005-1 & 101-006-1, FIG. 39], rests on the top of the deck foot. During assembly the ‘T’ protrusion of the sliding part inserts through the slot in the washer [109-003-1, FIG. 39] whist positioned on the rail connector [102-001-1, FIG. 39], which is fixed to the deck.

In summary, the standard assembly procedure of this [first] embodiment: The rack rows are aligned on the rails [102-001-1, FIG. 39], positioned on the deck [201-001-1, FIG. 39], via the top ‘T’ of the sliding part [103-001-1, FIG. 39], which is inserted through the rack foot holes [101-005-1, FIGS. 29 & 30]. The slot washers [109-001-1, FIGS. 39 & 40], are then inserted over the vertical ‘T’ extrusion into the rack foot hole, rotated to an optimum position to provide maximum strength and then drilled through via pilot holes [103-005-1, FIG. 38]. The slotted washer, the slide part and the rail connector part are fixed via a standard bolt [aspect#5202, FIG. 52].

FIG. 31 illustrates the rack design of the second [and preferred deck fixing] embodiment. This embodiment differs from the previous in the fact that it connects directly to the deck. The direct deck connection scheme improves the assembly speed at the cost of swapping the Omni-angle alignment for specific angle alignments when connecting to the deck. Aside from this limitation, this embodiment has significant advantages over the previous.

The advantages of this embodiment are in:
The method of row concatenation via piggy-back connection; and
The rib alignment system;
The clip-n-lock snap positioning system;
The zip-n-lock variable PV panel sliding/tensioning rear clamp adaptation;
The zip-n-lock variable PV panel tensioning front clip-clamp adaptation;
No screw and bolt fixings to fix the PV panel to the rack;
Allowance for thermal expansion cycling in all jointing systems;
CFD optimised design;
Direct fixing of restraints;
Cable management accessory adaptation;
Various adaptations to roof and land base deployment.

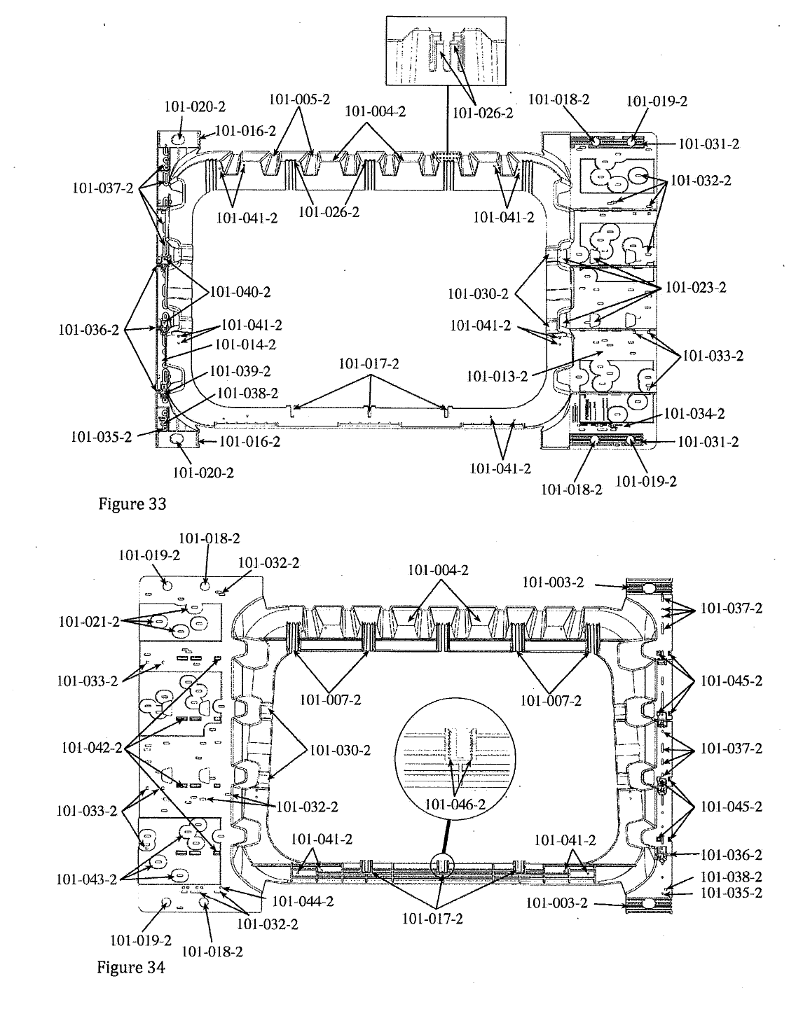

The left leg of the rack is defined as the pivot plate [101-014-2, FIG. 31], as the row angles are defined from the pivot point [101-035-2, FIGS. 33 & 34], on this plate. The right leg is defined as the fixing plate [101-013-2, FIG. 31], as it provides the major fixing points in the mid array assembly. Moulded flutes [101-009-2, FIG. 31], on both sides of the rack, provide cable access to the bottom of the PV panels.

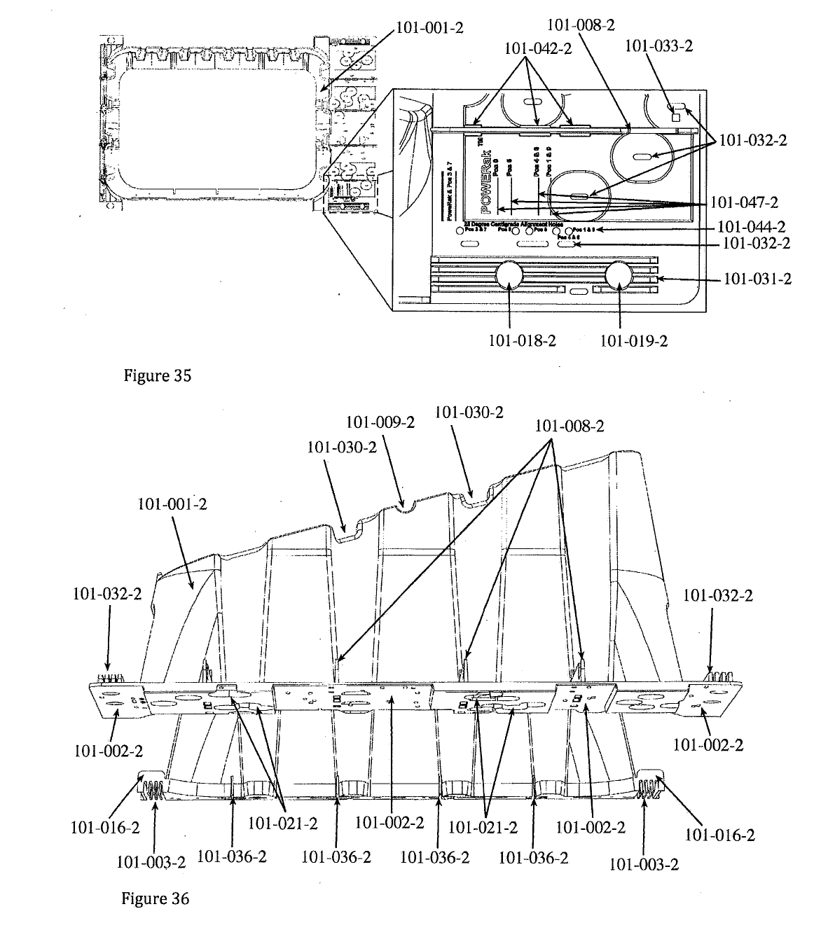

The PV angle defined as the angle between the PV panel fixing surface [101-001-2, FIG. 31], and the horizontal plane through surface [101-002-2, FIG. 31], can be made to suit any application [ie: any latitude angle]. In this embodiment it has been set to 15 degrees. The rack has a moulded rear fairing [101-004-2, FIG. 31], to reduce wind lift. The rack form has been strengthened in the fairing with fluting [101-005-2, FIGS. 31 & 33], and on both sides with fluting [101-006-2, FIG. 31], to improve its vertical compressional strength [to endure high 100 mph+ wind loads]. A front ledge [101-010-2, FIGS. 31 & 32], provides a rest and pivot point [for assembly], for one side of the PV panel enabling the panel fixing to be done by a single person. The rack provides five rear slots [101-026-2, FIGS. 32 & 33], through which the five arms of a sliding adjustable rear PV panel fixing part [105-001-1, FIGS. 45 & 46] slides. This said [sliding] part provides PV panel fixing points on raised brackets [105-003-1, FIGS. 45 & 46], via a birds-mouth [105-010-1, FIG. 45], with [rattle proofing] fixing tensioners [105-009-1, FIGS. 45 & 46]. A ratchet-tensioning system via saw tooth profile [105-008-1, FIG. 45], and a connecting wire management tray [105-004-1, FIG. 45]. Five sets of dual flipper (ratchet) arms [101-026-2, FIG. 33], moulded into the rack provide the single directional adjustment. This part is inserted from inside the rack, and by sliding towards the rear, the shape of the ratchet arm tip [101-026-2, FIG. 33], produces unidirectional movement. There is another ratchet fixing mechanism on the front of the rack at the base of slots [101-017-2, FIGS. 31, 32, 33 & 34]. A front fixing PV panel moulded (zip-lock) part [106-001-2, FIG. 46], slides into the said slots [101-017-2], fixed via a ratchet mechanism. A sawtooth profile [101-046-1, FIGS. 46, 34 & 32], moulded into the rack provides the ratchet for arms [106-002-1, FIG. 46], to lock in several positions, allowing for the fixing of differing widths of the PV panel aluminium frame bottom profiles. A birds-mouth recess [106-004-1, FIG. 46], on the zip lock, provides the clamping force to fix the PV panel frame to the top of the rack. The zip locks slide guides [106-005-1, FIG. 46], run at a slight angle to the birds-mouth flats providing a extra pre-stress to the said clamping force. The rack has a parallel set of ribs [101-008-2, FIGS. 31, 35 & 36], on the fixing plate, which align with a corresponding set of slots on and through the pivot plate [101-036-2, FIGS. 33 & 36]. Each of these slots, have a ‘clip’ fastening mechanism [101-028-2, FIG. 32], in which the clip [101-029-2, FIG. 32], clips over the ribs on the fixing plate into one of three positions, via holes [101-042-2, FIGS. 34 & 35], cut through the bottom of the plate. Each of these said holes [101-042-2, FIGS. 34 & 35], are slotted to allow for thermal movement. The rack rows are concatenated via ‘piggy-back’ assembly [see FIG. 41], using the said ribs and slots [aspect#4102, FIG. 41], for alignment and spacing. This arrangement accelerates the assembly speed by eliminating the need for row alignment and with the advantage of the push-n-clip assembly [refer FIG. 41]. Note the outer connections [aspect#4101, FIG. 41], are utilised in another application—refer section 5.

Each of the set pivot angle positions fixing points that relate to the deck protrusions [201-005-2, FIGS. 42 & 3], have corresponding fixing holes in the rack pivot plate [101-037-2, FIG. 33]. Each set angle has a corresponding array of slotted recesses [101-021-2, FIGS. 34, 36 & 42], with slotted fixing points on the fixing plate [101-032-2, FIGS. 33, 35, allowing for: seasonal and diurnal thermal expansion], or a raised plate with slotted fixing points [101-002-2, FIG. 36]. FIG. 42 illustrates two racks [101-001-2], piggybacked on an array of deck cones [201-005-2, FIG. 42], set at an angle theta, pivoted through [101-035-2, FIG. 42], clarifying the rack assembly on the deck and the rack slotted recess scheme. Note: only the tops of the deck cones have been shown for clarity. FIG. 43 illustrates a two-rack row [101-001-2, FIG. 43], positioned at six different angles [illustrated via aspect#4301-4306], on an array of 2×2 cone tops (the deck substructure suppressed) [201-005-2, FIG. 43]. Note the pivot point [1010-035-2, FIG. 43], enabling a quick and easy first alignment setup for the racking.

FIG. 35 illustrates the piggyback alignment positions [101-047-2, FIG. 35], and the Degree centigrade [77° F.], alignment holes [101-044-2, FIG. 35], for each of these positions. There is a primary alignment hole in the pivot plate [101-038-2, FIG. 33], through which a length of dowel is placed through to the appropriate piggyback rack receptacle hole [101-044-2, FIG. 35]. This alignment sets the rack array up for negative as well as positive expansion through thermal cycling. To enable the piggyback concatenation of the racks, the pivot plate foot length is designed shorter than that of the fixing plate. A cone cap spacer [104-001-1, FIG. 44], enables the first column of the array to fix the pivot plate at the same height as the fixing plate. This cone sits on the deck-rack support cone [201-005-2, FIG. 44], and is sandwiched between the pivot plate and the said support cone, fixed via a plastite screw trough the rack to the support cone.

Most deployments of this invention will be on the central plates of storages, where the working water level is constantly varying due to the fact that they are municipal storages and the community draws from them, and they are restored in seasonal and diurnal cycles. This coupled with the possibility of storm events necessitates the deployment to be restrained in position over the central plate of the storage. Another factor affecting the restraint system is the necessary alignment of the PV panels due south [in the northern hemisphere], and the fact that most regular shaped polygonal storages are not aligned south or north, also a there are a large number of storages without any defined shape. To avoid force component complexity we required the restraint system to run restraint cables where possible normal [ie perpendicular] to the banks of the storage. To address the varying angle of the PV panel array to the storage banks and transfer the forces at those angles normal to the storage banks requires the placement of a storage perimeter transfer beam [601-001-X, FIG. 59]. Note the ‘X’ signifies that all membrane [i.e. all rack/deck/invert-assemblies] embodiments are applicable in the specific assembly.

To distinguish and clarify the restraint system, the restraints encircled by [601-001-X, FIG. 59], and in the plane of the said transfer beam [403-001-X, FIG. 59 (in plane—horizontal) & 402-001-X, FIG. 59 (in plane—vertical)], are designated: tendons. The restraints running exterior from the transfer beam assembly [ie: running to the storage banks —406-001-X, FIGS. 59 & 407-001-X, FIG. 59], are designated: tethers. FIG. 52 illustrates a first embodiment assembly of a row of three racked PV panels [aspect#5201, FIG. 52], on a first embodiment base membrane, comprising of an array of 3×2 decks [201-001-1, FIG. 52], with the seals [203-005-1, FIG. 52], and seal connectors [not shown], on 6 inverts [301-001-1, FIG. 52]. It also illustrates the location of the X [403-001-2, FIG. 52], and Y [402-001-2, FIG. 52] tendons. FIG. 53 is a bottom view of FIG. 52, clearly indicating the location of the fixing points of the X tendons [405-001-1, FIG. 53], and the Y tendons [404-001-1, FIG. 53], on the front reinforcing bar of the rack [107-001-1, FIG. 53], as well as the locations and loci of tendons [403-001-2, 402-001-2, FIG. 53 respectively].

In the preferred embodiment the first set of tendons are run parallel to the rows [403-001-1, FIG. 54], and fixed to the front of the pivot and fixing plates [ie: in two places], the columns of tendons (normal to the rows), are run along the pivot and fixing plates [402-001-1, FIG. 54], and fixed at the front and back of the (pivot & fixing), plates via clamps [405-001-1 & 404-001-1—FIG. 48 for X and Y tendons respectively], on a tendon bracket [401-001-1, FIG. 47]. More specifically because of the ‘piggy back’ row concatenation of the racks all of the columns of tendons (with the exception of the last column), will be run along the pivot-fixing plate junction. FIG. 48 illustrates the positioning of the tendons, clamps and bracket on the rack. The tendon bracket is fixed to the rack via plastite screws through holes [401-004-1, FIGS. 48 & 47] in the tendon bracket to [101-040-2, FIG. 33] fixing pilot holes in the rack. FIG. 49 illustrates a clip on cable tray accessory [108-001-2, FIG. 49], for the rack. The cable tray can clip on top of the tendon bracket [401-001-1, FIG. 51], or clip directly to the rack either on the pivot plate and or the fixing plate [see FIG. 50]. The cable tray fixes via clips [108-002-2, FIG. 49], into holes [101-033-2, FIG. 34], on the fixing plate, or [101-045-2, FIG. 34], holes on the pivot plate.

FIG. 55 illustrates several views including:
1. An exploded view of a length of the transfer beam [bottom and left of drawing], illustrating the top and bottom trapezoidal outer [601-001-1, FIG. 55], and inner [602-001-1, FIG. 55] shells and the principal plate [603-001-1, FIG. 55], each part with a series of aligning holes [see insert: 601-002-1, FIG. 55], in the flanges functioning as attachment holes for tendons and/or tether connection and part fixing;
2. A view of the sliding slot plate [604-001-1, FIG. 55]. The said slot plate is bolted through slots [604-002-1, FIG. 55] and slots [603-002-1, FIG. 55], in the principal plate and placed top and bottom of the principal plate, fixed with nylock nuts and washers [605-001-1, FIG. 55], the said slot plate allows for limited multi directional planar [x, y], movement of the connected transfer beam whilst limiting torsion about the [x, z] and [y, z] axes, allowing for direct/indirect tension transfer from the worm gear driven winched tethers [406-001-1, FIGS. 56 and 407-001-1, FIG. 56], to the internal array of tendons [Horizontal: 403-001-X, FIG. 56 and vertical: 402-001-X, FIG. 56] across the transfer beam [601-001-1, FIG. 56];
3. A sectional view of the construction of the beam illustrating the bi-trapezoidal outer shell [601-001-1, FIG. 55], the internal principal plate [603-001-1, FIG. 55], and a bi-trapezoidal inner [602-001-1, FIG. 55] insert, which is a type of beam concatenating ‘fish plate’. Note that when extending the beam, the bi-trapezoidal insert takes the place of the principal plate.

The transfer beam is assembled in linear sections comprising of assemblies: [2×601-001-1, and the principal plate 603-001-1, both—FIG. 55], concatenated via bi-trapezoidal assembly: [2×602-001-1, FIG. 55], which is inserted into the outer bi-trapezoid, along the straight lengths of the storage [as close as can practically be], parallel to the shoreline. These sections are connected via the ‘bi-trapezoidal insert [602-001-1, FIG. 55]. The sliding slot plate adaption allows the transfer beam Omni-angle flexibility so that the assembly can follow the storage shoreline contours.

Note: design of the transfer beam will vary according to the site size and location.

FIG. 56 illustrates the X-tendon [403-001-X, FIG. 56], Y-tendon [402-001-1, FIG. 56] and respective tethers [X-407-001-1, FIG. 56 & Y-406-001-1] attachment method suitable for and adaptable to suit any shaped storage bank shape.

FIG. 57 illustrates a reinforced variable density cost effective concrete transfer beam part [601-001-2, FIG. 57]. The material density and geometry of the base [601-004-2, FIG. 57], of this beam can be altered [preferably widened], to vary the mass (inertia) of the beam to specifically suit the localised wind conditions. The mass of the beam [601-001-2, FIG. 61], and floatation response of the float under the beam [608-001-X, FIG. 61], is calculated to resist to a required safety factor for worst-case wind speed duration. This includes the differing responses of ‘solid’ packaged foam floatation vs the ‘invert’ [301-001-3, FIG. 58], type floatation where partial flooding of the interior of the invert can be engineered to resist wind induced lift. The beam is generally ‘U’ section [601-005-2, FIG. 57], for optimal torsional and vertical and horizontal deflection stiffness. The beam is reinforced with heavily galvanized mesh and rods to provide the said required stiffness. There is a series of galvanised/stainless steel loops [601-003-2, FIG. 57], on either side for tether and tendon connection. Either end there is a set of reinforced holes [601-002-2, FIG. 57], for the insertion/fixing of a ‘U’ shaped section connection part [602-002-2, FIG. 58], through holes [602-003-2, FIG. 58], allowing for concatenation of any number of concrete beams. FIG. 58 illustrates a row of three such connections fixed on top of a series of reuse water modified inverts [301-001-3, FIG. 58], see FIG. 101 for feature identification. Note the said ‘U’ section connector includes a slot [603-002-2, FIG. 58], which when fixed through to the slot [604-002-1, FIG. 58], via bolt [605-001-1, FIG. 58], in the sliding slot plate provides the same in plane horizontal properties as in the steel trapezoidal transfer beam.

FIG. 59 illustrates an in plan view of a typical small storage clarifying the placements of: the X-tendons [403-001-X, FIG. 59], and the Y-tendons [402-001-1], FIG. 59), transfer beam [601-001-X, FIG. 59], and the respective tethers [X-407-001-1, FIG. 59 & Y-406-001-1, FIG. 59] as would be used commercially. The rack rows are fixed and run parallel to the X-tendons. The X-tendon minimum (vertical), separation is determined by the shadow angle of the previous row. This separation may be varied according to the occupational health and safety requirements of the regional authorities.

Wind loading on the PV panels is distributed along the tendons that terminate at the transfer beam. The transfer beam allows tethering [X direction—407-011-X, FIG. 59, Y direction-406-001-X, FIG. 59], normal to the parapet/berm of the storage, by reconfiguring the forces in the tendons; it needs to be engineered specifically to accommodate vertical, horizontal and torsional deflections for each application. FIG. 60 illustrates an isometric view of the typical storage as illustrated in FIG. 59. This view illustrates the transfer beam [601-001-X, FIG. 60], with the vertical restraint system cables [408-001-X, FIG. 60] revealed. As the water levels vary normally in commercial situations, in particular as the water levels fall, the central plate will become vulnerable to uncontrolled horizontal drifting in concert to the wind loads developed on the PV panel rows. This risk is eliminated with the use of vertical restraint cables [408-001-X, FIG. 60]. Note: Loads do not appear on the vertical restraint cables, unless there is a load on the tendons. To distribute the loads on the chord of the transfer beam [and remove the appearance of unsightly cabling], the vertical restraints can be run halfway along the transfer beam chord and in opposite directions. Consider the front facing transfer beam chord, the right half of the group [highlighted by the dashed arrow], of vertical restraints [aspect#6004], is taken off through cabling point [aspect#6002], the left group [aspect#6003], is taken off through point [aspect#6001]. There is an identical strategy for each chord of the transfer beam [see right cord FIG. 60]. The vertical restraints can also be run normal to the transfer beam directly to the shore, parallel with the tethering.

FIG. 61 illustrates a section of a typical storage, specifically designating the low wind [ie no ground anchor], restraint system differences between the reuse storage [A], and a potable or partially treated water storage [B].
A. The system: The modules floating on the central plate [301-001-X, FIG. 61], are fixed in position via the tendon (cables) [402-001-X, FIG. 61], which are connected to the transfer beam [601-001-X, FIG. 61]. The transfer beam is connected to the worm drive winch [409-001-X, FIG. 61], positioned at the shoreline via the tether (cable) [406-001-X, FIG. 61]. The winch will feed cable back and forth in concert with water level changes via a mechanical or electronic algorithm. Depending on the wind level variation and budget transfer beam system C [concrete transfer beam 601-001-2, FIG. 61], D [metal transfer beam [601-001-1, FIG. 61], with high density ballast [606-001-1, FIG. 61], (or a variant of both), and the floatation system [608-001-X, FIG. 61—Solid or ‘invert’ type], will be chosen;
B. This system is similar to the above with the exception that the modular system includes a deck part [301-001-X, FIG. 61], with an attached geo-membrane [refer FIGS. 24, 25, 26 & 54], shown in the diagram as [203-003-2, FIG. 61]. The Geo-membrane will require a fold/loop [203-004-2, FIG. 61], on the shore side of the transfer beam, which expands and contracts in concert with the water level changes. This said loop has a two-fold function:
(1) It acts as a flexible material reservoir cover for the surface area extension/changes—mathematically related to the water level changes;
(2) A perimeter gutter function, for the rain water/particulate cover run off shedding, deposition and subsequent removal [via sump pumps].

A small perimeter floatation pod [203-005-2, FIGS. 61 & 25], will keep the wall definition of the runoff ‘gutter’, as the sand filled bags [203-004-2, FIG. 25], maintain the depth profile as per current practice.

### Section 3: The Wing Slope Population

The population of the slopes [or wings] of the storage requires a change in the substructure that will allow movement on the slopes of the beached module rows. Differential movement of the module rows occurs in the beaching/re-floating process and through wind pressure. This type of movement can damage liners and create holes in slopes that are not concrete lined.

The purpose of the substructure pipe adaptor is to provide a rolling ‘wheel’ type surface intermediary that would roll over the surface instead of scraping the surface in the duration of the differential movement.

The square substructure pipe adaptor part [501-001-1, FIG. 62], has on top four shelled extrusions [501-002-1, FIGS. 62 & 63], with shelled sleeves and slots [501-003-1, FIG. 62]. The shelled sleeves and slots fit over the deck underside fixing points, and the hexagonal extrusions fit into the corner four rib cavities only [refer FIG. 67]. The part has a flat plate at the base of the hexagonal extrusions [501-009-1, FIG. 62], with three linked pairs of dual curved arms [501-008-1, FIGS. 62 & 63], with five snap fit holes cut into the interior curve of each of the arms [501-005-1, FIGS. 62 & 63], as fixing points for Teflon pipe rollers [502-001-1, FIG. 63], that clip into the holes. The diameters are such that standard off the shelf pipe would slide into the arms and rotate freely on its cylindrical axis, via the rollers [refer pipe 504-001-1, FIG. 67 inserted in adaptor 501-001-1, FIG. 67 and roller 502-001-1, FIG. 67]. The pipes pass through two faces/sides of the adaptor square, on the other two sides, are two extrusions [501-006-1, FIG. 62], with locking pin adaptors [501-007-1, FIG. 62], through which pins [503-002-1, FIG. 63] are inserted and locked off [using (cotter pins)/(plastic clip) through 503-002-1, FIG. 63], at the bottom of the locking pin adaptors [501-007-1, FIG. 63].

The purpose of the said extrusions is to support/lock the end caps [505-003-1, FIGS. 64 & 67-70], which are welded onto the pipe [504-110-1, FIG. 64]. The locking pin [503-001-1, FIG. 63], restricts axial movement of the pipe via nesting in the groove in the end cap [505-003-1, FIG. 64], whilst allowing rotation of the pipe about the said axis.

If the pipe adaptor is oriented [and fixed in the deck [201-001-1, FIG. 67], so that in a row of assembled decks all the parallel pipes are collinear [ie: pipes: 504-001-1, FIG. 68], then concatenations of this assembly can be used for populating the slopes of storages, as the rotating/rolling capability of the pipes provides the least friction to the storage slope liner [refer FIG. 68]. As can be seen from the illustration, there are four rows of pipe traversing/(and fixed to) the module top part. The internal pipes need an axial movement restrictor and fixing point for pipe end caps. This is achieved by the pipe dock part [506-001-1, FIG. 67], which fixes to the underneath of the drain [in the deck], and docks and locks two pipes together whilst allowing axial rotation.

Concatenation of row assemblies [FIG. 68], is provided via a further row linking coupling/hinging part [507-001-1, FIG. 66]. This hinge coupling incorporates two cylinders [507-002-1, FIG. 66], separated by all extrusion [507-008-1, FIG. 66]. The external diameter of the said cylinders is such that in their operation they will not impede the rotation and travel of the pipe on the slope [or any other surface]. The hinge coupling has provision for the insertion of two [locking] pin parts [503-001-1, FIG. 66], that when inserted, provide protrusions through holes [507-005-1, FIG. 66], that lock the pipe caps in place via a circular groove in the pipe cap [505-003-1, FIG. 64]. A further purpose of the hinge part, is to lock two end caps [and therefore two pipe ends], together, and also to keep the pipes axially in place via separation guards [507-003-1, FIGS. 66 & 68], to arrest endplay. FIG. 68 illustrates two decks with substructure pipe adaptors [501-001-1, FIG. 68], rollers [502-001-1, FIG. 68], pipes [504-001-1, FIG. 68], end caps [505-001-1, FIG. 68] and the hinge part [507-001-1, FIG. 68], with hypalon sheet [aspect#6801]. The hypalon sheet provides flexible water proofing for water runoff off the top parts. FIGS. 69 & 70 illustrate two pipe connection systems—FIG. 69 illustrates an ‘inner’ connection scheme, and FIG. 70 illustrates an ‘outer’ connection scheme. FIG. 71 illustrates the inner assembly of one inner and one outer schemes, as an inner-outer assembly. FIG. 72 illustrates the connection of two ‘inner-outer’ assemblies [aspect#7202 & 7203, FIG. 72 respectively] illustrating a constructive model, more ‘inner-outer’ assemblies can be added [in the same way], ad infinitum to this nucleus. Demonstrating the possible construction of large scale assemblies from the two said ‘inner’ and ‘outer’ building blocks. The floatation substructure of this said assembly, consisting of an endless array of four parallel pipes [aspect#7204, FIG. 72], mounted normal to each other, in an arrangement similar to a basket weave paving pattern. The said assembly is an alternative method for construction of the central plate membrane, the linked pipe substructure would ensure a rigid construction with a very high natural resonant frequency unable to be set into resonance by elemental forces.

FIG. 73 illustrates a North oriented storage [aspect#7301], with a CP population [aspect#7303], and slope [wing] populations [aspect#'s 7304 & 7309], of modules with PV racking. Note that:
The water level of the storage is below full—exemplified by the outermost PVP row on the slope perimeter [aspect#'s 7304 & 7309], partially beached;
The modules in the CP [aspect#7308], and the module rows on the slopes [aspect#'s 7306 & 7307, long & short respectively], are drawn as blocks with no hinge parts;
The rectangles on the module rows [aspect#7305], represent the PV panels and superstructure.

This drawing illustrates the necessary spacing of the slope population [aspect#'s 7309 & 7310], so as to not interfere with the tethering of the CP to the shoreline and the reduction in population density of the PV panels due to the necessary articulation of the slope rows.

One of the requirements of the US EPA LT2 rule, is that access is made available to the subsurface of the cover, for maintenance and/or cleaning. The regular array of water access portals [301-015-2, FIGS. 15 & 21], in the membrane—exposed after removing the caps [205-001-1, FIG. 27], allow for the insertion of inexpensive membrane lifting apparatus. A balloon deploying and inflation device is illustrated in FIG. 74. A pressurized air canister [303-006-2, FIG. 74], via electronic controls releases air through orifice [303-012-2, FIG. 74], forcing piston [303-010-2, FIG. 74] down, thereby deploying:
The shield umbrella [303-003-2, FIG. 74], from folded in can perimeter position [aspect#7401] to expanded position [aspect#7402]; and
Inflating the balloon [303-001-2, FIG. 74] through extendable tube [303-011-2, FIG. 74] and the outer nylon net [303-002-2, FIG. 74].

As the balloon is inflated it is restricted in volume and shape by the design of the nylon net, providing a rigid structure. The assembled device packed into a metal tube [303-005-2, FIG. 74], with ‘pop’ of cap [303-009-2, FIG. 74], with friction fit seal [303-014-2, FIG. 74]. Note that this device is designed to be re-packable with the deflated balloon and net, and the air canister is also rechargeable.

FIG. 35a illustrates top and bottom views of four lift balloon assemblies [303-001-2, FIG. 75], deployed under a 2×2 array of square inverts [301-001-2, FIG. 75]. The un deployed device is inserted as described [above], through holes [303-005-2, FIG. 75], and discharged. On discharging the folded umbrella [303-003-2, FIGS. 74 & 75], in unpacked position [aspect#7402, FIG. 74], provides a support interface between the balloon and the ribbing substructure of the square invert. By partially draining the storage and by deploying the temporary lift balloons in large or small sections, this method, will give a cost effective access to the substructure of the membrane. After use the balloons can be deflated and repacked for reuse.

### Section 4: CP Population of Gas Producing Reuse Storages

Reuse storages, such as storages that have large volumes of gas emissions either from emissions from the water body or from the storage bed, where the use of the invert part would not be suitable, unless recovery of the gas emissions in intended. If gas emission collection is specified, the perimeter cavities of each invert of the array could be connected, and the pressurised emissions collected.

As discussed, the above substructure system [ie: the third floatation embodiment], with a minor adaption can be used to form an alternative storage central plate [CP] substructure. The advantage of this embodiment is that the floatation of the CP array would not be affected by gas emitting reuse storages.

### Section 5: Spinoff Adaptation of the Racking System to Roof and Land Bases Arrays

The preferred embodiment of the rack with the addition of a small number of parts can be easily adapted for deployment on top of flat roofs and land based arrays. FIG. 76 illustrates a row separator [110-001-1, see FIGS. 76, 77, 79, 85 & 86 for all perspectives], which clips into the junction of two piggy backed racks, via the downward facing clip [110-009-1, FIGS. 76 & 77]. The row separator by insertion defines the row spacing, locks the two racks together and provides two vented [via slots: 110-006-1, FIG. 76], cable management trays [110-005-1, FIG. 76]. The rack has a moulded raised ribb-block within and around the fixing plate clip area [101-031-2, FIGS. 77, 33 & 35], and a similar moulded inverted rib-block, within and around the pivot plate [101-003-2 FIG. 34]. In the piggyback process both of these rib-blocks [i.e. the pivot and fixing plate rib-block mouldings], intermesh. The pivot rib-block also incorporates side extrusions [101-016-2, FIGS. 33 & 77], which only allow movement normal to the direction allowed by the raised rib-block illustrated by the arrow highlighted by [aspect#7702]. The purpose of the intermeshing of the rib-blocks, is to remove as much as possible the longitudinal loads from the separator clip joint whilst retaining thermal expansion laterally. Longitudinal expansion [ie: expansion along the direction of the separator length], is addressed by the connection of the circular clip [110-009-1, FIG. 77], via parallel bars to the main body of the separator [110-011-1 FIGS. 76 & 77]. Longitudinal expansion is absorbed by the flexing of these connecting bars, moving the circular clip only in the longitudinal direction whilst retaining perspective to all other orientations. Holes [110-010-1, FIG. 76], are moulding finger insertion points, that create the cable tray clip holes [110-007-1, FIG. 76, The Cut outs [110-003-1, FIG. 76], placed at either end of the separator, allow for the positioning of the bottom tendon bracket clamp [405-001-1, FIG. 51], and the slot holes [110-004-1, FIG. 76], are for the insertion and fixing of a ‘key’ [115-001-1, FIG. 96], in land based applications [refer: FIG. 99].

FIG. 78 illustrates the ballast wedge [111-001-1, FIG. 78], —made of light concrete with galvanized steel arms [111-003-1, FIG. 78], with a variable density and therefore variable weight [anchoring] values. The ballast wedge is designed to fit snugly between two racks [111-011-1, FIG. 79]. It features contoured concave sides [111-008-1, FIG. 78], and protruding tapered extrusions [111-007-1, FIG. 78], the legs extending down from these said extrusions. The ballast wedge in application to the second embodiment, rests on its legs [111-006-1, FIG. 78], that protrude through the rack fixing and pivot plate [101-023-2, FIG. 33], note this applies to the second embodiment of the rack only. In the third embodiment the legs rest on shelves [101-023-3, FIG. 83], and raised blocks [101-056-3, FIG. 83]. The top of the ballast wedge is tapered to match the design angle [111-002-1, FIG. 78], of the rack—as specified. The galvanized arms [111-003-1, FIG. 78] rest on the ledges [101-030-2, FIGS. 33 & 34]. There is provision for a wider legged ballast wedge [101-024-2, FIG. 32] of similar but wider design. Necessitating the two separator fixing points [101-018-2 & 101-019-2, FIG. 35]. The ballast wedge is used in conjunction with the tendoning system and provides an extra gravity ‘hold down’ function where roof waterproofing penetrations are forbidden. Holes [111-004-1, FIG. 78] provide cable access and rain water drainage.

A direct result of the role of the pivot plate in the piggyback scheme, is the requirement for the entire pivot leg to be shorter than the fixing leg—as discussed previously in the application of the rack to the deck. This only affects the first column of the rack array. FIG. 81 illustrates a buffer part [113-001-1, FIG. 81], that equates the leg lengths. This part also provides a total fixing point [113-002-1, FIG. 81], for the separator [110-001-1, FIG. 76] by imitating the piggyback fixing assembly [113-003-1, FIG. 81], allowing a secure fitment. It also incorporates screw holes [113-004-1, FIG. 81], that align with the tendon bracket holes for extra fixing.

A full restraint system is as a rule deployed on a roof only if it is not strong enough to support a ballasted system, or if the deployment is subject to high winds. Generally the restraining system on a roof is limited to two to three perimeter rows [& columns], mainly to arrest potential vertical lift with resultant planar horizontal repositioning and laterally moving seismic events.

To this end, the far right hand side column of the array also needs a buffer part [112-001-1, FIG. 80], to provide/complete a fixing point [112-002-1, FIG. 80], for the separator [110-001-1, FIG. 79], and the tendon bracket [401-001-1, FIGS. 80 & 79]. Therefore, providing the adaption to attach a restraint tendon system to the far right column of an array. The said part is attached to the rack via intermeshing of the rib-blocks [112-004-1, FIG. 80], and the tendon bracket fixing screws [403-003-1, FIG. 47], that fix through the fixing buffer into the separator circular clip pilot hole [110-008-1], FIG. 76]. Supplementary fixing of the tendon bracket is achieved via screws into the buffer pilot holes via path: [112-003-1, FIG. 80].

FIGS. 86 and 86 illustrate the entire part assembly and explosion diagrams of the scheme. Note the ability of the design to incorporate the tendon bracket [405-001-1, FIG. 85], running under the ballast wedge [111-001-1, FIGS. 85 & 86]. FIG. 87 illustrates a top view of a 6×3 array roof racking array clearly illustrating the horizontal [403-001-1, FIG. 87], and vertical [402-001-1, FIG. 87], tendons, the separators [110-001-1, FIG. 87], and the rack and PV panel assemblies [aspect#8701]. Note the grey arrows indicating/travelling from the left to the right showing the clip-n-lock assembly process.

FIG. 82 is an isometric rendering of the production [third embodiment of], the Rack part [101-001-3, FIG. 82]. To reduce the number of ancillary components the following changes may be made:
The pivot separator connection block [101-016-3, FIGS. 82, 83 & 84], of the rack. The circular clip design of the separator [110-009-1, FIG. 76], was replaced with linear in-line clips recesses [110-002-2, FIG. 88], with matching clips on the rack [101-058-3, FIG. 83], also, the recesses have allowances [lengthwise] for thermal cycling movement of the separator on bottom and parallel in line clips [3911e] on top. The slots [101-164-3, FIG. 88], were retained to allow thermal movement along the slotted ‘long’ direction. The receptacle clip rests and recesses [101-061-3, FIGS. 88 & 101-015-3, FIG. 88 respectively], also have thermal movement allowances. The top clips of the said connection block [101-058-3, FIG. 86], connect the separator through slots [110-002-3, FIG. 89], are also configured for thermal movement;
The number of front zip connector slots [101-017-3, FIGS. 85, 86 & 87], was increased to four enhancing connective strength;
A ‘last column’ separator extra fixing point was included in the rack [101-052-3, FIGS. 86, 87 & 88], for perimeter tendon fixing of the array. Plastite screws are fixed into these bosses running through thermal slots [110-003-2, FIG. 89], in the separator. Bosses [101-050-3, FIG. 86], and ribbing [101-008-3, FIG. 86], support the fixing of the tendon bracket [see FIG. 86];
All raised recesses for deck connection ‘cones’ [see 201-006-2, FIGS. 3 and 101-021-2, FIG. 32], have been removed [101-002-3], to enhance the rack base contact area and therefore friction with the roof membranes; If more friction is required the bottom of the deck could be ‘textured’ with a raised pattern.
Ballast feet penetration [101-023-3, FIGS. 85, 86 & 88], has been removed to enhance the weight distribution (and thus friction), between the rack base and roof membrane;
Extension pads [101-059-3, FIGS. 87 & 88], were added to provide roof contact (friction and balance), to the piggy back leg, with corresponding slotted holes in the fixing plate [101-053-3, FIGS. 87 and 101-054-3, FIG. 87 for piggyback fixing position #2];
The base of the rack has been extended to accommodate the larger (wider) panel sizes, with two clip locating row piggyback positions [101-053-3, FIGS. 87 and 101-054-3, FIG. 87 for piggyback fixing position #2] and ballast rest plate [101-056-3, FIGS. 86 &87].
FIGS. 90 and 91 illustrate the assembly of the two different panel sizes. Note the separation distance increase [aspect#9102, FIG. 91].

FIG. 92 illustrates an angle adaptor part. This rack accessory slides via extrusions [114-009-1, FIGS. 93 & 114-008-1, FIG. 93] into slots [101-017-2, FIG. 33 &101-026-2, FIG. 33] respectively [see FIG. 95], to rest on the rack PV panel ledge [101-010-2, FIG. 96] and securely screw fixes in the rack through [114-010-1, FIG. 93] into [101-041-2, FIG. 33]. The adaptor is reinforced through perimeter fluting [114-002-1, FIG. 92], and has scallops for cable access [114-005-1, FIG. 92]. The adaptor has rear slots that accept the PV panel slide and fixing part [105-001-1, FIG. 94], that is identical to those of the rack [refer FIG. 46], with the corresponding ‘flipper’ ratchet arms [114-007-1, FIGS. 93 & 94]. The front bar of the adaptor has a front facing birds mouth connection [114-004-1, FIG. 94], the rear of this connection can be used as a stop for the electrical assembly of the PV panel. The front frame part, is then moved over the birds-mouth, and the rear frame, placed over the rear slide adjuster—which is pulled and fixed in place via the rear ratchet mechanisms. The advantage of this accessory is that the adaptor can be made to any angle [greater or equal to 5 Degrees], for a modest cost to augment an off the shelf rack to the required PV angle. Another Advantage is the adaptor is reversible, FIG. 96, illustrates a rack [110-001-2, FIG. 96], with the adaptor in a low angle position [A] and then reversed in a larger angle position [B], note that [aspect#9601] indicates the PV panel.

Another adaptation of the racking system is to a land based array application. One of the major problems with most land based racking systems is addressing the problem of weed and grass growth. FIG. 100 illustrates in principle the land based system. A weed mat [aspect#10002] is laid down on a per-graded site. Light concrete blocks [117-001-1, FIGS. 100 &99], re then laid over the site, —each block easily manoeuvred into place via two men. The racking array is fixed to the concrete blocks via the key part [115-001-1, FIGS. 97 & 99], which inserts through the separator slot hole [110-004-1, FIGS. 76 and 110-004-2, FIG. 89 in the second embodiment], through to the lock part [116-001-1, FIG. 99, & FIG. 98], which is embedded in the light concrete block [117-001-1, FIG. 99]. The key has a t-bar protrusion [115-006-1, FIG. 97], which when inserted into the lock and twisted clockwise [via a special too which inserts in the top of the key], preloads the joint as it is forced up a half circle ramp [116-005-1, FIG. 98], to rest in a detent [16-004-1, FIG. 98]. The twisting motion is stopped via block [116-006-1, FIG. 98], so that the key cannot be unlocked by further twisting. Also the oval shaped top of the key [115-003-1, FIG. 97], is made just larger than the width between the separator walls at the insertion point [115-001-1, FIG. 100], so that on insertion the twisting prestresses the walls outward [away from the key], until the major oval axis is turned past the walls. Each of the separators have fixings in two places all as close as possible to the rack.

FIG. 101 illustrates an invert redesigned to eliminate the need for a deck system for water reuse storages which do not require air and water particulate shedding systems. The inverts are deployed as in potable installations, except that the deck is replaced with the flat based ‘production’ rack [see FIG. 102]. This system has a single assembly orientation of 45 degree rack to invert, to maximise connective (membrane) strength. As there is no need for geo-membranes, with the perimeter transfer beam the array orientation provides no installation problems.

FIG. 103 illustrates a partial shipping parts stack. To enhance part installation and deployment efficiency, the parts are semi assembled in groups, so that all parts are delivered and present at the installation point enhancing the speed of deployment of the system. A locking pin [118-001-1, FIG. 103], locks the rear sliding clamp on the rack, without engaging the flipper arms. The separator has ‘T’ shaped holes cut along its centre line [110-005-2, FIG. 89], which are large enough to fit over the ‘birds mouth’ feature of the said rear sliding clamp [105-003-1, FIG. 45]. To increase the packing density, cut outs [110-006-2, FIG. 89], were necessary in the separator to accommodate the bottom reinforcing bar [105-007-1, FIG. 45], of the said sliding clamp. FIG. 103 illustrates two layers of packing, exemplifying two instances [aspect#10301 & 10302, FIG. 103], of rack stacking, two of rear sliding clamp [aspect#10305 & 10306, FIG. 103], and two of separator stacking [aspect#10303 & 10304, FIG. 103], are clear. Note also the partial assembly of the front zip clamps [106-101-1, FIG. 103].

### Section 6: Adaptation of the Racking System to Domestic Roof Arrays

FIG. 104 illustrates the basic roof rack [101-001-4, FIGS. 104, 105, 107 & 110]. The design is based around a rectangular PVP perimeter mould with a preferred hexagonal mesh base [101-018-4, FIG. 104] with horizontal and vertical connective frames, [101-003-4 & 101-002-4, FIG. 104], respectively. The said frames when concatenating the rack, insert into receptacles fitted with vertical deflection limiters [101-013-4, FIG. 104], and a quick clip fastening system [101-014-4, FIG. 104]. The said connection is further substantiated via a circular push in clip [102-001-4, FIGS. 105 & 106], which connects the two concatenated racks via aligned receptacles [101-011-4 and 101-010-4, FIGS. 104 & 105]. The said circular clip also fixes the PVP inserted into the perimeter frame, via the wings [102-003-4, FIG. 106], and vibrationally restrained by the arms [102-002-4, FIG. 106]. Cable guides [101-018-4, FIG. 104], moulded onto the hexagonal base, form internal cable trays running below the PVP's. Perimeter horizontal wall penetrations [101-009-4 & 101-008-4, FIG. 104], respectively allow for the continuous passage of cabling through each rack. The penetrations are placed such that both assembly configurations [vertical & horizontal, direct and offset alignment respectively]. The rack has incorporated a raised standoff discontinuous [hexagonally perforated] vented perimeter skirt [101-017-4, FIG. 104], to enhance the air flow underneath the PVP, thereby improving the cooling of the PVP. The said discontinuities in the skirt optimize rack transport stack-ability, and inter rack connection.

The domestic rack is fixed to the gabled roof via a ratchet and strapping mechanism [103-001-4, FIGS. 108 & 110]. The ratchet mechanism consists of a bracket [103-002-4, FIG. 108], into which is inserted a ratchet part which comprises of a shaft slotted to accept the strapping [103-008-4, FIG. 108], and a cog [103-003-4, FIG. 108], attached to the said shaft, with its ‘teeth’ specifically designed to allow clockwise rotation only via the spring [103-004-4, FIG. 108]. The said shaft also incorporates a small and large [10 mm (⅜″) & 12.7 mm (½″)] square drive points [103-009-4 & 103-010-4, FIG. 108], respectively, for standard hand or power tool connection. The base of the bracket has two slots [103-006-4, FIG. 108], allowing reverse installation of the ratchet mechanism, to optimise practical access to the winding mechanism accessed via hole [101-016-4, FIG. 104]. The ratchet mechanism inserts into the rack via slots oriented in the [z—normal out of rack base plane], direction, oriented in vertically, [in rack base plane-y], and horizontally [in rack base plane-x], directions [101-005-4 & 101-004-4, FIG. 104], respectively—deemed the rack fixings. The strap is inserted through a slot in the said fixings [101-006-4, FIG. 104], the slot cut also penetrates through adjacent wall mouldings in the same plane of the rack, in both vertical [101-007-4, FIG. 104], and horizontal [101-006-4, FIG. 104], directions. These slots add connective functionality to the rack roofing application system. FIG. 110 illustrates a 2×2 domestic rack array [101001—not including PVP for clarity], with six magnified strap connection scenarios [11005-11010].

Scenario [11005], illustrates an in rack base plan plane strapping mechanism [103-001-4, FIG. 110], oriented in the vertical direction. The strap [103-005-4, FIG. 110], fixes and via the ratchet mechanism, tensions the bottom LHS of the roof PVP array to the turn buckle bracket [104-001-4, FIGS. 109 & 110], which is in turn fixed to the lowest rafter point [near the facia board 11004], or if not appropriate to a noggin fixed between two adjacent parallel rafters. The 11005 fixing scenario provides a series bottom tensioned fixing points for the PVP array in all possible roof systems. If the roof is a flat tile roof the facia [11004], is notched out (slightly) to fit the turn buckle bracket.

Scenario [11006], illustrates an in rack base plan plane strapping mechanism [103-001-4, FIG. 110], oriented in the horizontal LHS direction. The strap [103-005-4, FIG. 110], can fix and tension the LHS of the array to either a Gable edge, valley rafter or in between rafter.

Scenario [11007], illustrates an in rack base plan plane strapping mechanism [103-001-4, FIG. 110], and can be oriented in both horizontal and vertical directions. The strap [103-005-4, FIG. 110], can fix and tension up to 10 linearly concatenated domestic racks, in either oriented directions. If the installation position is subject to a wide range of diurnal and seasonal temperature variation a maximum of two inline racks are recommended.

Scenario [11008], illustrates an in rack base plan plane strapping mechanism [103-001-4, FIG. 110], oriented in the vertical top centre support direction. The strap [103-005-4, FIG. 110], can fix the top of the array to either a ridge beam or the top of a rafter in proximity to the ridge beam or to a noggin fixed between two adjacent parallel rafters in proximity to the ridge beam.

Scenario [11009], illustrates an in rack base plan plane strapping mechanism [103-001-4, FIG. 110], oriented in the horizontal direction. The strap [103-005-4, FIG. 110], fixes through the gaps in between the roof tiles, to the rafter or installed noggin. The fixing is tensioned via the ratchet mechanism, the passage through the tile/roof penetration may need to be waterproofed. The fixing provides an internal support point for the array.

Scenario [11010], illustrates an in rack base plan plane strapping mechanism [103-001-4, FIG. 110], oriented in the horizontal RHS direction. The strap [103-005-4, FIG. 110], can fix and tension the RHS of the array to either a Gable edge [11002], valley rafter or in between rafter.

Note:

(1) The turn buckle bracket is fixed to the rafter/noggin via in skew screws or similar product.
(2) The straps can be fixed directly to metal roofs, or to rafters, ridge beams, gable beams etc with vibration proof screw nails/rivets.

This invention is particularly useful in

1) The prevention of a large amount of evaporation from large water storage areas;
2) The prevention of rain water entering a treated water deployment;
3) Reduction of the salination increase of the water storage volume;
4) Reducing the formation of Blue-green Algae in all water storage areas for covers>=about 40% of the full surface area of the storage;
5) Allowing the control of dissolved oxygen [DO] levels in a water body, by patterning the membrane [agricultural storages only];
6) Reduction of aqua weed growth in and/or above the storage water surface;
7) The [standard] electrical system can be used as a net metering or commercial power provider system;
8) The membrane is stiff enough to not be susceptible to storm induced low frequency resonance;
9) The membrane has a high enough integrity to dampen induced oscillations;
10) The membrane has a PMS restraint system;
11) The tendons maintain a expansion gap between the top parts, and the Synthetic rubber gutter width, whilst distributing the forces from the loads impacting the solar panel racked rows;
12) The transfer beam normalises the forces on the tendons, permitting the option of tethering normal to the storage bank;
13) Populating the slopes of storages with solar PV panels;
14) Method of populating gas emitting water reuse storages.

From the above, those skilled in the art will realise that this invention includes the following benefits.

The modular parts can be assembled to form a high strength membrane with a high floatation capability;
Quick installation of the rack payload infrastructure;
The payload infrastructure can be fixed/aligned into any angular position;
A direct fix rack to deck system requiring specific fixing angles;
The rack aligns the PV panel to the site latitude angle or any other desired angle;
The membrane cover can be laid into any size or shape of water storage central plate surface area;
The membrane can be supported via rolling modular articulated floating pipes replacing the invert on the slopes, reducing wear and geo-membrane content;
The membrane central plate can be supported with fixed modular pipe arrays for gas emitting storages;
The membrane has a high degree of stiffness and therefore a higher resonant frequency, unlikely to be resonated via PMS;
The membrane has a virtual ballast of water which contributes to the energy dissipation/dampening of its energy waves traversing its surface;
The membrane can support ‘missing’ modules/areas—holes allowing the aqua culture enough oxygenation via the holes in the deployment—water reuse only;
The membrane constructed with a square module invert, and has capped access holes to the water body;
The membrane can be raised for sub inspection via retractable [and reusable], nylon net encased balloon props;
The membrane can be designed for a site specific dissolved oxygen requirement;
The membrane deployment extinguishes excess light access to the water reducing the formation of Algae preferably Blue-green Algae;
The membrane deployment reduces the absorption of energy from the sun by the water body and therefore reduces the temperature of said water body;
The membrane deployment reduces the salination increase in the water storage volume by reducing evaporation;
The membrane can be connected via flexible membranes, perimeter drains and sumps to form a total floating cover impervious to rainwater and dust particulate pollution and their combination.
The membrane payload preferably a solar PV generator, permits power generation close to cities [as most water supplies are in close proximity to cities] reducing infrastructure power insertion costs;
The membrane is tethered to normal to the shoreline via a transfer beam;
The transfer beam enables the transformation of forces generated in the rows, to the shoreline tethers.
The transfer beam can assist in the restraint of slope populations eliminating the requirement for extra tethering winches.
The membrane racking system can be adapted for roof top as well as land base arrays using light cement blocks, ballast wedges, separators and connecting locks and key mouldings;

Those skilled in the art will realise that this invention provides a unique arrangement to control evaporation and water quality in large water storages and at the same time take advantage of the availability of solar energy falling on the water surface to provide solar energy generation. Those skilled in the art will also appreciate that this invention provides a PV panel support structure and deck that may be deployed on any land or water support infrastructure in an inexpensive and speedy installation method.

Those skilled in the art will realise that the present invention may be made in embodiments other than those described without departing from the core teachings of the invention. The modular platform may be adapted for use in a range of applications and sizes and can be shaped to fit the requirements of the desired application.

1. A platform for supporting solar panels in which a solar panel support surface seats on an existing building structure or on top of two or more flotation pods to form a module that is adapted to carry a solar panel said platform consisting of an array of said modules connected by a grid of tendons that clip onto the solar panel support surface modules and the solar panels are mounted in spaced apart positions on said support surface.

2. A platform as claimed in claim 1 in which the solar panels are mounted on solar panel supports arranged in arrays on said solar panel support surface.

3. A platform as claimed in claim 1 which includes ballast units located between solar panel supports.

4. A floating platform for supporting solar panels which consists of a plurality of inter-connectable modules, a plurality of structural tendons forming a grid each tendon being attached to a plurality of modules along its length and a transfer beam positioned about the periphery of said plurality of modules each end of said tendons being secured to said transfer beam.

5. The floating platform as claimed in claim 1 is able to be tethered to the shore line of a water body so that the solar panels face north or south;

6. The platform as claimed in claim 1 which forms a platform with the ability to support latitude angle photovoltaic panels by the provision of bosses on the upper surface of each module to connect to photovoltaic panel support structures.

7. The platform as claimed in claim 1 in which each module has at least one surface recess so that the assembled platform has a water run off profile draining in two normal directions in the horizontal plane.

8. A floating platform as claimed in claim 4 in which each module is provided with insertable seals that fit onto and between the perimeter edges of the top surface of each module.

9. A floating platform for supporting floating platforms which includes intermeshing floatation pods and a solar panel support surface that seats on top of two or more flotation pods to form a module that is adapted to carry a solar panel the support surface incorporation drainage channels.

10. A floating platform as claimed in claim 9 in which each flotation pod is an up turned T shaped open-pod with several isolated downward open cavities and two pods are aligned to nest at right angles to form the minimum repeatable module.

11. A floating platform as claimed in claim 1 adapted for water storages where the area of the central plate of the reservoir is less than about half of the surface area of the full reservoir and the reservoir has slope areas on its periphery wherein the slope areas are fitted with a slope tracking membrane.

12. The platform as claimed in claim 4 which forms a platform with the ability to support latitude angle photovoltaic panels by the provision of bosses on the upper surface of each module to connect to photovoltaic panel support structures.

13. The platform as claimed in claim 4 in which each module has at least one surface recess so that the assembled platform has a water run off profile draining in two normal directions in the horizontal plane.
